(19) United States
(12) Patent Application Publication
(10) Pub. No.: US 2025/0072277 A1
(43) Pub. Date: Feb. 27, 2025

(54) LIGHT EMITTING ELEMENT AND DISPLAY DEVICE INCLUDING THE SAME

(71) Applicant: Samsung Display Co., LTD., Yongin-si (KR)

(72) Inventors: SEULONG KIM, Yongin-si (KR); YOUNGHO KIM, Yongin-si (KR); BUM SUK LEE, Yongin-si (KR); SEOKJAE LEE, Yongin-si (KR); JAHYUN IM, Yongin-si (KR)

(21) Appl. No.: 18/814,267

(22) Filed: Aug. 23, 2024

Related U.S. Application Data
(63) Continuation-in-part of application No. 18/798,601, filed on Aug. 8, 2024, now abandoned.

(30) Foreign Application Priority Data
Aug. 25, 2023 (KR) 10-2023-0111807
Aug. 22, 2024 (KR) 10-2024-0112976

(51) Int. Cl. H10K 85/30; C09K 11/02; C09K 11/06; H10K 50/12; H10K 50/19; H10K 50/858; H10K 85/60

(52) U.S. Cl. CPC H10K 85/342; C09K 11/02; C09K 11/06; H10K 50/19; H10K 85/633; H10K 85/636; H10K 85/654; H10K 85/6572; H10K 85/658; C09K 2211/1007; C09K 2211/1011; C09K 2211/1014; C09K 2211/1022; C09K 2211/1037; C09K 2211/1092; C09K 2211/185; H10K 50/12; H10K 50/858; H10K 85/624; H10K 85/6576

(57) ABSTRACT

A light emitting element of an embodiment includes a first electrode, a first light emitting unit on the first electrode and including a first emission layer, a charge generation unit on the first light emitting unit, a second light emitting unit on the charge generation unit and including a second emission layer, a second electrode on the second light emitting unit, and a capping layer on the second electrode, wherein the first light emitting unit includes a first compound including a first moiety, the second light emitting unit includes a second compound including a second moiety, the capping layer includes a third compound including a third moiety, and the first moiety, the second moiety and the third moiety each independently includes one among benzothiophene, thienopyridine, thienopyrimidine, thienopyridazine, thienopyrazine, thienotriazine, thienotetrazine, benzothiazole, thiazolopyridine, thiazolopyrimidine, thiazolopyridazine, thiazolopyrazine, thiazolotriazine, thiazoloetetrazine, benzothiadiazole, thiadiazolepyridine, thiadiazolepyrimidine, thiadiazolepyridazine, thiadiazolepyrazine, thiadiazoletriazine, and thiadiazoletetrazine.

### CROSS-REFERENCE TO RELATED APPLICATIONS

The present application is a continuation-in-part of U.S. patent application Ser. No. 18/798,601, filed Aug. 8, 2024 which claims priority to and the benefit of Korean Patent Application No. 10-2023-0111807, filed on Aug. 25, 2023, in the Korean Intellectual Property Office, and also claims priority to and the benefit of Korean Patent Application No. 10-2024-0112976, filed on Aug. 22, 2024, in the Korean Intellectual Property Office, the entire contents of all of which are hereby incorporated by reference.

### BACKGROUND

### 1. Field

Embodiments of the present disclosure herein relate to a light emitting element and a display device including the same.

### 2. Description of the Related Art

An organic light emitting element is a self-luminescent type (or kind) of element that shows a rapid response time and is driven by a low voltage. Accordingly, an organic luminescence display device including the organic light emitting element may omit a separate light source and have various advantages including weight lightening, thinning, excellent luminescence and a lack of viewing angle dependence.

An organic light emitting element is a display element having an emission layer composed of an organic material between an anode electrode and a cathode electrode. Holes provided from the anode electrode and electrons provided from the cathode electrode recombine in an emission layer form excitons, and from the excitons, light corresponding to an energy between the holes and electrons is produced.

A tandem organic light emitting element has a structure composed of a plurality of layers including two or more stacks of hole transport layer/emission layer/electron transport layer between an anode electrode and a cathode electrode, and a charge generation layer assisting the generation and transfer of charges may be present between the stacks.

### SUMMARY

Embodiments of the present disclosure provide a light emitting element having improved emission properties and element lifetime.

Embodiments of the present disclosure also provide a display device having excellent display quality by including a light emitting element having improved emission efficiency and lifetime.

A light emitting element according to an embodiment of the present disclosure includes a first electrode, a first light emitting unit on the first electrode and including a first emission layer, a charge generation unit on the first light emitting unit, a second light emitting unit on the charge generation unit and including a second emission layer, a second electrode on the second light emitting unit, and a capping layer on the second electrode, wherein the first light emitting unit includes a first compound including a first moiety, the second light emitting unit includes a second compound including a second moiety, the capping layer includes a third compound including a third moiety, and the first moiety, the second moiety and the third moiety each independently include one among benzothiophene, thienopyridine, thienopyrimidine, thienopyridazine, thienopyrazine, thienotriazine, thienotetrazine, benzothiazole, thiazolopyridine, thiazolopyrimidine, thiazolopyridazine, thiazolopyrazine, thiazolotriazine, thiazoloetetrazine, benzothiadiazole, thiadiazolepyridine, thiadiazolepyrimidine, thiadiazolepyridazine, thiadiazolepyrazine, thiadiazoletriazine, and thiadiazoletetrazine.

In an embodiment, the first moiety, the second moiety and the third moiety may each independently include one among benzothiophene, thienopyridine, benzothiazole, and thiazolopyridine.

In an embodiment, the third compound may be represented by Formula 1.

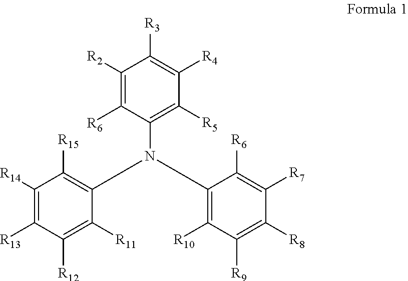

In Formula 1, R₁ to R₁₅ are each independently a hydrogen atom, a deuterium atom, a halogen atom, a substituted or unsubstituted amine group, a substituted or unsubstituted aryl group of 6 to 30 ring-forming carbon atoms, or a substituted or unsubstituted heteroaryl group of 2 to 30 ring-forming carbon atoms, and at least one among R₁ to R₁₅ is a substituent represented by Formula 2.

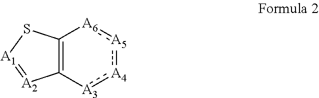

In Formula 2, A1 to A6 are each independently CRᵢ or N, and Rᵢ is a hydrogen atom, a deuterium atom, a halogen atom, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined together with an adjacent group to form a ring.

In an embodiment, the capping layer may include at least one among the compounds in Compound Group C.

In an embodiment, the first emission layer may include a first light emitting host and a first light emitting dopant doped in the first light emitting host and including the first compound, and the second emission layer may include a second light emitting host and a second light emitting dopant doped in the second light emitting host and including the second compound.

In an embodiment, the first emission layer may include a first red emission layer that emits red light, a first green emission layer that emits green light, and a first blue emission layer that emits blue light, the second emission layer may include a second red emission layer that emits red light, a second green emission layer that emits green light, and a second blue emission layer that emits blue light, at least one among the first red emission layer, the first green emission layer and the first blue emission layer may include the first compound, and at least one among the second red emission layer, the second green emission layer and the second blue emission layer may include the second compound.

In an embodiment, the first red emission layer, the first green emission layer and the first blue emission layer may be separated from each other on a plane, and the second red emission layer, the second green emission layer and the second blue emission layer may be separated from each other on a plane.

In an embodiment, the first red emission layer may include a first red light emitting host and a first red light emitting dopant doped in the first red light emitting host, the second red emission layer may include a second red light emitting host and a second red light emitting dopant doped in the second red light emitting host, the first green emission layer may include a first green light emitting host and a first green light emitting dopant doped in the first green light emitting host, the second green emission layer may include a second green light emitting host and a second green light emitting dopant doped in the second green light emitting host, at least one among the first red light emitting dopant and the first green light emitting dopant may include the first compound, and at least one among the second red light emitting dopant and the second green light emitting dopant may include the second compound.

In an embodiment, the first red light emitting dopant, the second red light emitting dopant, the first green light emitting dopant and the second green light emitting dopant may be phosphorescence dopants.

In an embodiment, at least one among the first red light emitting dopant and the first green light emitting dopant may be represented by Formula 3-1 or Formula 3-2, and at least one among the second red light emitting dopant and the second green light emitting dopant may be represented by Formula 3-1 or Formula 3-2.

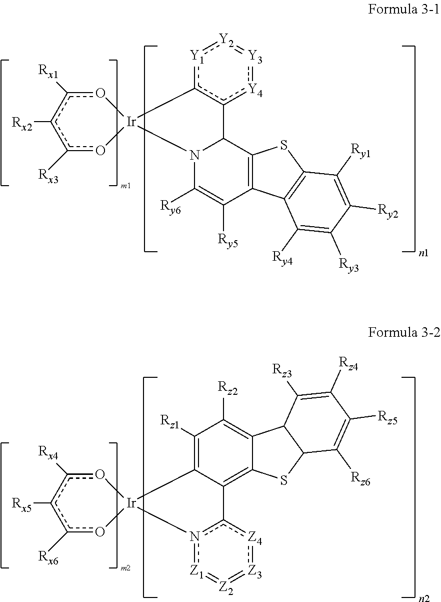

In Formula 3-1 and Formula 3-2, Y₁ to Y₄, and Z₁ to Z₄ are each independently CR_{w} or N, R_{w} and Rₓ₁ to Rₓ₆ are each independently a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined together with an adjacent group to form a ring, R_{y1} to R_{y6}, and R_{z1} to R_{z6} are each independently a hydrogen atom, a deuterium atom, a halogen atom, a cyano group or a substituted or unsubstituted alkyl group of 1 to 20 carbon atoms, m1 and m2 are each independently 0 or 1, and n1 and n2 are each independently 2 or 3, where, if m1 is 0, n1 is 3, if m1 is 1, n1 is 2, if m2 is 0, n2 is 3, and if m2 is 1, n2 is 2.

In an embodiment, at least one among the first red light emitting dopant and the first green light emitting dopant may include at least one among the compounds in Compound Group R, and at least one among the second red light emitting dopant and the second green light emitting dopant may include at least one among the compounds in Compound Group R.

In an embodiment, the first blue emission layer may include a first blue light emitting host and a first blue light emitting dopant doped in the first blue light emitting host, the second blue emission layer may include a second blue light emitting host and a second blue light emitting dopant doped in the second blue light emitting host, and at least one among the first blue light emitting dopant and the second blue light emitting dopant may include at least one among the compounds in Compound Group B.

In an embodiment, the first blue light emitting dopant and the second blue light emitting dopant may be fluorescence dopants.

In an embodiment, the first light emitting unit may further include a first hole transport region between the first electrode and the first emission layer, and a first electron transport region between the first emission layer and the charge generation unit, and the second light emitting unit may further include a second hole transport region between the charge generation unit and the second emission layer, and a second electron transport region between the second emission layer and the second electrode.

In an embodiment, at least one among the first hole transport region, the first emission layer and the first electron transport region may include the first compound, and at least one among the second hole transport region, the second emission layer and the second electron transport region may include the second compound.

In an embodiment, at least one among the first hole transport region and the second hole transport region may include at least one among the compounds in Compound Group HT.

In an embodiment, at least one among the first electron transport region and the second electron transport region may include at least one among the compounds in Compound Group E.

In an embodiment, each of the first hole transport region and the second hole transport region may include a hole transport layer, a hole injection layer, and an emission auxiliary layer, stacked in order from the first electrode.

In an embodiment, the light emitting element may include a first light emitting region that emits red light, a second light emitting region that emits green light, and a third light emitting region that emits blue light, and the first electrode, the first hole transport region, the first electron transport region, the second hole transport region, the second electron transport region, and the second electrode may be provided as common layers in the first light emitting region, the second light emitting region and the third light emitting region.

A display device according to an embodiment of the present disclosure includes a base layer, a circuit layer on the base layer, and a display device layer on the circuit layer and including a light emitting element, wherein the light emitting element includes a first electrode, a first light emitting unit on the first electrode and including a first emission layer, a charge generation unit on the first light emitting unit, a second light emitting unit on the charge generation unit and including a second emission layer, a second electrode on the second light emitting unit, and a capping layer on the second electrode, wherein the first light emitting unit includes a first compound including a first moiety, the second light emitting unit includes a second compound including a second moiety, the capping layer includes a third compound including a third moiety, and the first moiety, the second moiety and the third moiety each independently includes one among benzothiophene, thienopyridine, thienopyrimidine, thienopyridazine, thienopyrazine, thienotriazine, thienotetrazine, benzothiazole, thiazolopyridine, thiazolopyrimidine, thiazolopyridazine, thiazolopyrazine, thiazolotriazine, thiazoloetetrazine, benzothiadiazole, thiadiazolepyridine, thiadiazolepyrimidine, thiadiazolepyridazine, thiadiazolepyrazine, thiadiazoletriazine, and thiadiazoletetrazine.

### BRIEF DESCRIPTION OF THE DRAWINGS

The accompanying drawings are included to provide a further understanding of the subject matter of the present disclosure and are incorporated in and constitute a part of this specification. The drawings illustrate embodiments of the present disclosure and, together with the description, serve to explain principles of the present disclosure. In the drawings:

FIG. 1 is a plan view of a display device according to an embodiment of the present disclosure;

FIG. 2 is a cross-sectional view of a display device according to an embodiment of the present disclosure;

FIG. 3A to FIG. 3D are cross-sectional views schematically showing light emitting elements according to embodiments of the present disclosure;

FIG. 4 is a cross-sectional view schematically showing a light emitting element according to an embodiment of the present disclosure; and

FIG. 5 is a diagram showing a vehicle in which a display device according to an embodiment of the present disclosure is provided.

### DETAILED DESCRIPTION

The subject matter of the present disclosure may have various modifications and may be embodied in different forms, and example embodiments will be explained in more detail with reference to the accompany drawings. The subject matter of the present disclosure may, however, be embodied in different forms and should not be construed as limited to the embodiments set forth herein. Rather, all modifications, equivalents, and substituents which are included in the spirit and technical scope of the present disclosure should be included in the present disclosure.

Like reference numerals refer to like elements throughout. In the drawings, the dimensions of structures are exaggerated for clarity of illustration. It will be understood that, although the terms first, second, etc. may be used herein to describe various elements, these elements should not be limited by these terms. These terms are only used to distinguish one element from another element. Thus, a first element could be termed a second element without departing from the spirit or scope of the present disclosure. Similarly, a second element could be termed a first element. As used herein, the singular forms are intended to include the plural forms as well, unless the context clearly indicates otherwise.

In the description, it will be further understood that the terms “comprises” and/or “comprising,” when used in this specification, specify the presence of stated features, numerals, steps, operations, elements, parts, or the combination thereof, but do not preclude the presence or addition of one or more other features, numerals, steps, operations, elements, parts, or the combination thereof.

In the description, when a layer, a film, a region, a plate, etc. is referred to as being “on” or “above” another part, it can be “directly on” the other part, or intervening layers may also be present. On the contrary, when a layer, a film, a region, a plate, etc. is referred to as being “under” or “below” another part, it can be “directly under” the other part, or intervening layers may also be present. Also, when an element is referred to as being “on” another element, it can be under the other element.

In the description, the term “substituted or unsubstituted” corresponds to substituted or unsubstituted with at least one substituent selected from the group consisting of a deuterium atom, a halogen atom, a cyano group, a nitro group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In some embodiments, each of the exemplified substituents may be substituted or unsubstituted. For example, a biphenyl group may be interpreted as an aryl group or a phenyl group substituted with a phenyl group.

In the description, the term “forming a ring via the combination with an adjacent group” may mean forming a substituted or unsubstituted hydrocarbon ring, or a substituted or unsubstituted heterocycle via the combination with an adjacent group. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocycles or polycycles. In some embodiments, the ring formed via the combination with an adjacent group may be combined together with another ring to form a spiro structure.

In the description, the term “adjacent group” may mean a substituent substituted for an atom which is directly combined together with an atom substituted with a corresponding substituent, another substituent substituted for an atom which is substituted with a corresponding substituent, or a substituent sterically positioned at the nearest position to a corresponding substituent. For example, in 1,2-dimethylbenzene, two methyl groups may be interpreted as “adjacent groups” to each other, and in 1,1-diethylcyclopentene, two ethyl groups may be interpreted as “adjacent groups” to each other. In some embodiments, in 4,5-dimethylphenanthrene, two methyl groups may be interpreted as “adjacent groups” to each other.

In the description, a halogen atom may be a fluorine atom, a chlorine atom, a bromine atom or an iodine atom.

In the description, an alkyl group may be a linear or branched type (or kind). The carbon number of the alkyl group may be 1 to 50, 1 to 30, 1 to 20, 1 to 10, or 1 to 6. Examples of the alkyl group may include methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, 1-methylpentyl, 3-methylpentyl, 2-ethylpentyl, 4-methyl-2-pentyl, n-hexyl, 1-methylhexyl, 2-ethylhexyl, 2-butylhexyl, n-heptyl, 1-methylheptyl, 2,2-dimethylheptyl, 2-ethylheptyl, 2-butylheptyl, 3-methylheptyl, n-octyl, t-octyl, 2-ethyloctyl, 2-butyloctyl, 2-hexyloctyl, 3,7-dimethyloctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldocecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-henicosyl, n-docosyl, n-tricosyl, n-tetracosyl, n-pentacosyl, n-hexacosyl, n-heptacosyl, n-octacosyl, n-nonacosyl, n-triacontyl, etc., without limitation.

In the description, a cycloalkyl group may mean a ring-type alkyl group. The carbon number of the cycloalkyl group may be 3 to 50, 3 to 30, or 3 to 20, 3 to 10. Examples of the cycloalkyl group include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., without limitation.

In the description, an alkenyl group means a hydrocarbon group including one or more carbon double bonds at a main chain (e.g., in the middle) or at a terminal end (e.g., the terminus) of an alkyl group having a carbon number of 2 or more. The alkenyl group may be a linear chain or a branched chain. The carbon number is not specifically limited, but may be 2 to 30, 2 to 20, or 2 to 10. Examples of the alkenyl group include a vinyl group, a 1-butenyl group, a 1-pentenyl group, a 1,3-butadienyl aryl group, a styrenyl group, a styrylvinyl group, etc., without limitation.

In the description, an alkynyl group means a hydrocarbon group including one or more carbon triple bonds at a main chain (e.g., in the middle) or at a terminal end (e.g., the terminus) of an alkyl group having a carbon number of 2 or more. The alkynyl group may be a linear chain or a branched chain. The carbon number is not specifically limited, but may be 2 to 30, 2 to 20, or 2 to 10. Examples of the alkynyl group include an ethynyl group, a propynyl group, etc., without limitation.

In the description, a hydrocarbon ring group means an optional functional group or substituent derived from an aliphatic hydrocarbon ring. The hydrocarbon ring group may be a saturated hydrocarbon ring group of 5 to 20 ring-forming carbon atoms.

In the description, an aryl group means an optional functional group or substituent derived from an aromatic hydrocarbon ring. The aryl group may be a monocyclic aryl group or a polycyclic aryl group. The carbon number for forming rings in the aryl group may be 6 to 30, 6 to 20, or 6 to 15. Examples of the aryl group may include phenyl, naphthyl, fluorenyl, anthracenyl, phenanthryl, biphenyl, terphenyl, quaterphenyl, quinquephenyl, sexiphenyl, triphenylenyl, pyrenyl, benzofluoranthenyl, chrysenyl, etc., without limitation.

In the description, a fluorenyl group may be substituted, and two substituents may be combined together with each other to form a spiro structure. Examples of a substituted fluorenyl group are as follows, but embodiments of the present disclosure are not limited thereto.

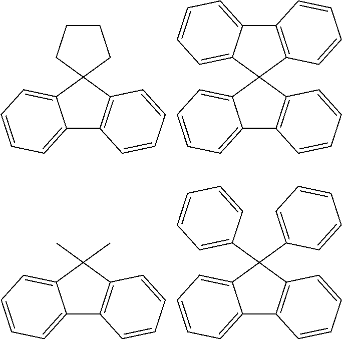

In the description, a heterocyclic group means an optional functional group or substituent derived from a ring including one or more among B, O, N, P, Si, and S as heteroatoms. The heterocyclic group includes an aliphatic heterocyclic group and an aromatic heterocyclic group. The aromatic heterocyclic group may be a heteroaryl group. The aliphatic heterocyclic group and the aromatic heterocyclic group may be a monocycle or a polycycle.

In the description, a heterocyclic group may include one or more among B, O, N, P, Si, and S as heteroatoms. If the heterocyclic group includes two or more heteroatoms, two or more heteroatoms may be the same or different. The heterocyclic group may be a monocyclic heterocyclic group or a polycyclic heterocyclic group, and the term encompasses a heteroaryl group. The ring-forming carbon of the heterocyclic group may be 2 to 30, 2 to 20, or 2 to 10.

In the description, an aliphatic heterocyclic group may include one or more among B, O, N, P, Si, and S as heteroatoms. The number of ring-forming carbon atoms of the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., without limitation.

In the description, a heteroaryl group may include one or more among B, O, N, P, Si, and S as heteroatoms. If the heteroaryl group includes two or more heteroatoms, two or more heteroatoms may be the same or different. The heteroaryl group may be a monocyclic heterocyclic group or polycyclic heterocyclic group. The carbon number for forming rings of the heteroaryl group may be 2 to 30, 2 to 20, or 2 to 10. Examples of the heteroaryl group may include thiophene, furan, pyrrole, imidazole, pyridine, bipyridine, pyrimidine, triazine, acridyl, pyridazine, pyrazinyl, quinoline, quinazoline, quinoxaline, phenoxazine, phthalazine, pyrido pyrimidine, pyrido pyrazine, pyrazino pyrazine, isoquinoline, indole, carbazole, N-arylcarbazole, N-heteroarylcarbazole, N-alkylcarbazole, benzoxazole, benzoimidazole, benzothiazole, benzocarbazole, benzothiophene, dibenzothiophene, thienothiophene, benzofuran, phenanthroline, thiazole, isoxazole, oxazole, oxadiazole, thiadiazole, phenothiazine, dibenzosilole, dibenzofuran, etc., without limitation. The heteroaryl group including S as a heteroatom may include thienopyridine, thienopyrimidine, thienopyridazine, thienopyrazine, thienotriazine, thienotetrazine, thiazolopyridine, thiazolopyrimidine, thiazolopyridazine, thiazolopyrazine, thiazolotriazine, thiazoloetetrazine, benzothiadiazole, thiadiazolepyridine, thiadiazolepyrimidine, thiadiazolepyridazine, thiadiazolepyrazine, thiadiazoletriazine, thiadiazoletetrazine, and/or the like, in addition to benzothiophene.

In the description, the same explanation on the above-described aryl group may be applied to an arylene group except that the arylene group is a divalent group. The same explanation on the above-described heteroaryl group may be applied to a heteroarylene group except that the heteroarylene group is a divalent group.

In the description, a silyl group includes an alkyl silyl group and an aryl silyl group. Examples of the silyl group include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., without limitation.

In the description, the carbon number of a carbonyl group is not specifically limited, but the carbon number may be 1 to 40, 1 to 30, or 1 to 20. For example, the carbonyl group may have the structures below, but is not limited thereto.

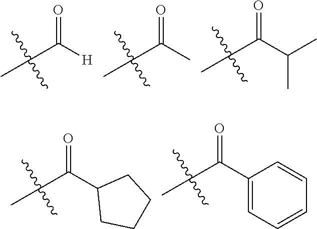

In the description, the carbon number of a sulfinyl group and sulfonyl group is not specifically limited, but may be 1 to 30. The sulfinyl group may include an alkyl sulfinyl group and an aryl sulfinyl group. The sulfonyl group may include an alkyl sulfonyl group and an aryl sulfonyl group.

In the description, a thio group may include an alkyl thio group and an aryl thio group. The thio group may mean the above-defined alkyl group or aryl group combined together with a sulfur atom. Examples of the thio group include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., without limitation.

In the description, an oxy group may mean the above-defined alkyl group or aryl group which is combined together with an oxygen atom. The oxy group may include an alkoxy group and an aryl oxy group. The alkoxy group may be a linear, branched or cyclic chain. The carbon number of the alkoxy group is not specifically limited but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc. However, embodiments of the present disclosure are not limited thereto.

In the description, a boron group may mean the above-defined alkyl group or aryl group, combined together with a boron atom. The boron group includes an alkyl boron group and an aryl boron group. Examples of the boron group include a dimethylboron group, a diethylboron group, a t-butylmethylboron group, a diphenylboron group, a phenylboron group, etc., without limitation.

In the description, the carbon number of an amine group is not specifically limited, but may be 1 to 30. The amine group may include an alkyl amine group and an aryl amine group. Examples of the amine group include a methylamine group, a dimethylamine group, a phenylamine group, a diphenylamine group, a naphthylamine group, a 9-methyl-anthracenylamine group, etc., without limitation.

In the description, alkyl groups in an alkylthio group, alkylsulfoxy group, alkylaryl group, alkylboron group, alkyl silyl group, and alkyl amine group may be the same as the examples of the above-described alkyl group.

In the description, aryl groups in an aryloxy group, arylthio group, arylsulfoxy group, arylboron group, aryl silyl group, and aryl amine group may be the same as the examples of the above-described aryl group.

In the description, a direct linkage may mean a single bond (e.g., a single covalent bond or a single coordinate covalent bond, which may also be referred to as a dative bond).

In the description,

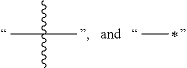

mean positions to be connected.

Hereinafter, embodiments of the present disclosure will be explained referring to the drawings.

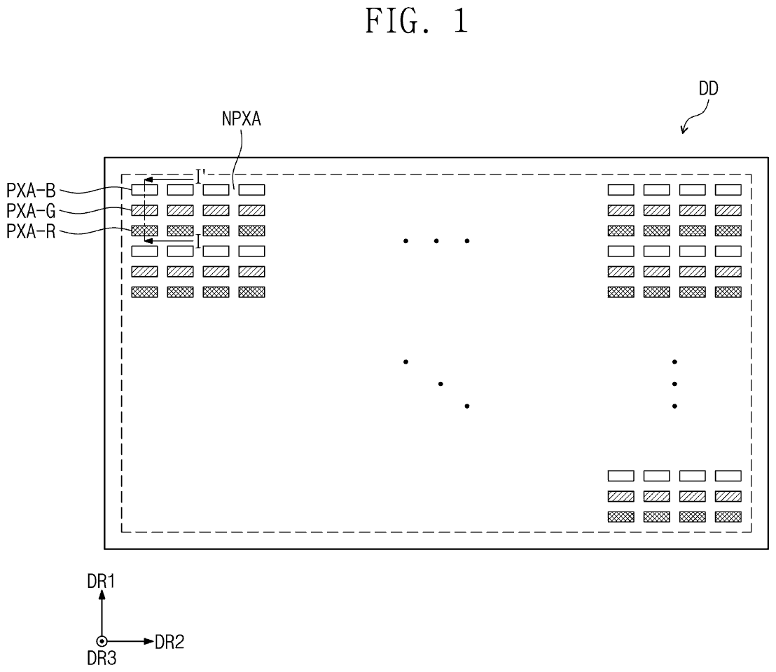

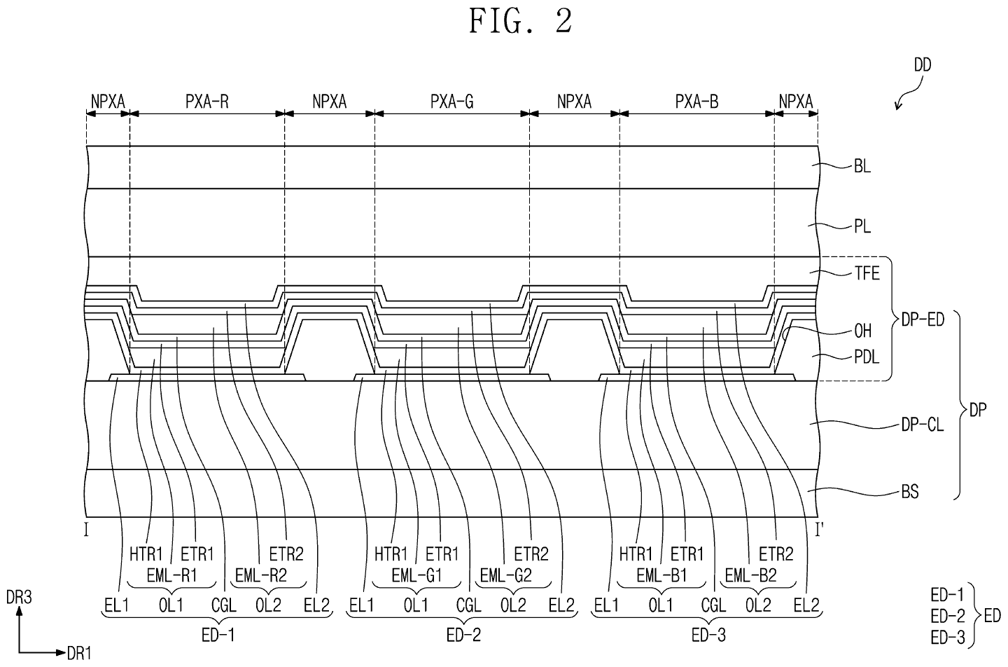

FIG. 1 is a plan view showing an embodiment of a display device DD. FIG. 2 is a cross-sectional view of a display device DD of an embodiment. FIG. 2 is a cross-sectional view showing a part corresponding to line I-I′ of FIG. 1.

A display device DD includes a display panel DP and an optical layer PL on the display panel DP. The display panel DP may include light emitting elements ED-1, ED-2 and ED-3. The display device DD includes a plurality of light emitting elements ED-1, ED-2 and ED-3. The optical layer PL may be on the display panel DP and control reflected light by external light at the display panel DP. The optical layer PL may include, for example, a polarization layer and/or a color filter layer. In some embodiments, the optical layer PL may be omitted from the display device DD.

On the optical layer PL, a base substrate BL may be provided. The base substrate BL may be a member providing a base surface where the optical layer PL is provided. The base substrate BL may be a glass substrate, a metal substrate, a plastic substrate, etc. However, embodiments of the present disclosure are not limited thereto, and the base substrate BL may be an inorganic layer, an organic layer or a composite material layer. In some embodiments, the base substrate BL may be omitted.

The display device DD according to an embodiment may further include a plugging layer. The plugging layer may be between a display device layer DP-ED and a base substrate BL. The plugging layer may be an organic layer. The plugging layer may include at least one among an acrylic resin, a silicon-based resin and an epoxy-based resin.

The display panel DP may include a base layer BS, a circuit layer DP-CL provided on the base layer BS and a display device layer DP-ED. The display device layer DP-ED may include a pixel definition layer PDL, light emitting elements ED-1, ED-2 and ED-3 in the pixel definition layer PDL, and an encapsulating layer TFE on the light emitting elements ED-1, ED-2 and ED-3.

The base layer BS may be a member providing a base surface where the display device layer DP-ED is provided. The base layer BS may be a glass substrate, a metal substrate, a plastic substrate, etc. However, embodiments of the present disclosure are not limited thereto, and the base layer BS may be an inorganic layer, an organic layer or a composite material layer.

In an embodiment, the circuit layer DP-CL may be on the base layer BS, and the circuit layer DP-CL may include a plurality of transistors. Each of the transistors may include a control electrode, an input electrode, and an output electrode. For example, the circuit layer DP-CL may include switching transistors and driving transistors for driving the light emitting elements ED-1, ED-2 and ED-3 of the display device layer DP-ED.

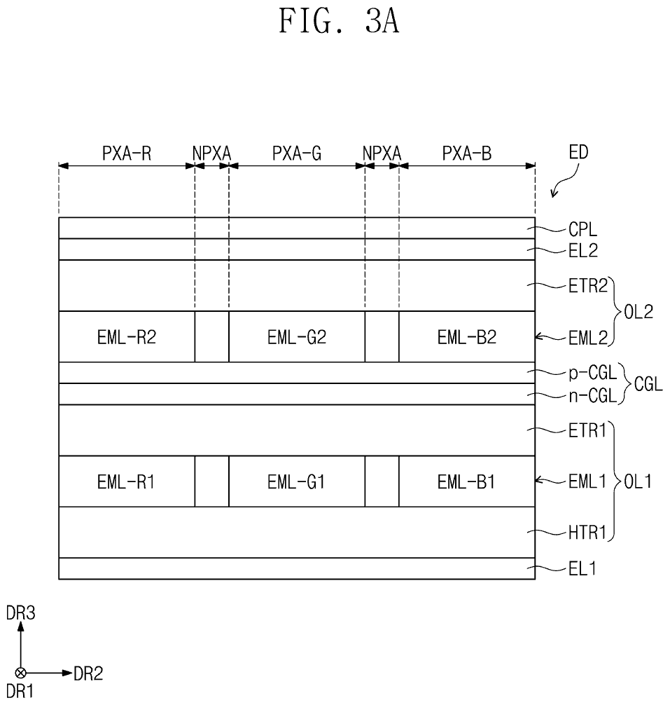

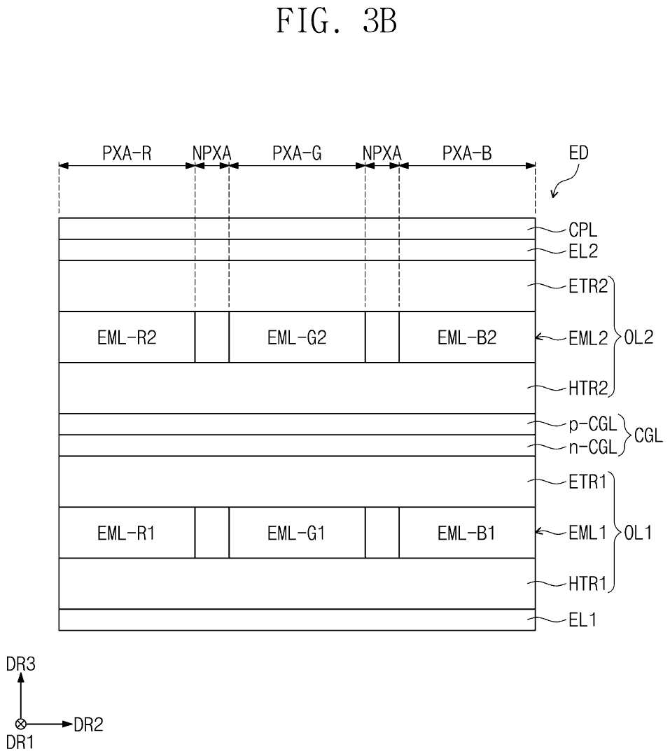

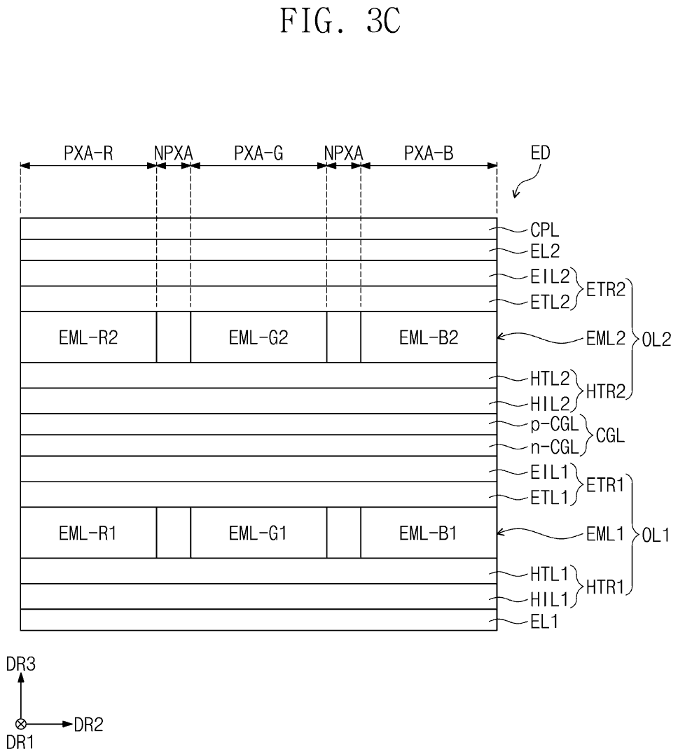

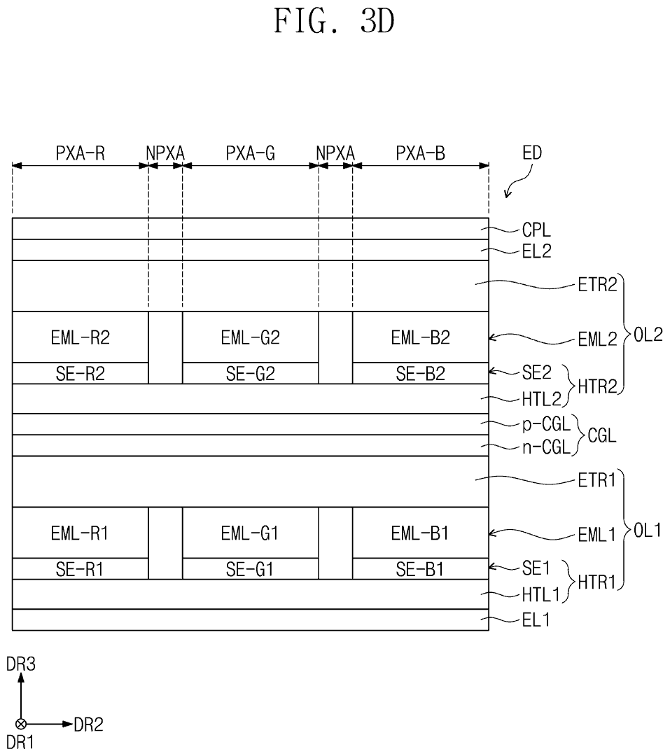

Light emitting elements ED-1, ED-2 and ED-3 may include a first light emitting element ED-1, a second light emitting element ED-2, and a third light emitting element ED-3. Each of the light emitting elements ED-1, ED-2 and ED-3 may have the structures of the light emitting elements ED of embodiments according to FIG. 3A to FIG. 3D, which will be further explained below. Each of the light emitting elements ED-1, ED-2 and ED-3 may include a first light emitting unit OL1, a charge generation unit CGL, a second light emitting unit OL2, and a second electrode EL2. Each of the light emitting elements ED-1, ED-2 and ED-3 may be a light emitting element of a tandem structure. In each of the light emitting elements ED-1, ED-2 and ED-3, the two light emitting units may emit light in the same wavelength region.

The first light emitting unit OL1 may include a first hole transport region HTR1, first emission layers EML-R1, EML-G1 and EML-B1, and a first electron transport region ETR1. The second light emitting unit OL2 may include second emission layers EML-R2, EML-G2 and EML-B2, and a second electron transport region ETR2. FIG. 2 illustrates an embodiment in which the first and second emission layers EML-R1, EML-G1, EML-B1, EML-R2, EML-G2 and EML-B2 of the light emitting elements ED-1, ED-2 and ED-3 are in the opening parts OH defined in the pixel definition layer PDL, and the first hole transport region HTR1, the first and second electron transport regions ETR1 and ETR2, the charge generation unit CGL and the second electrode EL2 are provided as common layers on the whole light emitting elements ED-1, ED-2 and ED-3. However, embodiments of the present disclosure are not limited thereto, and different from FIG. 2, in an embodiment, at least a portion of the first hole transport region HTR1, the first and second electron transport regions ETR1 and ETR2, and the charge generation unit CGL may be patterned in the opening parts OH defined in the pixel definition layer PDL and provided as pattern layers. In the description, the “common layer” may be commonly provided over the whole light emitting elements ED-1, ED-2 and ED-3 to form substantially one element, and the “pattern layer” may be patterned and separately provided in the opening parts OH defined in the pixel definition layer PDL. For example, in an embodiment, the first hole transport region HTR1, the first and second emission layers EML-R1, EML-G1, EML-B1, EML-R2, EML-G2 and EML-B2, the charge generation unit CGL and the first and second electron transport regions ETR1 and ETR2 of the light emitting elements ED-1, ED-2 and ED-3 may be patterned by an ink jet printing method as necessary and provided.

An encapsulating layer TFE may cover the light emitting elements ED-1, ED-2 and ED-3. The encapsulating layer TFE may encapsulate the display device layer DP-ED. The encapsulating layer TFE may be a thin film encapsulating layer. The encapsulating layer TFE may be one layer or a stacked layer of a plurality of layers. The encapsulating layer TFE includes at least one insulating layer (e.g., an electrically insulating layer). The encapsulating layer TFE according to an embodiment may include at least one inorganic layer (hereinafter, encapsulating inorganic layer). In some embodiments, the encapsulating layer TFE according to an embodiment may include at least one organic layer (hereinafter, encapsulating organic layer) and at least one encapsulating inorganic layer.

The encapsulating inorganic layer protects the display device layer DP-ED from moisture/oxygen, and the encapsulating organic layer protects the display device layer DP-ED from foreign materials such as dust particles. The encapsulating inorganic layer may include silicon nitride, silicon oxy nitride, silicon oxide, titanium oxide, and/or aluminum oxide, without specific limitation. The encapsulating organic layer may include an acrylic compound, an epoxy-based compound, etc. The encapsulating organic layer may include a photopolymerizable organic material, without specific limitation.

The encapsulating layer TFE may be on the second electrode EL2 and may be provided while filling the opening parts OH.

Referring to FIG. 1 and FIG. 2, the display device DD may include a non-light emitting region NPXA and light emitting regions PXA-R, PXA-G and PXA-B. The light emitting regions PXA-R, PXA-G and PXA-B may be regions that emit light produced from the light emitting elements ED-1, ED-2 and ED-3, respectively. The light emitting regions PXA-R, PXA-G and PXA-B may be separated from each other on a plane.

The light emitting regions PXA-R, PXA-G and PXA-B may be regions separated by the pixel definition layer PDL. The non-light emitting regions NPXA may be regions between neighboring light emitting regions PXA-R, PXA-G and PXA-B and may be regions corresponding to the pixel definition layer PDL. In some embodiments, each of the light emitting regions PXA-R, PXA-G and PXA-B may correspond to each pixel. The pixel definition layer PDL may divide the light emitting elements ED-1, ED-2 and ED-3. The first emission layers EML-R1, EML-G1 and EML-B1 and the second emission layers EML-R2, EML-G2 and EML-B2 of the light emitting elements ED-1, ED-2 and ED-3 may be provided and divided in the opening parts OH defined in the pixel definition layer PDL.

The light emitting regions PXA-R, PXA-G and PXA-B may be divided into a plurality of groups according to the color of light produced from the light emitting elements ED-1, ED-2 and ED-3. In the display device DD of an embodiment, shown in FIG. 1 and FIG. 2, three light emitting regions PXA-R, PXA-G and PXA-B emitting red light, green light and blue light are illustrated as embodiments. For example, the display device DD of an embodiment may include a first light emitting region of a red light emitting region PXA-R, a second light emitting region of a green light emitting region PXA-G and a third light emitting region of a blue light emitting region PXA-B, which are separated from each other.

In the display device DD according to an embodiment, a plurality of light emitting elements ED-1, ED-2 and ED-3 may emit light having different wavelength regions. For example, in an embodiment, the display device DD may include a first light emitting element ED-1 that emits red light, a second light emitting element ED-2 that emits green light, and a third light emitting element ED-3 that emits blue light. In some embodiments, each of the red light emitting region PXA-R, the green light emitting region PXA-G, and the blue light emitting region PXA-B of the display device DD may correspond to the first light emitting element ED-1, the second light emitting element ED-2, and the third light emitting element ED-3.

However, embodiments of the present disclosure are not limited thereto, and the first to third light emitting elements ED-1, ED-2 and ED-3 may emit light in the same wavelength region, or at least one thereof may emit light in a different wavelength region.

The light emitting regions PXA-R, PXA-G and PXA-B in the display device DD according to an embodiment may be provided in a stripe shape. Referring to FIG. 1, a plurality of red light emitting regions PXA-R, a plurality of green light emitting regions PXA-G and a plurality of blue light emitting regions PXA-B may be provided along a second directional axis DR2. In some embodiments, the red light emitting regions PXA-R, the green light emitting regions PXA-G and the blue light emitting regions PXA-B may be provided by turns (e.g., sequentially) along a first directional axis DR1.

In FIG. 1 and FIG. 2, the areas of the light emitting regions PXA-R, PXA-G and PXA-B are shown to be similar, but embodiments of the present disclosure are not limited thereto. The areas of the light emitting regions PXA-R, PXA-G and PXA-B may be different from each other according to the wavelength region of light emitted. In some embodiments, the areas of the light emitting regions PXA-R, PXA-G and PXA-B may mean areas on a plane defined by the first directional axis DR1 and the second directional axis DR2.

In some embodiments, the arrangement type of the light emitting regions PXA-R, PXA-G and PXA-B is not limited to the configuration shown in FIG. 1, and the arrangement order of the red light emitting regions PXA-R, the green light emitting regions PXA-G and the blue light emitting regions PXA-B may be provided in various suitable combinations according to the properties of display quality required or desired for the display device DD. For example, the arrangement type of the light emitting regions PXA-R, PXA-G and PXA-B may be a PENTILE® arrangement structure (e.g., an RGBG matrix, RGBG structure, or RGBG matrix structure) or a DIAMOND PIXEL™ arrangement structure, but the present disclosure is not limited thereto. PENTILE® is a duly registered trademark of Samsung Display Co., Ltd.

In some embodiments, the areas of the light emitting regions PXA-R, PXA-G and PXA-B may be different from each other. For example, in an embodiment, the area of the green light emitting region PXA-G may be smaller than the area of the blue light emitting region PXA-B, but embodiments of the present disclosure are not limited thereto.

FIG. 3A to FIG. 3D are cross-sectional views schematically showing light emitting elements according to embodiments.

Referring to FIG. 3A, the light emitting element ED according to an embodiment may include a first electrode EL1, a first light emitting unit OL1, a charge generation unit CGL, a second light emitting unit OL2, a second electrode EL2 and a capping layer CPL. In the light emitting element ED, the first light emitting unit OL1 may include a first hole transport region HTR1, a first emission layer EML1, and a first electron transport region ETR1, stacked in order, and the second light emitting unit OL2 may include a second emission layer EML2, and a second electron transport region ETR2, stacked in order.

Compared to FIG. 3A, FIG. 3B shows a cross-sectional view of a light emitting element ED in which the second light emitting unit OL2 further includes a second hole transport region HTR2 under the second emission layer EML2. Compared to FIG. 3B, FIG. 3C shows a cross-sectional view of a light emitting element ED in which the first and second hole transport regions HTR1 and HTR2 include first and second hole injection layers HIL1 and HIL2, and first and second hole transport layers HTL1 and HTL2, respectively, and the first and second electron transport regions ETR1 and ETR2 include first and second electron injection layers EIL1 and EIL2, and first and second electron transport layers ETL1 and ETL2, respectively. Compared to FIG. 3B, FIG. 3D shows a cross-sectional view of a light emitting element ED in which the first and second hole transport regions HTR1 and HTR2 include first and second emission auxiliary layers SE-R1, SE-G1, SE-B1, SER2, SE-G2 and SE-B2, and first and second hole injection layers HIL1 and HIL2, respectively.

Hereinafter, the constituent elements included in each of the light emitting elements ED will be explained referring to FIG. 3A to FIG. 3D.

The first electrode EL1 has conductivity (e.g., electrical conductivity). The first electrode EL1 may be formed using a metal material, a metal alloy and/or a conductive compound (e.g., an electrically conductive compound). The first electrode EL1 may be an anode or a cathode. However, embodiments of the present disclosure are not limited thereto. In addition, the first electrode EL1 may be a pixel electrode.

The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn and Zn, compounds of two or more selected therefrom, mixtures of two or more selected therefrom, and/or oxides thereof.

If the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). If the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/AI (a stacked structure of LiF and Al), Mo, Ti, W, compounds thereof, or mixtures thereof (for example, a mixture of Ag and Mg). In some embodiments, the first electrode EL1 may have a structure of a plurality of layers including a reflective layer or a transflective layer formed using the above materials, and a transmissive conductive layer formed using ITO, IZO, ZnO, and/or ITZO. For example, the first electrode EL1 may have a three-layer structure of ITO/Ag/ITO. However, embodiments of the present disclosure are not limited thereto. The first electrode EL1 may include the above-described metal materials, combinations of two or more metal materials selected from the above-described metal materials, and/or oxides of the above-described metal materials. The thickness of the first electrode EL1 may be from about 700 Å to about 10,000 Å. For example, the thickness of the first electrode EL1 may be from about 1,000 Å to about 3,000 Å.

The first light emitting unit OL1 is provided on the first electrode EL1. The charge generation unit CGL is provided on the first light emitting unit OL1. The charge generation unit CGL may be provided on the first electron transport region ETR1 of the first light emitting unit OL1. The second light emitting unit OL2 is provided on the charge generation unit CGL.

The first light emitting unit OL1 includes a first compound containing a first moiety. The second light emitting unit OL2 includes a second compound containing a second moiety. The first compound and the second compound may be compounds including the first moiety and the second moiety, respectively. For example, the first compound may be a metal complex in which a substituent including the first moiety is bonded to a metal as a ligand, and the second compound may be a metal complex in which a substituent including the second moiety is bonded to a metal as a ligand. However, the types of the first and second compounds are not limited thereto, and the first and second compounds may have diverse chemical formulae as long as the first and second moieties are included as portions of their structures, without limitation. In some embodiments, the first compound and the second compound may have the same chemical structure or different chemical structures, as necessary or desired. The first compound and the second compound will be explained in more detail in the description on the emission layers EML1 and EML2 included in the light emitting units OL1 and OL2, which will be further explained.

The first moiety and the second moiety each independently include one among benzothiophene, thienopyridine, thienopyrimidine, thienopyridazine, thienopyrazine, thienotriazine, thienotetrazine, benzothiazole, thiazolopyridine, thiazolopyrimidine, thiazolopyridazine, thiazolopyrazine, thiazolotriazine, thiazoloetetrazine, benzothiadiazole, thiadiazolepyridine, thiadiazolepyrimidine, thiadiazolepyridazine, thiadiazolepyrazine, thiadiazoletriazine, and thiadiazoletetrazine. For example, the first moiety and the second moiety may each independently include one among benzothiophene, thienopyridine, benzothiazole, and thiazolopyridine. In some embodiments, the term “including the first moiety” may mean “including a chemical structure including the first moiety as a portion”. For example, “including the first moiety of the above-described benzothiophene, benzothiazole, or thienopyridine” may mean “including a chemical structure of benzothiophene, benzothiazole, or thienopyridine including the first moiety as a portion”, but embodiments of the present disclosure are not limited thereto.

The first light emitting unit OL1 may include a first hole transport region HTR1, a first emission layer EML1, and a first electron transport region ETR1, stacked in order. The second light emitting unit OL2 may include a second emission layer EML2 and a second electron transport region ETR2, stacked in order. In an embodiment, the second light emitting unit OL2 may include a second hole transport region HTR2, a second emission layer EML2, and a second electron transport region ETR2, stacked in order.

At least one among the first hole transport region HTR1, the first emission layer EML1, and the first electron transport region ETR1 of the first light emitting unit OL1 may include the first compound including the first moiety. At least one among the second hole transport region HTR2, the second emission layer EML2, and the second electron transport region ETR2 of the second light emitting unit OL2 may include the second compound including the second moiety. For example, the first and second emission layers EML1 and EML2 of the first and second light emitting units OL1 and OL2 may include the first and second compounds, respectively. In some embodiments, each of the first hole transport region HTR1, the first emission layer EML1, and the first electron transport region ETR1 of the first light emitting unit OL1 may include the first compound, and each of the second hole transport region HTR2, the second emission layer EML2, and the second electron transport region ETR2 of the second light emitting unit OL2 may include the second compound.

The hole transport regions HTR1 and HTR2 may include at least one among hole injection layers HIL1 and HIL2, hole transport layers HTL1 and HTL2, emission auxiliary layers SE1 and SE2, and an electron blocking layer. The thickness of each of the hole transport regions HTR1 and HTR2 may be, for example, about 50 Å to about 15,000 Å.

Each of the hole transport regions HTR1 and HTR2 may have a single layer formed using a single material, a single layer formed using a plurality of different materials, or a multilayer structure including a plurality of layers formed using a plurality of different materials.

For example, the hole transport regions HTR1 and HTR2 may have the structure of a single layer of hole injection layers HIL1 and HIL2 or hole transport layers HTL1 and HTL2, respectively, and may have a structure of a single layer formed using a hole injection material and a hole transport material. In some embodiments, the hole transport regions HTR1 HTR2 may have structures of single layers formed using a plurality of different materials, or structures stacked from the first electrode EL1 of hole injection layers HIL1 and HIL2/hole transport layers HTL1 and HTL2, hole injection layers HIL1 and HIL2/hole transport layers HTL1 and HTL2/emission auxiliary layers SE1 and SE2, or hole injection layers HIL1 and HIL2/hole transport layers HTL1 and HTL2/electron blocking layer, respectively, but embodiments of the present disclosure are not limited thereto. If the hole transport regions HTR1 and HTR2 include the emission auxiliary layers SE1 and SE2, respectively, the emission auxiliary layers SE1 and SE2 may be pattern layers patterned and provided in opening parts OH (see FIG. 2). For example, the emission auxiliary layers SE1 and SE2 may include red emission auxiliary layers SE-R1 and SE-R2, green emission auxiliary layers SE-G1 and SE-G2, and blue emission auxiliary layers SE-B1 and SE-B2, which are overlapping with the first light emitting region PXA-R. The emission auxiliary layers SE1 and SE2 may compensate a resonance distance according to the wavelength of light emitted from the emission layers EML1 and EML2 and control hole charge balance to increase light emission efficiency. In some embodiments, the emission auxiliary layers SE1 and SE2 may play the role of preventing or reducing electron injection to the hole transport regions HTR1 and HTR2.

The hole transport regions HTR1 and HTR2 may be formed using various suitable methods such as a vacuum deposition method, a spin coating method, a cast method, a Langmuir-Blodgett (LB) method, an inkjet printing method, a laser printing method, and/or a laser induced thermal imaging (LITI) method.

Each of the hole transport regions HTR1 and HTR2 may include a compound represented by Formula H-1.

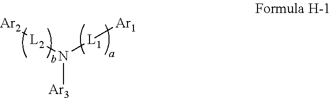

In Formula H-1 above, L₁ and L₂ may be each independently a direct linkage, a substituted or unsubstituted arylene group of 6 to 30 ring-forming carbon atoms, or a substituted or unsubstituted heteroarylene group of 2 to 30 ring-forming carbon atoms. “a” and “b” may be each independently an integer of 0 to 10. In some embodiments, if “a” or “b” is an integer of 2 or more, a plurality of L₁ and L₂ may be each independently a substituted or unsubstituted arylene group of 6 to 30 ring-forming carbon atoms, or a substituted or unsubstituted heteroarylene group of 2 to 30 ring-forming carbon atoms.

In Formula H-1, Ar₁ and Ar₂ may be each independently a substituted or unsubstituted aryl group of 6 to 30 ring-forming carbon atoms, or a substituted or unsubstituted heteroaryl group of 2 to 30 ring-forming carbon atoms. In some embodiments, in Formula H-1, Ar₃ may be a substituted or unsubstituted aryl group of 6 to 30 ring-forming carbon atoms or a substituted or unsubstituted heteroaryl group of 2 to 30 ring-forming carbon atoms.

The compound represented by Formula H-1 may be a monoamine compound. In some embodiments, the compound represented by Formula H-1 may be a diamine compound in which at least one among Ar₁ to Ar₃ includes an amine group as a substituent. In some embodiments, the compound represented by Formula H-1 may be a carbazole-based compound in which at least one among Ar₁ and Ar₂ includes a substituted or unsubstituted carbazole group, or a fluorene-based compound in which at least one among Ar₁ and Ar₂ includes a substituted or unsubstituted fluorene group.

The compound represented by Formula H-1 may be represented by one among the compounds in Compound Group H below. However, the compounds shown in Compound Group H are only examples, and the compound represented by Formula H-1 is not limited to the compounds represented in Compound Group H below.

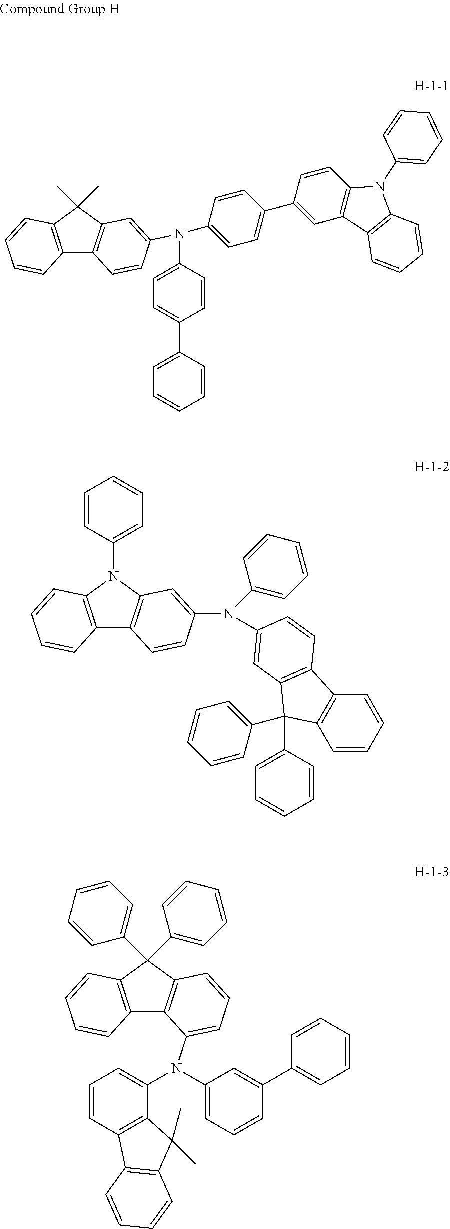 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

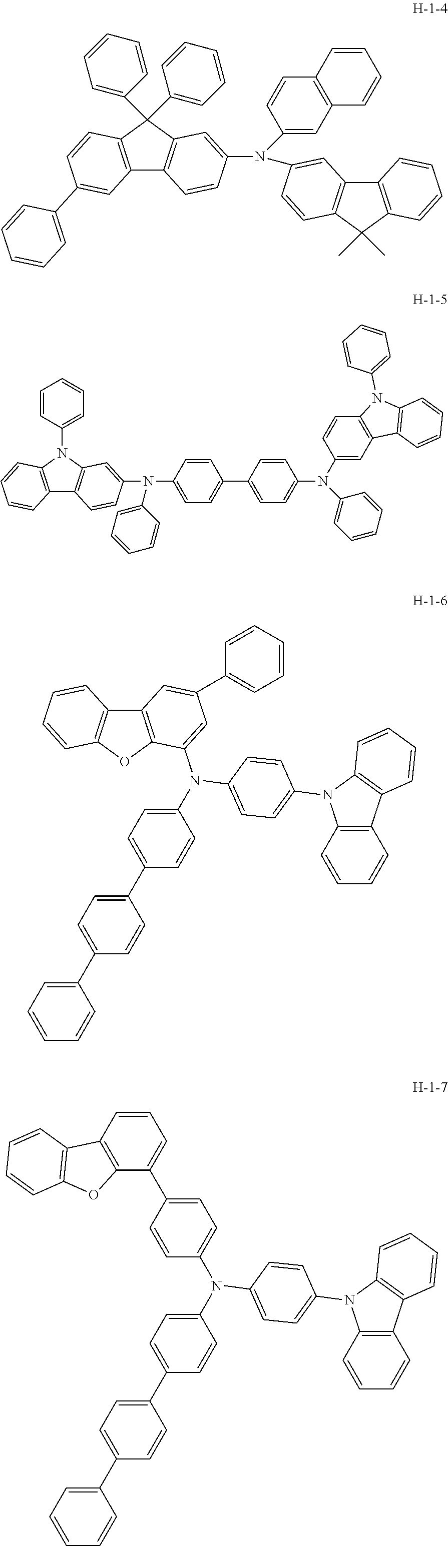 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

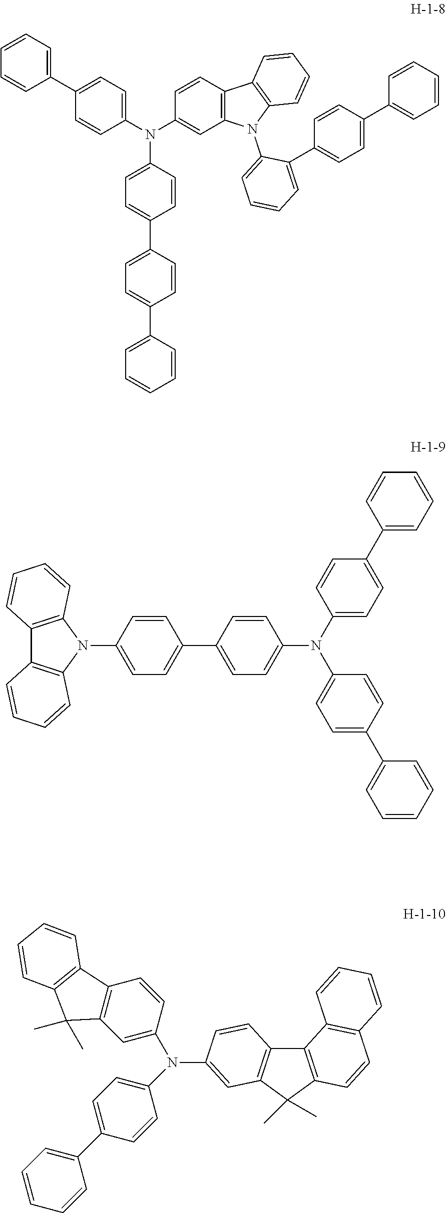 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

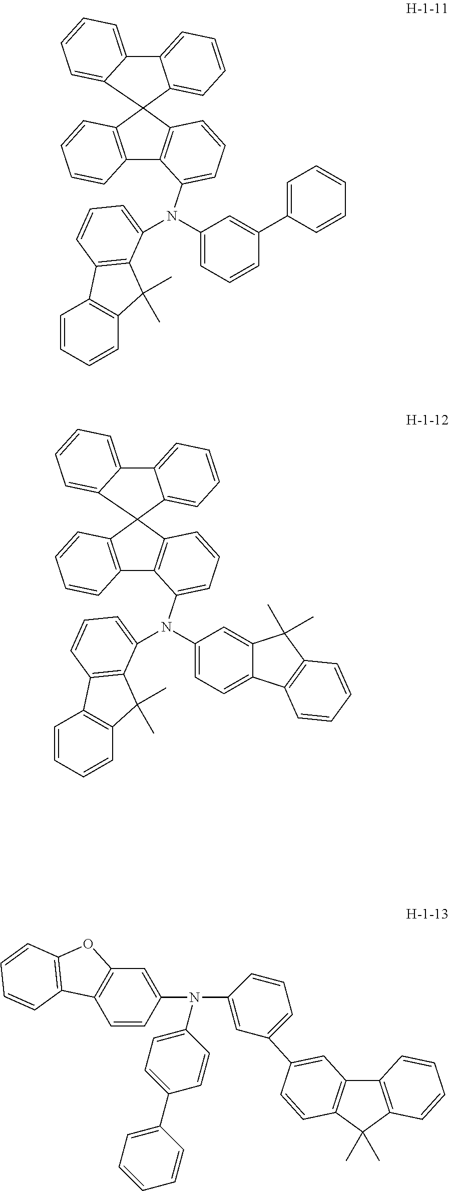 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

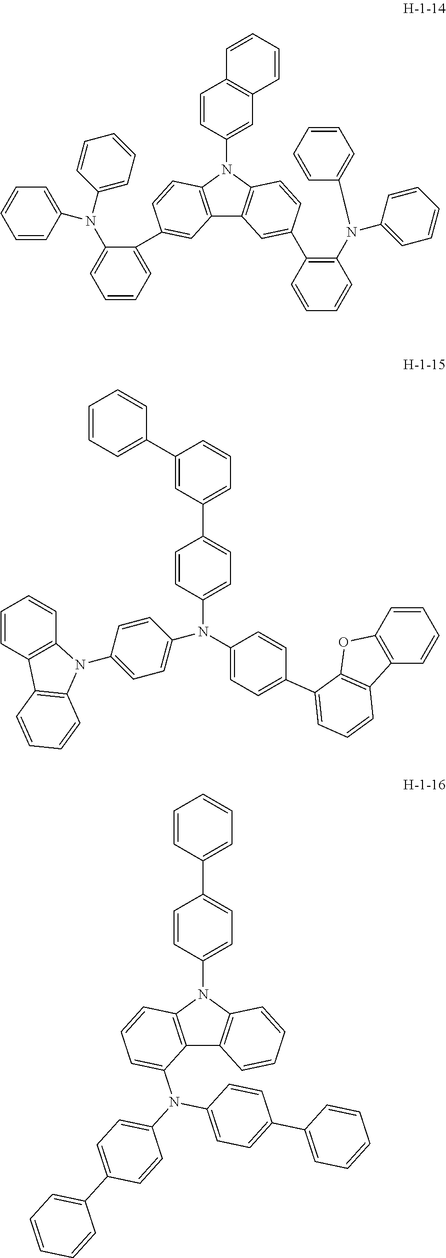 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

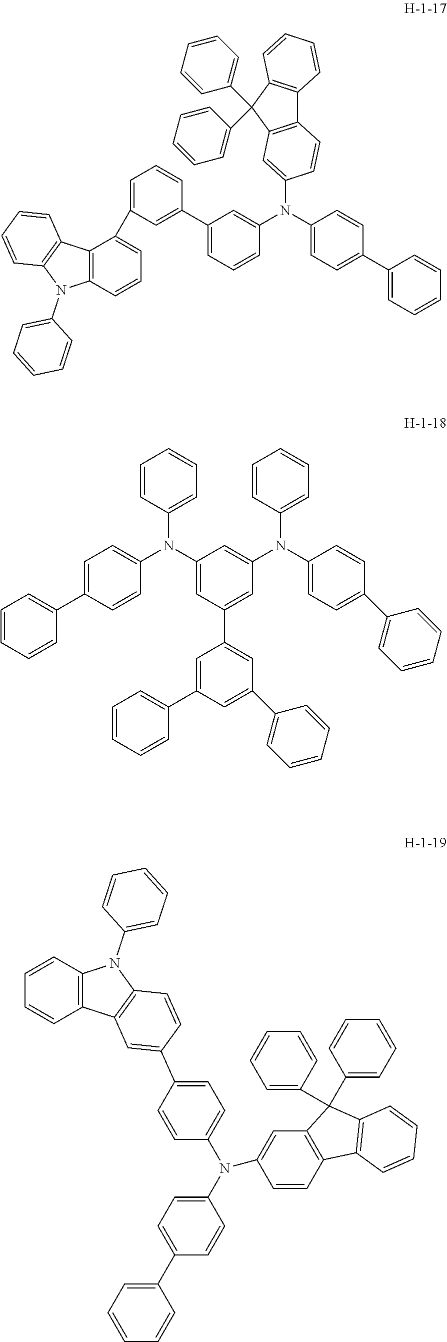 [SMILES: c1ccc(-c2ccc(N(c3cccc(-c4cccc(-c5cccc6c5c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

In an embodiment, the first hole transport region HTR1 may include the first compound including the first moiety among the compounds represented by Formula H-1. The second hole transport region HTR2 may include the second compound including the second moiety among the compounds represented by Formula H-1. That is, the first and second hole transport regions HTR1 and HTR2 may include the first compound represented by Formula H-1 and the second compound represented by Formula H-1, respectively.

In Formula H-1, L₁ and L₂ may be a substituted or unsubstituted heteroarylene group of 2 to 30 ring-forming carbon atoms, including the first moiety or the second moiety. For example, L₁ and L₂ may be each independently one among a substituted or unsubstituted benzothiophene group, a substituted or unsubstituted thienopyridine group, a substituted or unsubstituted thienopyrimidine group, a substituted or unsubstituted thienopyridazine group, a substituted or unsubstituted thienopyrazine group, a substituted or unsubstituted thienotriazine group, a substituted or unsubstituted thienotetrazine group, a substituted or unsubstituted benzothiazole group, a substituted or unsubstituted thiazolopyridine group, a substituted or unsubstituted thiazolopyrimidine group, a substituted or unsubstituted thiazolopyridazine group, a substituted or unsubstituted thiazolopyrazine group, a substituted or unsubstituted thiazolotriazine group, a substituted or unsubstituted thiazoloetetrazine group, a substituted or unsubstituted benzothiadiazole group, a substituted or unsubstituted thiadiazolepyridine group, a substituted or unsubstituted thiadiazolepyrimidine group, a substituted or unsubstituted thiadiazolepyridazine group, a substituted or unsubstituted thiadiazolepyrazine group, a substituted or unsubstituted thiadiazoletriazine group, and a substituted or unsubstituted thiadiazoletetrazine group. For example, Li and L₂ may be each independently a substituted or unsubstituted benzothiophene group, a substituted or unsubstituted thienopyridine group, a substituted or unsubstituted benzothiazole group, or a substituted or unsubstituted thiazolopyridine group.

In Formula H-1, Ar₁ and Ar₂ may be a substituted or unsubstituted heteroaryl group of 2 to 30 ring-forming carbon atoms, including the first moiety or the second moiety. For example, Ar₁ and Ar₂ may be each independently one among a substituted or unsubstituted benzothiophene group, a substituted or unsubstituted thienopyridine group, a substituted or unsubstituted thienopyrimidine group, a substituted or unsubstituted thienopyridazine group, a substituted or unsubstituted thienopyrazine group, a substituted or unsubstituted thienotriazine group, a substituted or unsubstituted thienotetrazine group, a substituted or unsubstituted benzothiazole group, a substituted or unsubstituted thiazolopyridine group, a substituted or unsubstituted thiazolopyrimidine group, a substituted or unsubstituted thiazolopyridazine group, a substituted or unsubstituted thiazolopyrazine group, a substituted or unsubstituted thiazolotriazine group, a substituted or unsubstituted thiazoloetetrazine group, a substituted or unsubstituted benzothiadiazole group, a substituted or unsubstituted thiadiazolepyridine group, a substituted or unsubstituted thiadiazolepyrimidine group, a substituted or unsubstituted thiadiazolepyridazine group, a substituted or unsubstituted thiadiazolepyrazine group, a substituted or unsubstituted thiadiazoletriazine group, and a substituted or unsubstituted thiadiazoletetrazine group. For example, Ar₁ and Ar₂ may be each independently a substituted or unsubstituted benzothiophene group, a substituted or unsubstituted thienopyridine group, a substituted or unsubstituted benzothiazole group, or a substituted or unsubstituted thiazolopyridine group.

The first compound or the second compound represented by Formula H-1 may be represented by one among the compounds in Compound Group HT. However, the compounds shown in Compound Group HT are examples, and the first compound or the second compound represented by Formula H-1 is not limited to the compounds represented in Compound Group HT.

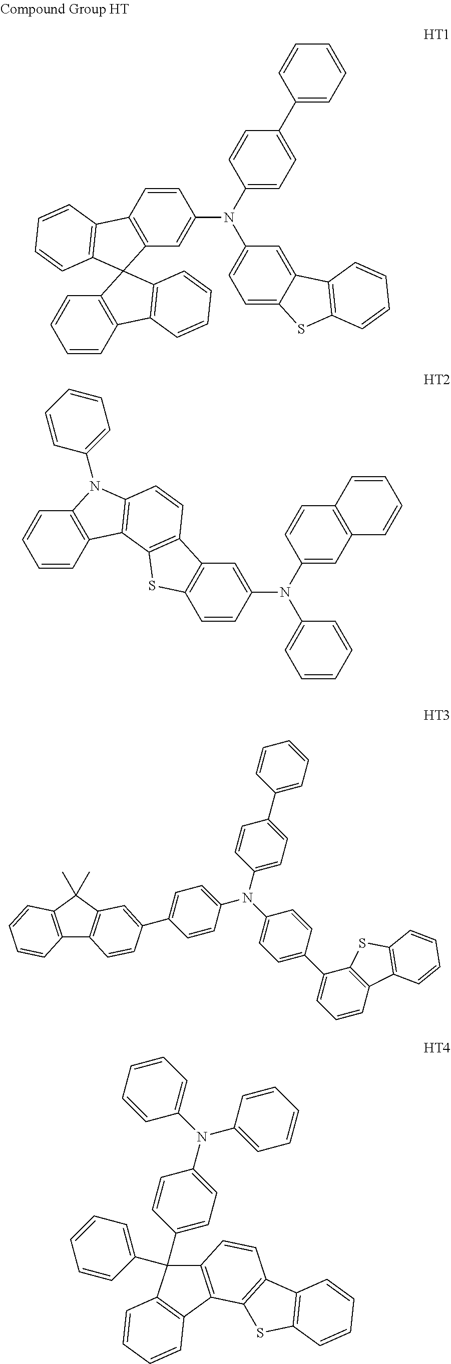

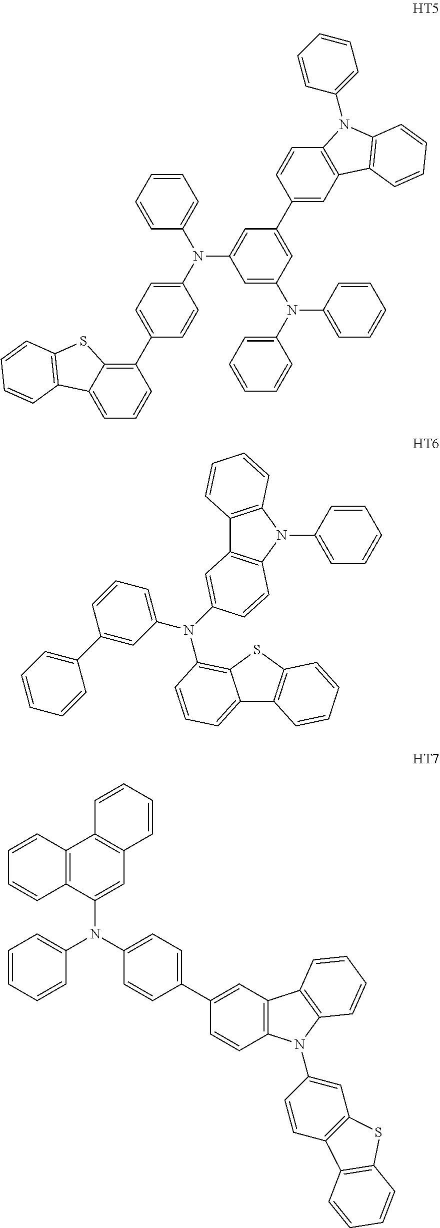 [SMILES: c1ccc(N(c2ccccc2)c2cc(-c3ccc4c(c3)c3ccccc3n4-c3ccccc3)cc(N(c3ccccc3)c3ccc(-c4cccc5c4sc4ccccc45)cc3)c2)cc1 ; c1ccc(-c2cccc(N(c3ccc4c(c3)c3ccccc3n4-c3ccccc3)c3cccc4c3sc3ccccc34)c2)cc1 ; c1ccc(N(c2ccc(-c3ccc4c(c3)c3ccccc3n4-c3ccc4c(c3)sc3ccccc34)cc2)c2cc3ccccc3c3ccccc23)cc1]

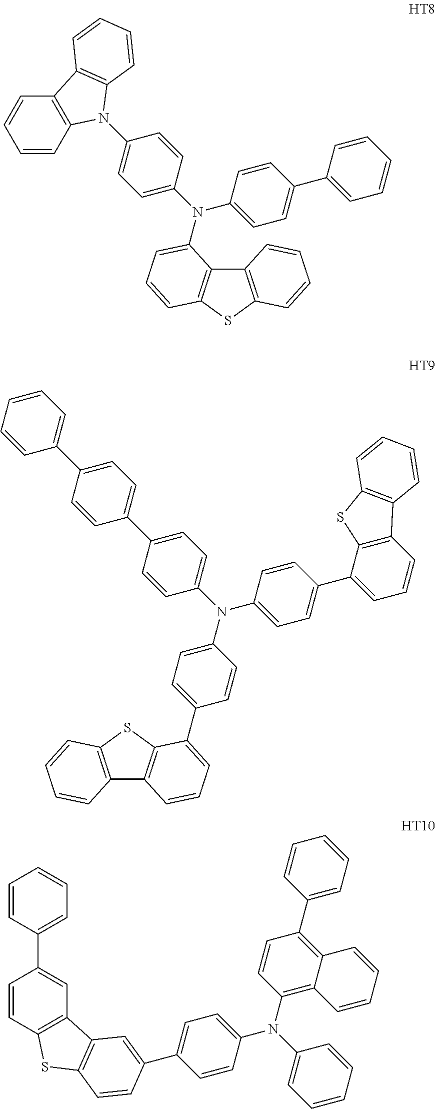 [SMILES: c1ccc(-c2ccc(N(c3ccc(-n4c5ccccc5c5ccccc54)cc3)c3cccc4sc5ccccc5c34)cc2)cc1 ; c1ccc(-c2ccc(-c3ccc(N(c4ccc(-c5cccc6c5sc5ccccc56)cc4)c4ccc(-c5cccc6c5sc5ccccc56)cc4)cc3)cc2)cc1 ; c1ccc(-c2ccc3sc4ccc(-c5ccc(N(c6ccccc6)c6ccc(-c7ccccc7)c7ccccc67)cc5)cc4c3c2)cc1]

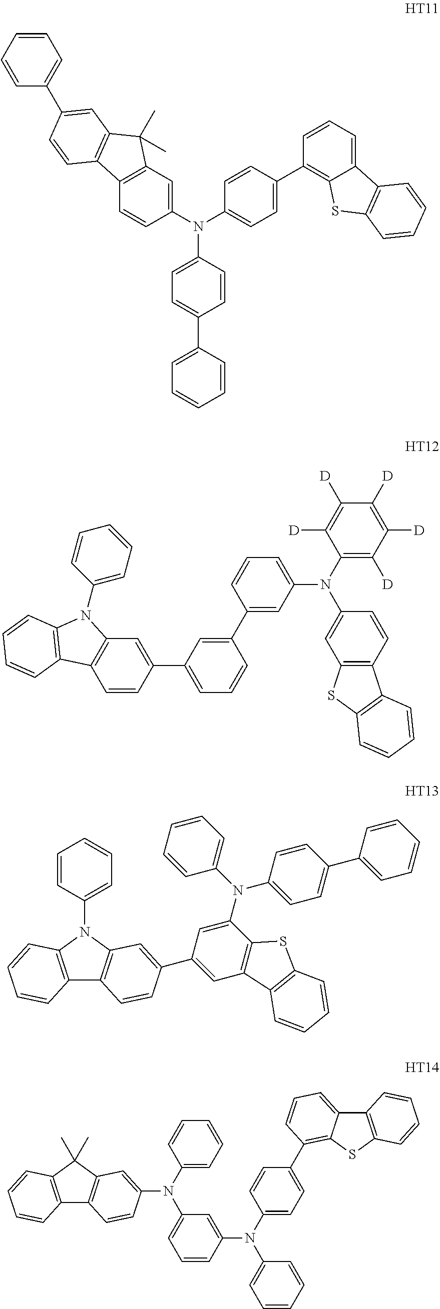 [SMILES: CC1(C)c2cc(-c3ccccc3)ccc2-c2ccc(N(c3ccc(-c4ccccc4)cc3)c3ccc(-c4cccc5c4sc4ccccc45)cc3)cc21 ; [2H]c1c([2H])c([2H])c(N(c2cccc(-c3cccc(-c4ccc5c6ccccc6n(-c6ccccc6)c5c4)c3)c2)c2ccc3c(c2)sc2ccccc23)c([2H])c1[2H] ; c1ccc(-c2ccc(N(c3ccccc3)c3cc(-c4ccc5c6ccccc6n(-c6ccccc6)c5c4)cc4c3sc3ccccc34)cc2)cc1 ; CC1(C)c2ccccc2-c2ccc(N(c3ccccc3)c3cccc(N(c4ccccc4)c4ccc(-c5cccc6c5sc5ccccc56)cc4)c3)cc21]

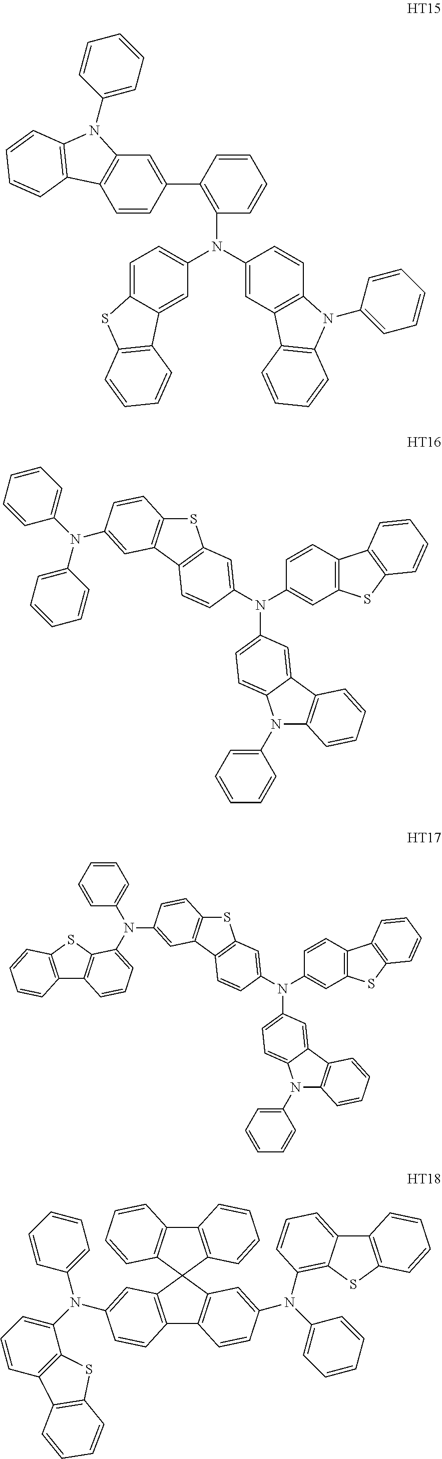 [SMILES: c1ccc(-n2c3ccccc3c3cc(N(c4ccc5sc6ccccc6c5c4)c4ccccc4-c4ccc5c6ccccc6n(-c6ccccc6)c5c4)ccc32)cc1 ; c1ccc(N(c2ccccc2)c2ccc3sc4cc(N(c5ccc6c(c5)sc5ccccc56)c5ccc6c(c5)c5ccccc5n6-c5ccccc5)ccc4c3c2)cc1 ; c1ccc(N(c2ccc3sc4cc(N(c5ccc6c(c5)sc5ccccc56)c5ccc6c(c5)c5ccccc5n6-c5ccccc5)ccc4c3c2)c2cccc3c2sc2ccccc23)cc1 ; c1ccc(N(c2ccc3c(c2)C2(c4ccccc4-c4ccccc42)c2cc(N(c4ccccc4)c4cccc5c4sc4ccccc45)ccc2-3)c2cccc3c2sc2ccccc23)cc1]

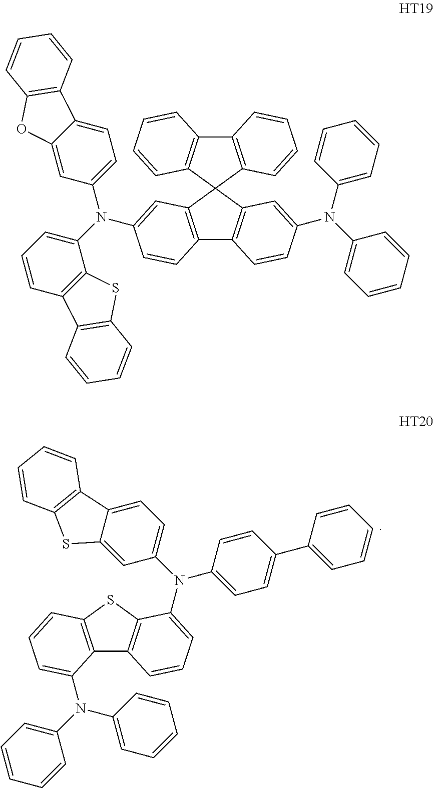 [SMILES: c1ccc(N(c2ccccc2)c2ccc3c(c2)C2(c4ccccc4-c4ccccc42)c2cc(N(c4ccc5c(c4)oc4ccccc45)c4cccc5c4sc4ccccc45)ccc2-3)cc1 ; c1ccc(-c2ccc(N(c3ccc4c(c3)sc3ccccc34)c3cccc4c3sc3cccc(N(c5ccccc5)c5ccccc5)c34)cc2)cc1]

Each of the hole transport regions HTR1 and HTR2 may include a phthalocyanine compound such as copper phthalocyanine, N1, N1′-([1,1′-biphenyl]-4,4′-diyl)bis(N1-phenyl-N4,N4-di-m-tolylbenzene-1,4-diamine) (DNTPD), 4,4′,4″-[tris(3-methylphenyl)phenylamino] triphenylamine (m-MTDATA), 4,4′,4″-tris(N,N-diphenylamino)triphenylamine (TDATA), 4,4′,4″-tris [N (2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(1-naphthalene-1-yl)-N, N′-diphenyl-benzidine (NPB), triphenylamine-containing polyetherketone (TPAPEK), 4-isopropyl-4′-methyldiphenyliodonium [tetrakis(pentafluorophenyl) borate], and/or dipyrazino[2,3-f: 2′,3′-h] quinoxaline-2,3,6,7,10,11-hexacarbonitrile (HATCN).

Each of the hole transport regions HTR1 and HTR2 may further include carbazole derivatives such as N-phenylcarbazole and/or polyvinylcarbazole, fluorene-based derivatives, triphenylamine-based derivatives such as N,N′-bis(3-methylphenyl)-N,N′-diphenyl-[1,1′-biphenyl]-4,4′-diamine (TPD) and/or 4,4′,4″-tris(N-carbazolyl)triphenylamine (TCTA), N,N′-di(naphthalene-I-yl)-N,N′-diphenyl-benzidine (NPB), 4,4′-cyclohexylidene bis [N,N-bis(4-methylphenyl)benzenamine] (TAPC), 4,4′-bis [N,N′-(3-tolyl)amino]-3,3′-dimethylbiphenyl(HMTPD), 1,3-bis(N-carbazolyl)benzene (mCP), and/or the like.

In some embodiments, each of the hole transport regions HTR1 and HTR2 may further include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport regions HTR1 and HTR2 may respectively include the compounds of the hole transport region in at least one among the hole injection layers HIL1 and HIL2, the hole transport layers HTL1 and HTL2, the emission auxiliary layers SE1 and SE2, and the electron blocking layer.

The thickness of each of the hole transport regions HTR1 and HTR2 may be from about 100 Å to about 10,000 Å, for example, from about 100 Å to about 5,000 Å. If the hole transport regions HTR1 and HTR2 include the hole injection layers HIL1 and HIL2, respectively, the thickness of each of the hole injection regions HIL1 and HIL2 may be, for example, from about 30 Å to about 1,000 Å. If the hole transport regions HTR1 and HTR2 include the hole transport layers HTL1 and HTL2, respectively, the thickness of each of the hole transport layers HTL1 and HTL2 may be from about 30 Å to about 1,000 Å. For example, if the hole transport regions HTR1 and HTR2 include the electron blocking layer, the thickness of the electron blocking layer may be from about 10 Å to about 1,000 Å. If the thicknesses of the hole transport regions HTR1 and HTR2, the hole injection layers HIL1 and HIL2, the hole transport layers HTL1 and HTL2, and the electron blocking layer satisfy the above-described ranges, suitable or satisfactory hole transport properties may be achieved without substantial increase of a driving voltage.

Each of the hole transport regions HTR1 and HTR2 may further include a p-dopant in addition to the above-described materials. The p-dopant may be dispersed uniformly or non-uniformly in the hole transport regions HTR1 and HTR2. The p-dopant may include at least one of metal halide compounds, quinone derivatives, metal oxides, and/or cyano group-containing compounds, without limitation. For example, the p-dopant may include metal halide compounds such as Cul and/or Rbl, quinone derivatives such as tetracyanoquinodimethane (TCNQ) and/or 2,3,5,6-tetrafluoro-7,7′,8,8-tetracyanoquinodimethane (F4-TCNQ), metal oxides such as tungsten oxide and/or molybdenum oxide, cyano group-containing compounds such as dipyrazino[2,3-f: 2′,3′-h] quinoxaline-2,3,6,7,10,11-hexacarbonitrile (HATCN) and/or 4-[2,3-bis [cyano-(4-cyano-2,3,5,6-tetrafluorophenyl)methylidene] cyclopropylidene]-cyanomethyl]-2,3,5,6-tetrafluorobenzonitrile (NDP9), etc., without limitation.

The emission layers EML1 and EML2 may include red emission layers EML-R₁ and EML-R2 overlapping with the first light emitting region PXA-R, green emission layers EML-G1 and EML-G2 overlapping with the second light emitting region PXA-G, and blue emission layers EML-B1 and EML-B2 overlapping with the third light emitting region PXA-B. Each of the emission layers EML1 and EML2 may have a thickness of about 100 Å to about 1000 Å, or about 100 Å to about 300 Å. Each of the emission layers EML1 and EML2 may have a single layer formed using a single material, a single layer formed using a plurality of different materials, or a multilayer structure having a plurality of layers formed using a plurality of different materials.

Each of the emission layers EML1 and EML2 may include anthracene derivatives, pyrene derivatives, fluoranthene derivatives, chrysene derivatives, dihydrobenzanthracene derivatives, and/or triphenylene derivatives. In some embodiments, the emission layers EML1 and EML2 may include anthracene derivatives and/or pyrene derivatives.

Each of the emission layers EML1 and EML2 may be formed using various suitable methods such as a vacuum deposition method, a spin coating method, a cast method, a Langmuir-Blodgett (LB) method, an inkjet printing method, a laser printing method, and/or a laser induced thermal imaging (LITI) method.

Each of the emission layers EML1 and EML2 may include a host and a dopant, and each of the emission layers EML1 and EML2 may include a compound represented by Formula E-1. For example, the blue emission layers EML-B1 and EML-B2 may include the compound represented by Formula E-1. The compound represented by Formula E-1 below may be used as a fluorescence host material.

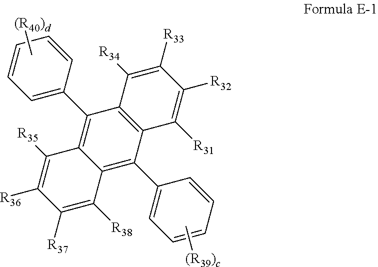

In Formula E-1, R₃₁ to R₄₀ may be each independently a hydrogen atom, a deuterium atom, a halogen atom, a substituted or unsubstituted silyl group, a substituted or unsubstituted thio group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, or a substituted or unsubstituted heteroaryl group of 2 to 30 ring-forming carbon atoms, or may be combined together with an adjacent group to form a ring. In some embodiments, R₃₁ to R₄₀ may be combined together with an adjacent group to form a saturated hydrocarbon ring, an unsaturated hydrocarbon ring, a saturated heterocycle, or an unsaturated heterocycle.

In Formula E-1, “c” and “d” may be each independently an integer of 0 to 5.

The compound represented by Formula E-1 may be represented by one among Compound E1 to Compound E20 below.

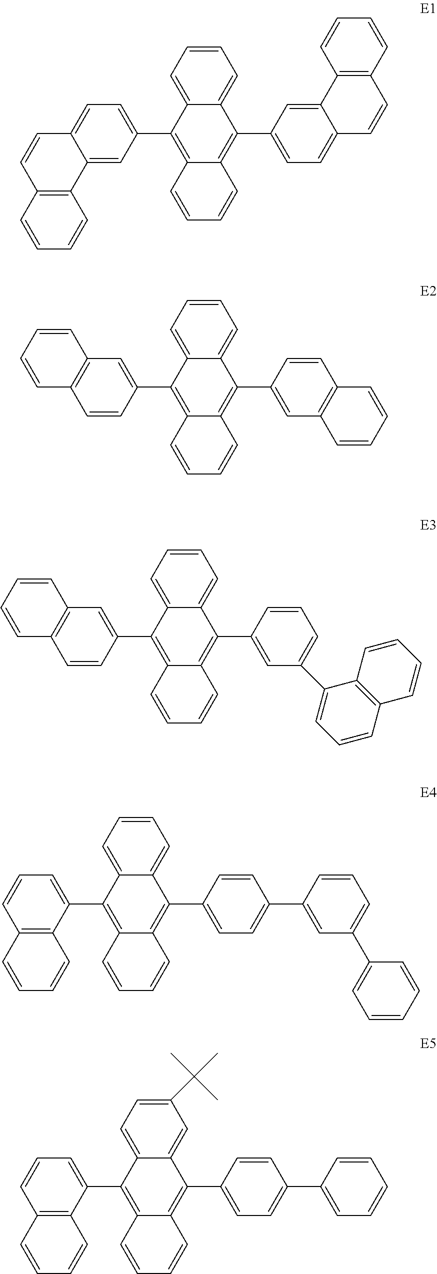

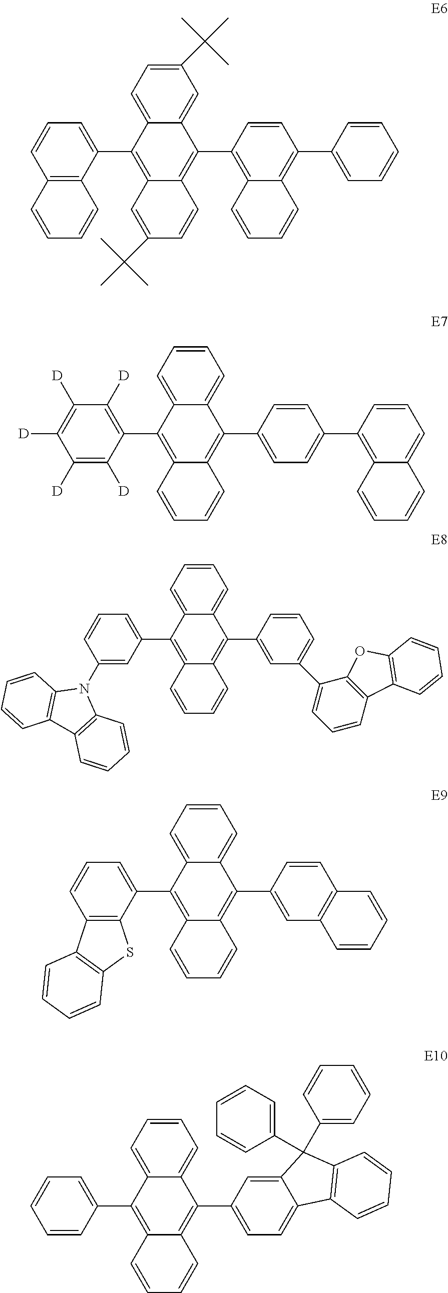

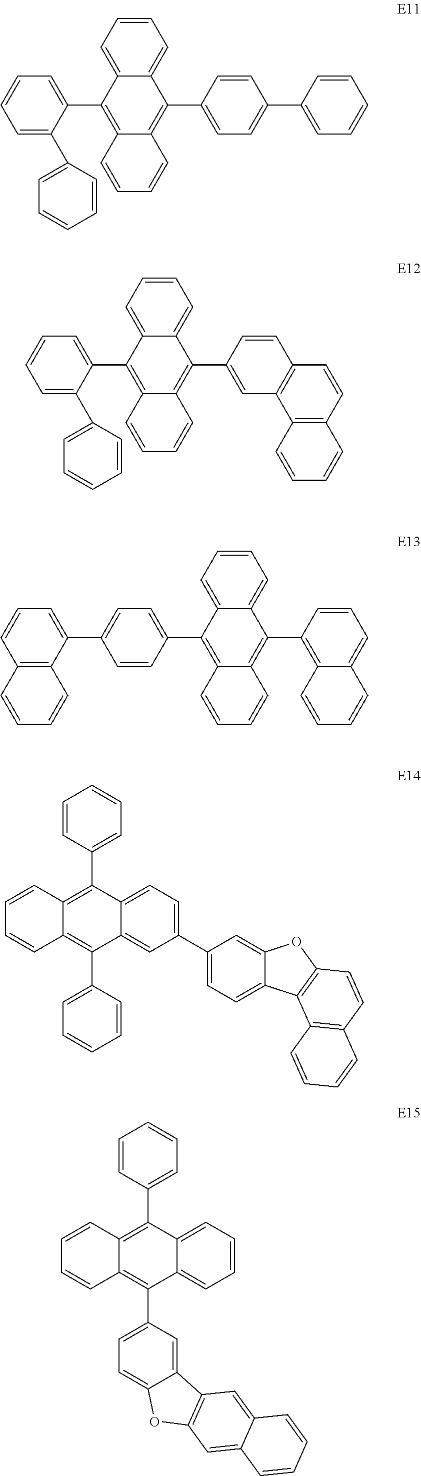

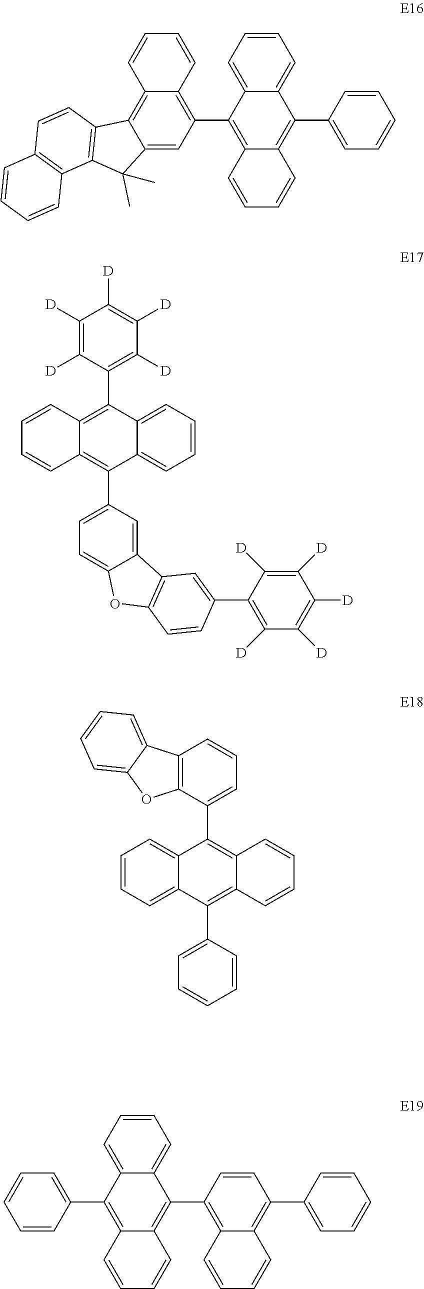

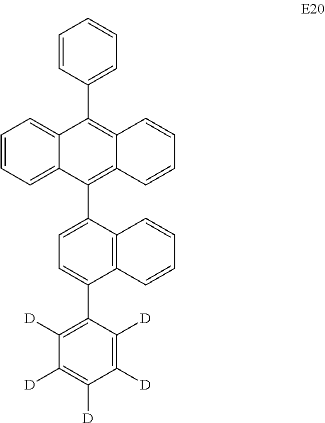 [SMILES: [2H]c1c([2H])c([2H])c(-c2ccc(-c3c4ccccc4c(-c4ccccc4)c4ccccc34)c3ccccc23)c([2H])c1[2H]]

In an embodiment, each of the emission layers EML1 and EML2 may include a compound represented by Formula E-2a or Formula E-2b. For example, each of the red emission layers EML-R1 and EML-R₂ and the green emission layers EML-G1 and EML-G2 may include the compound represented by Formula E-2a or Formula E-2b. The compound represented by Formula E-2a or Formula E-2b may be used as a phosphorescence host material.

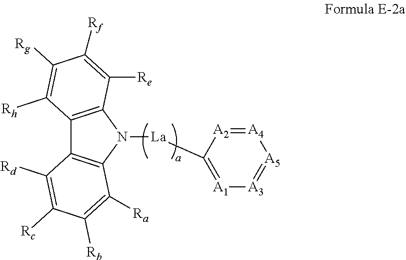

In Formula E-2a, “a” may be an integer of 0 to 10, La may be a direct linkage, a substituted or unsubstituted arylene group of 6 to 30 ring-forming carbon atoms, or a substituted or unsubstituted heteroarylene group of 2 to 30 ring-forming carbon atoms. In some embodiments, if “a” is an integer of 2 or more, a plurality of La may be each independently a substituted or unsubstituted arylene group of 6 to 30 ring-forming carbon atoms, or a substituted or unsubstituted heteroarylene group of 2 to 30 ring-forming carbon atoms.

In addition, in Formula E-2a, A1 to A₅ may be each independently N or Cri. Ra to Rᵢ may be each independently a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined together with an adjacent group to form a ring. Ra to Rᵢ may be combined together with an adjacent group to form a hydrocarbon ring or a heterocycle including N, O, S, etc. as a ring-forming atom.

In some embodiments, in Formula E-2a, two or three selected from A1 to A5 may be N, and the remainder may be CRᵢ.

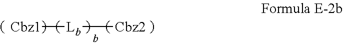

In Formula E-2b, Cbz1 and Cbz2 may be each independently an unsubstituted carbazole group, or a carbazole group substituted with an aryl group of 6 to 30 ring-forming carbon atoms. L_{b} may be a direct linkage, a substituted or unsubstituted arylene group of 6 to 30 ring-forming carbon atoms, or a substituted or unsubstituted heteroarylene group of 2 to 30 ring-forming carbon atoms. “b” is an integer of 0 to 10, and if “b” is an integer of 2 or more, a plurality of L_{b} may be each independently a substituted or unsubstituted arylene group of 6 to 30 ring-forming carbon atoms, or a substituted or unsubstituted heteroarylene group of 2 to 30 ring-forming carbon atoms.

The compound represented by Formula E-2a or Formula E-2b may be represented by one among the compounds in Compound Group E-2 below. However, the compounds shown in Compound Group E-2 below are only illustrations, and the compound represented by Formula E-2a or Formula E-2b is not limited to the compounds represented in Compound Group E-2 below.

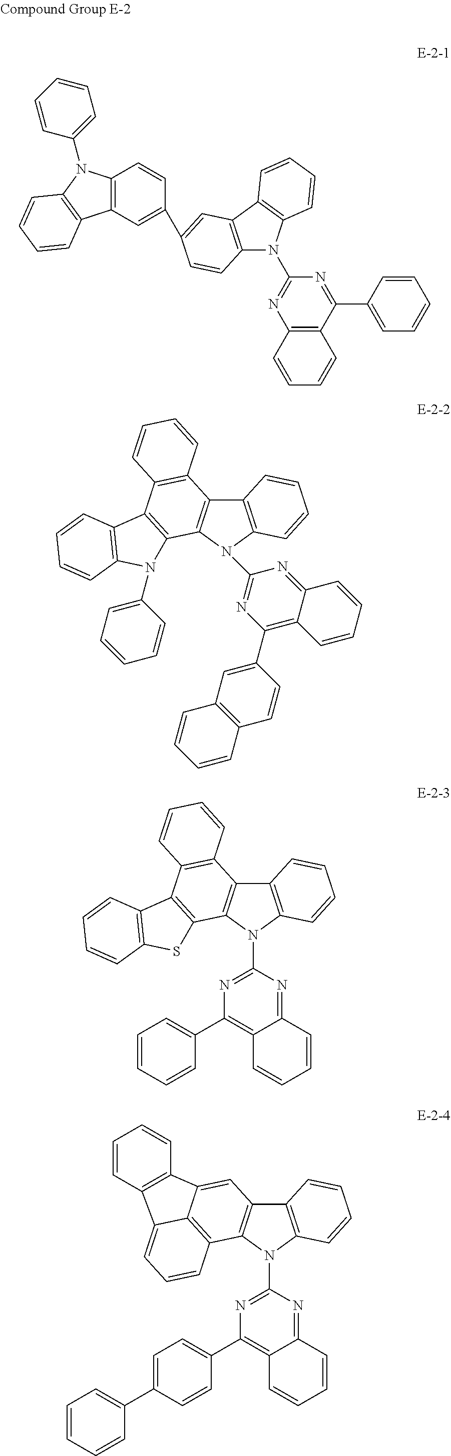

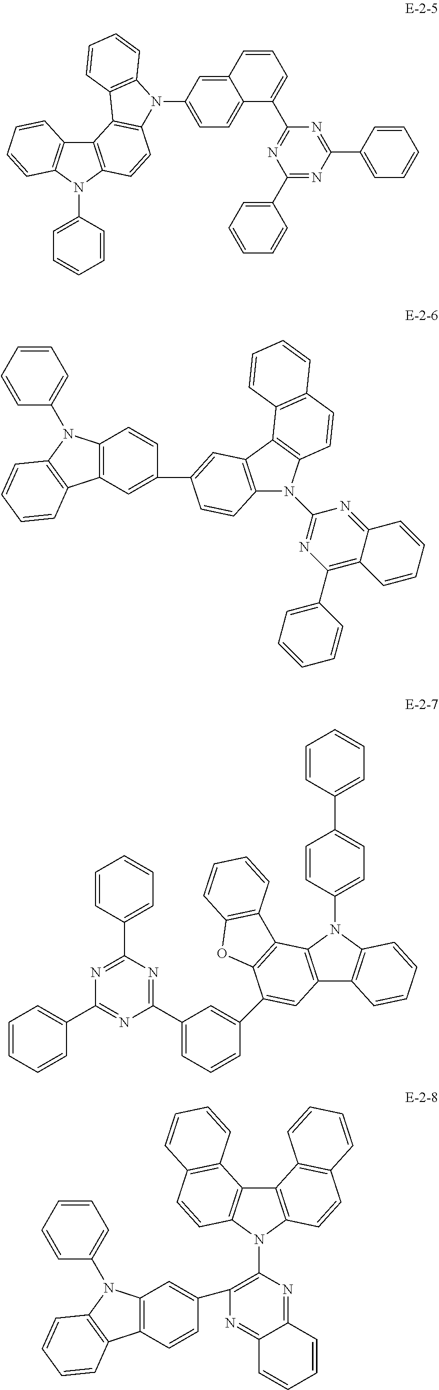

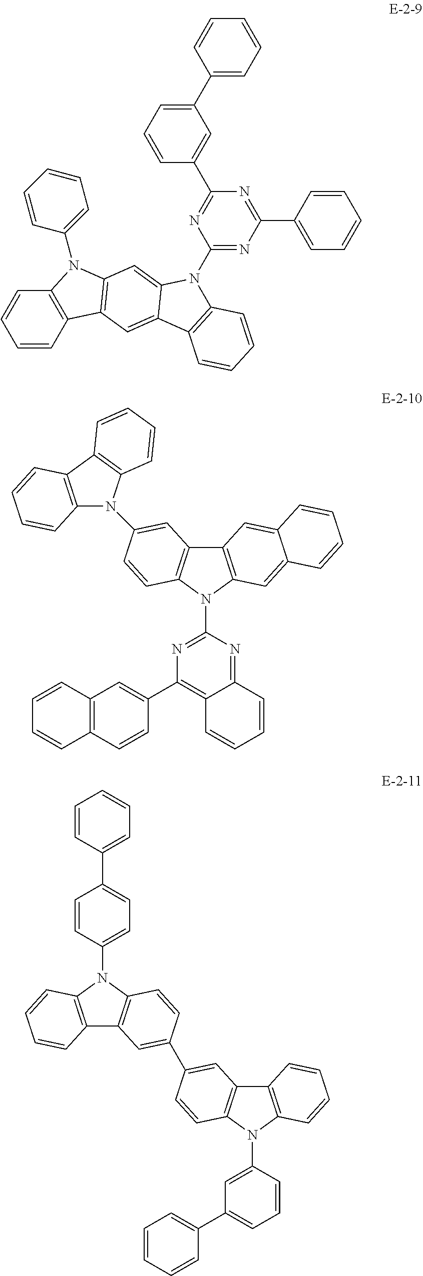

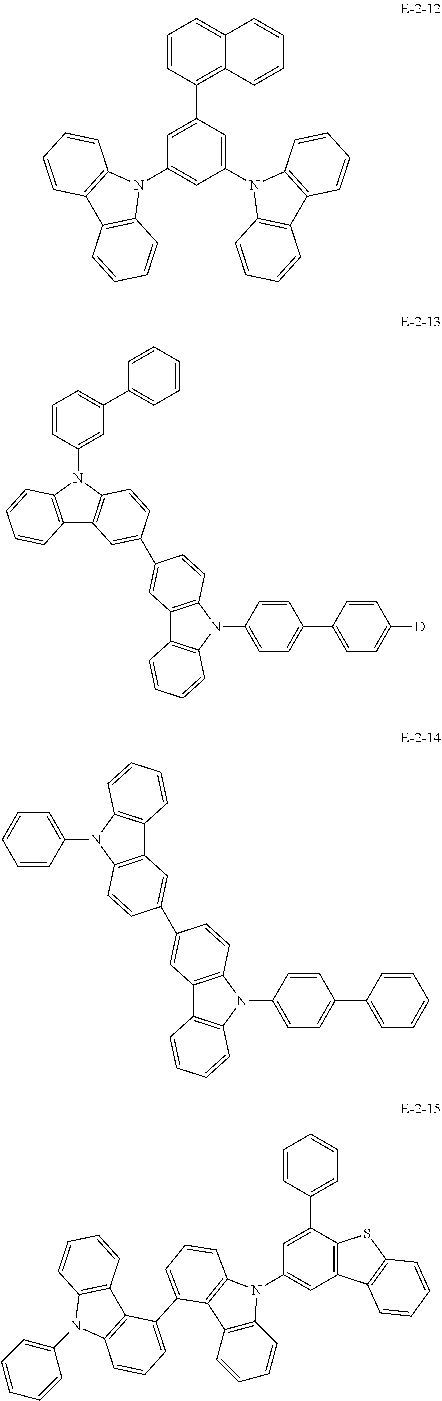 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

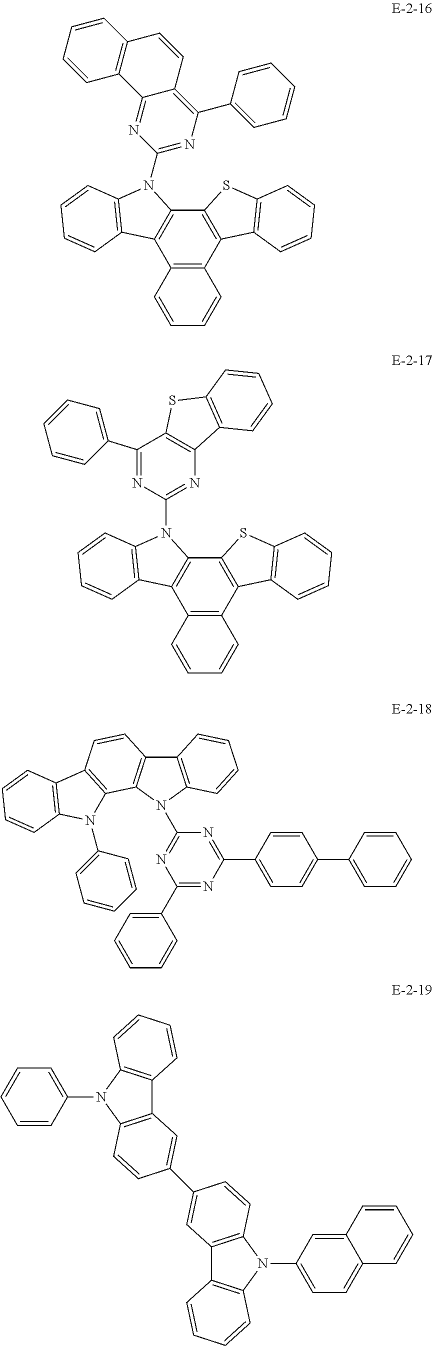 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1]

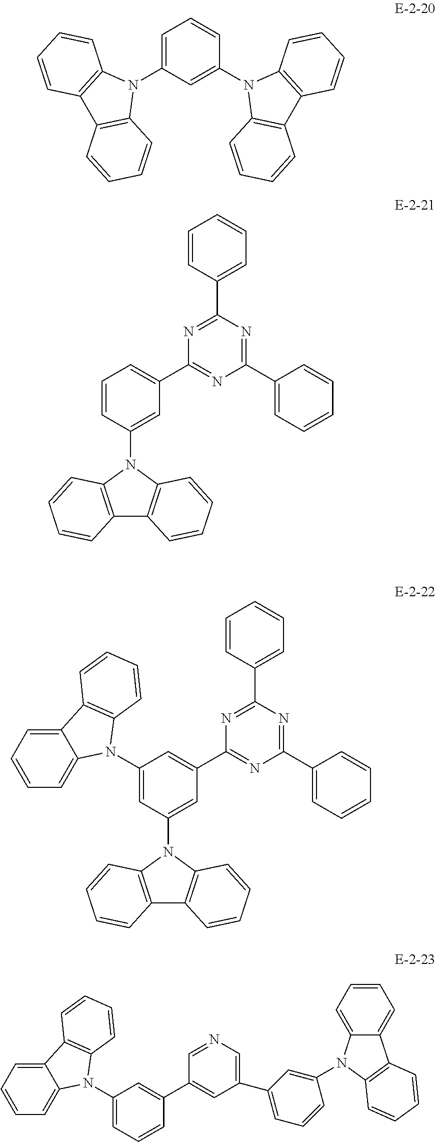

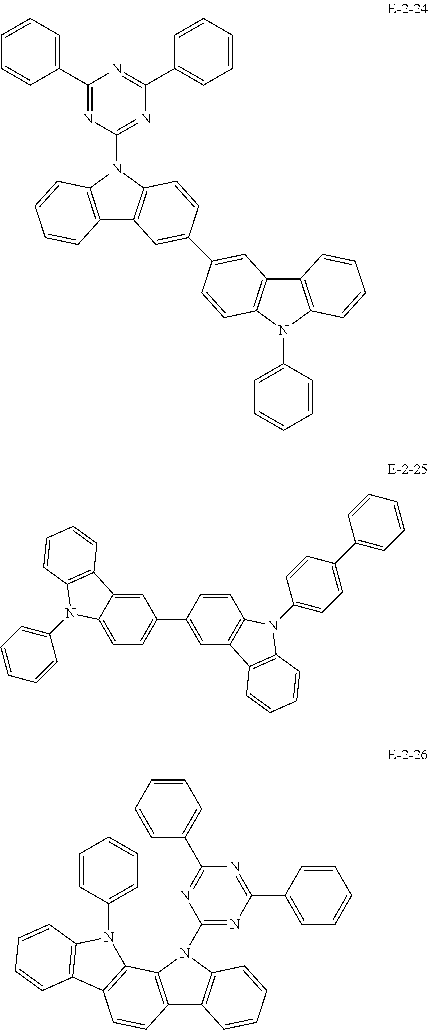 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2nc(-c3ccccc3)nc(-n3c4ccccc4c4ccc5c6ccccc6n(-c6ccccc6)c5c43)n2)cc1]

Each of the emission layers EML1 and EML2 may further include any suitable material generally used in the art as a host material. In some embodiments, each of the emission layers EML1 and EML2 may include as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis [2-(diphenylphosphino)phenyl] ether oxide (DPEPO), 4,4′-bis(N-carbazolyl)-1,1′-biphenyl(CBP), 1,3-bis(carbazol-9-yl)benzene (mCP), 2,8-bis(diphenylphosphoryl)dibenzo[b,d] furan (PPF), 4,4′,4″-tris(carbazol-9-yl)-triphenylamine (TCTA), and/or 1,3,5-tris(1-phenyl-1H-benzo[d]imidazole-2-yl)benzene (TPBi). However, embodiments of the present disclosure are not limited thereto. For example, tris(8-hydroxyquinolino)aluminum (Alq3), 9,10-di(naphthalene-2-yl) anthracene (ADN), 2-tert-butyl-9,10-di(naphth-2-yl) anthracene (TBADN), distyrylarylene (DSA), 4,4′-bis(9-carbazolyl)-2,2′-dimethyl-biphenyl(CDBP), 2-methyl-9,10-bis(naphthalen-2-yl) anthracene (MADN), hexaphenyl cyclotriphosphazene (CP1), 1,4-bis(triphenylsilyl)benzene (UGH2), hexaphenylcyclotrisiloxane (DPSiO3), octaphenylcyclotetra siloxane (DPSiO4), etc. may be used as the host material.

Each of the emission layers EML1 and EML2 may include a compound represented by Formula M-a below. For example, each of the red emission layers EML-R1 and EML-R₂ and the green emission layers EML-G1 and EML-G2 may include the compound represented by Formula M-a. The compound represented by Formula M-a may be used as a phosphorescence dopant material.

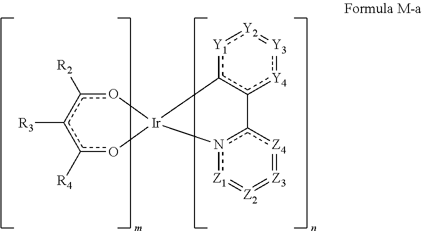

In Formula M-a, Y₁ to Y₄, and Z₁ to Z₄ may be each independently CR1 or N, and Rᵢ to R₄ may be each independently a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined together with an adjacent group to form a ring. In Formula M-a, “m” is 0 or 1, and “n” is 2 or 3. In Formula M-a, if “m” is 0, “n” is 3, and if “m” is 1, “n” is 2.

The compound represented by Formula M-a may be used as a phosphorescence dopant.

The compound represented by Formula M-a may be represented by one among Compounds M-a1 to M-a25 below. However, Compounds M-a1 to M-a25 below are examples, and the compound represented by Formula M-a is not limited to the compounds represented by Compounds M-a1 to M-a25 below.

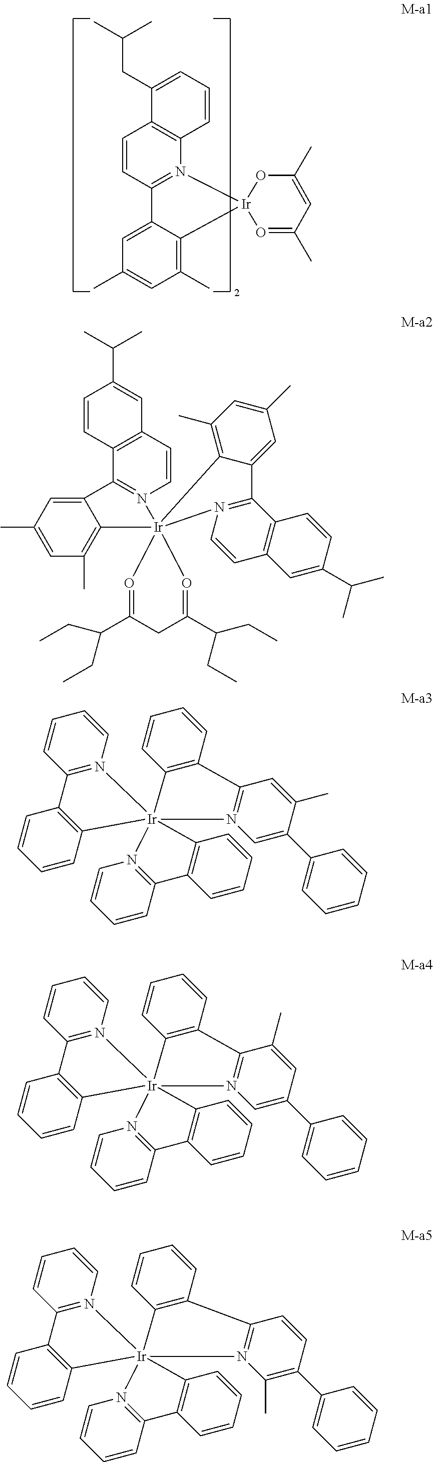

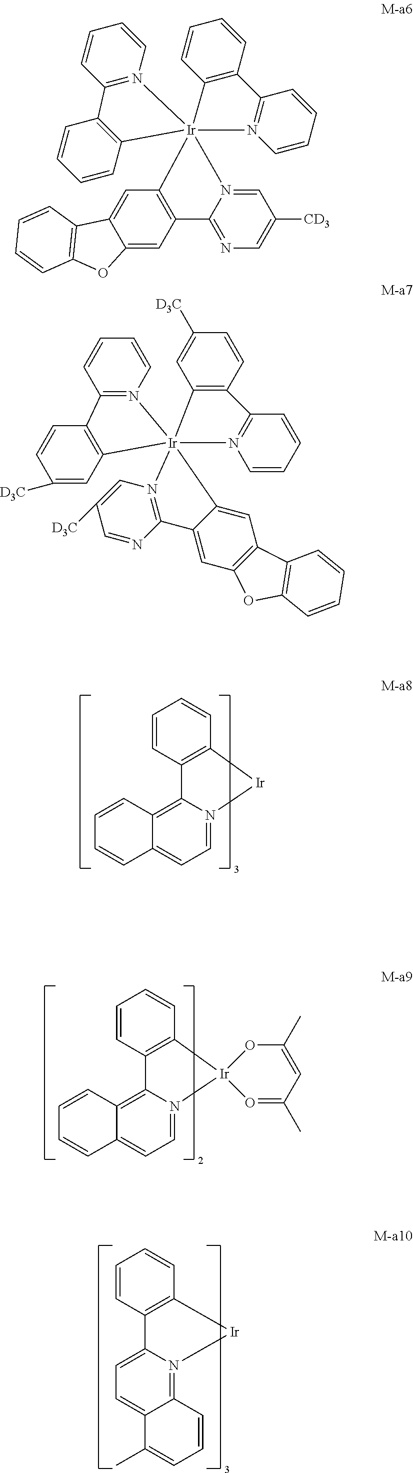

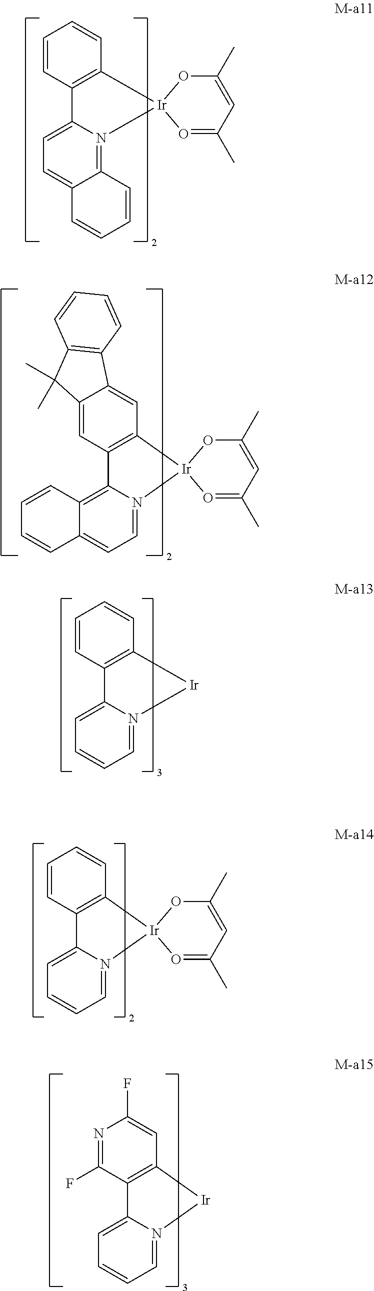

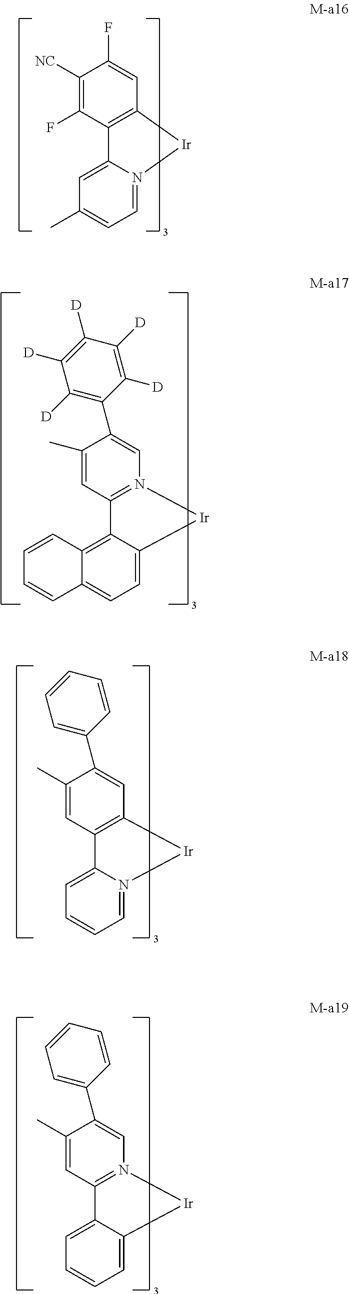

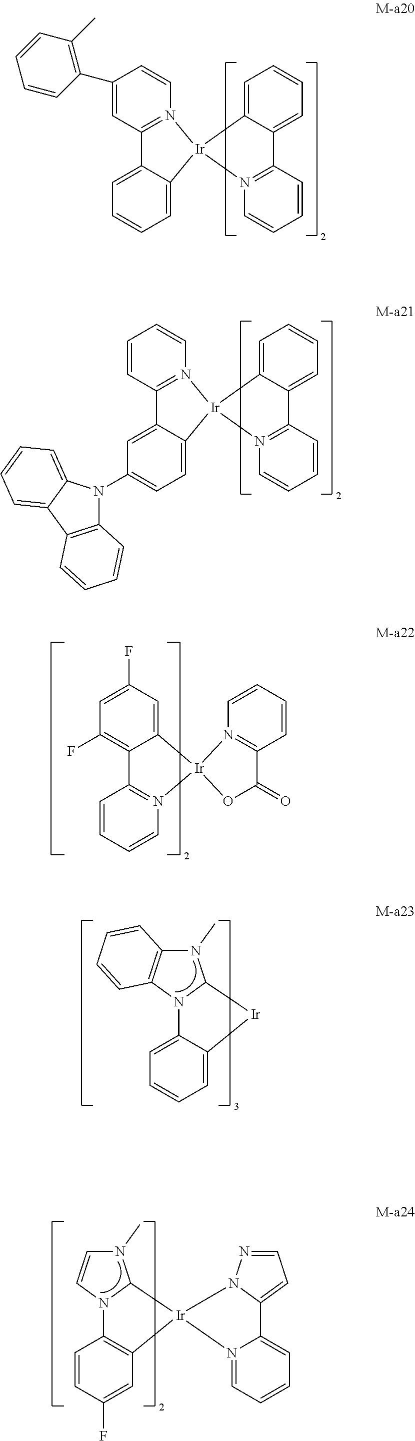

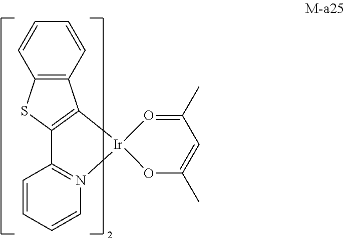

In an embodiment, the first emission layer EML1 may include the first compound including the first moiety among the compounds represented by Formula M-a. The second emission layer EML2 may include the second compound including the second moiety among the compounds represented by Formula M-a. In some embodiments, the first and second emission layers EML1 and EML2 may include the first compound represented by Formula M-a and the second compound represented by Formula M-a, respectively. The first compound represented by Formula M-a and the second compound represented by Formula M-a may be represented by Formula 3-1 or Formula 3-2 below.

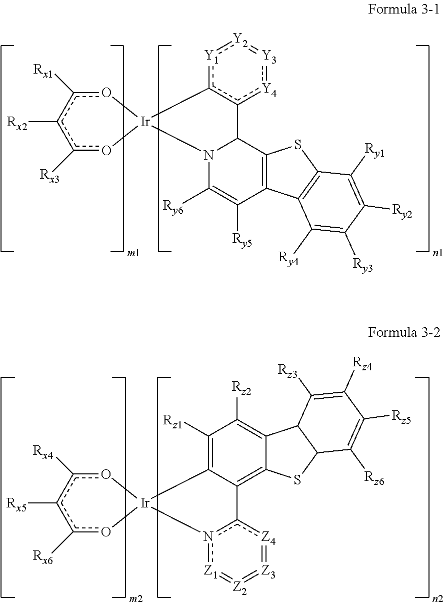

In Formula 3-1 and Formula 3-2, Y₁ to Y₄, and Z₁ to Z₄ may be each independently CR_{w} or N, R_{w} and Rₓ₁ to Rₓ₆ may be each independently a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined together with an adjacent group to form a ring. In Formula 3-1 and Formula 3-2, R_{y1} to R_{y6}, and R_{z1} to R_{z6} may be each independently a hydrogen atom, a deuterium atom, a halogen atom, a cyano group or a substituted or unsubstituted alkyl group of 1 to 20 carbon atoms. In Formula 3-1 and Formula 3-2, m1 and m2 may be each independently 0 or 1, and n1 and n2 may be each independently 2 or 3. In Formula 3-1 and Formula 3-2, if m1 is 0, n1 may be 3, if m1 is 1, n1 may be 2, if m2 is 0, n2 may be 3, and if m2 is 1, n2 may be 2.

The first compound represented by Formula M-a and the second compound represented by Formula M-a may be represented by one among the compounds in Compound Group R or Compound Group G. However, the compounds shown in Compound Group R and Compound Group G are examples, and the first compound or the second compound represented by Formula M-a is not limited to the compounds in Compound Group R or Compound Group G.

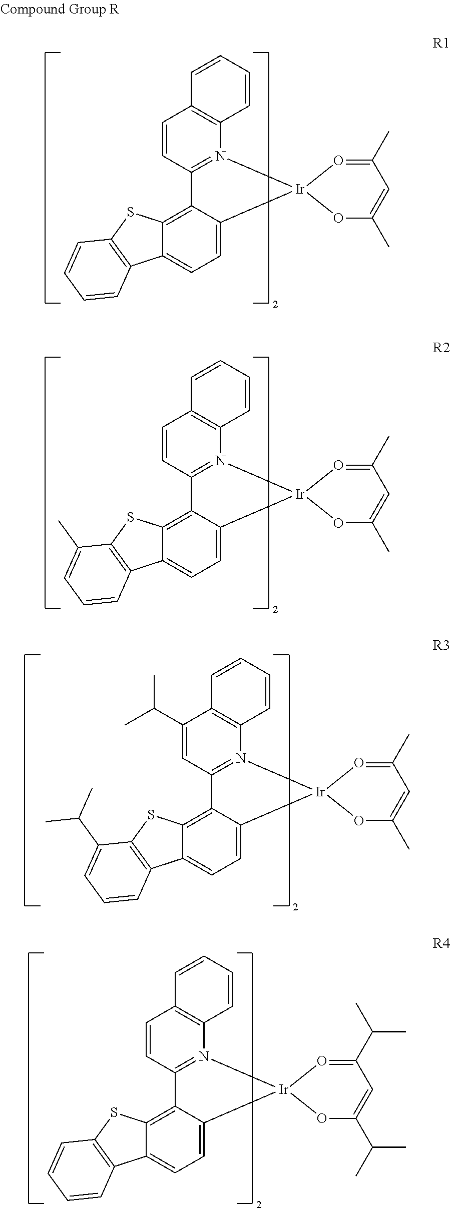

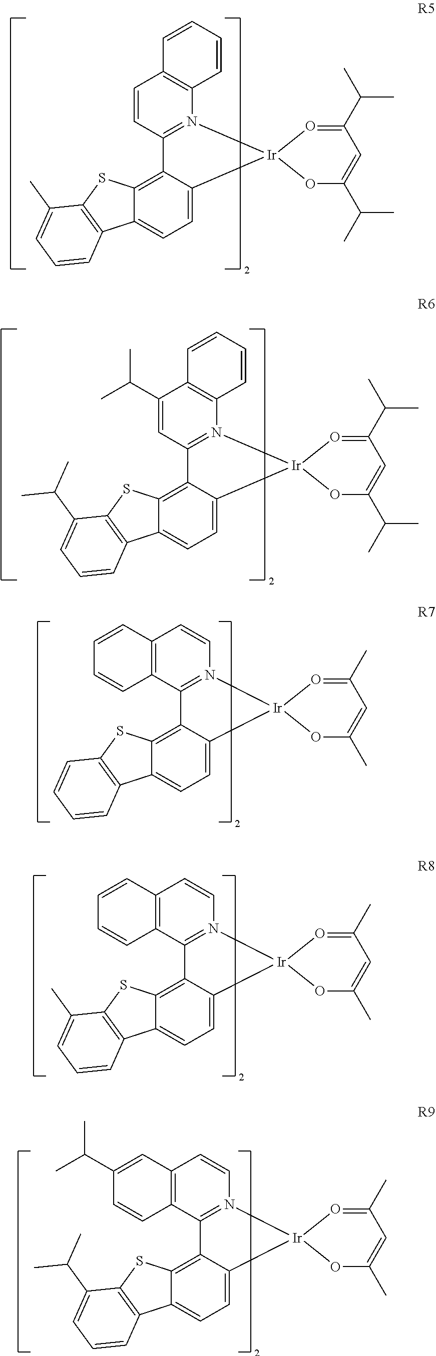

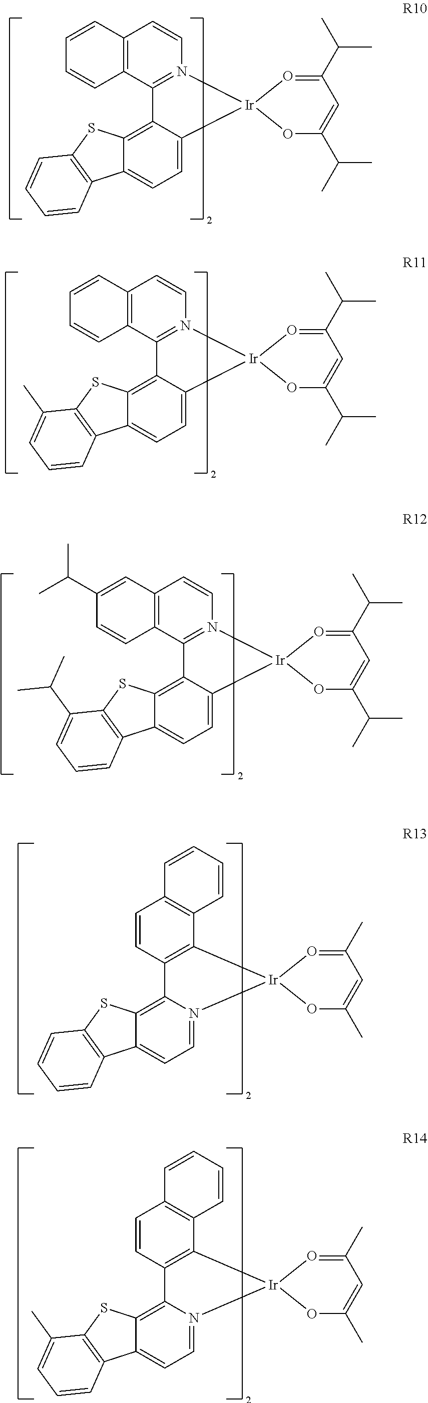

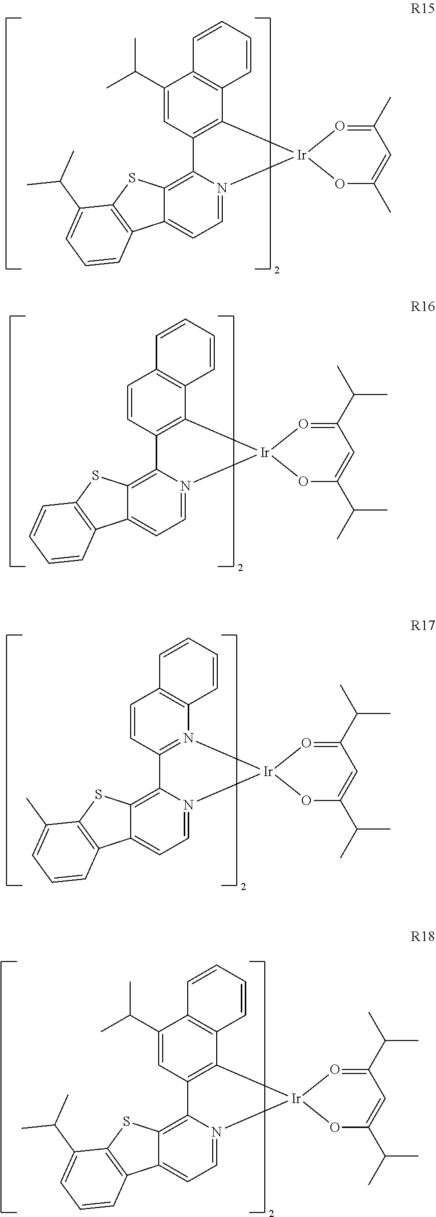

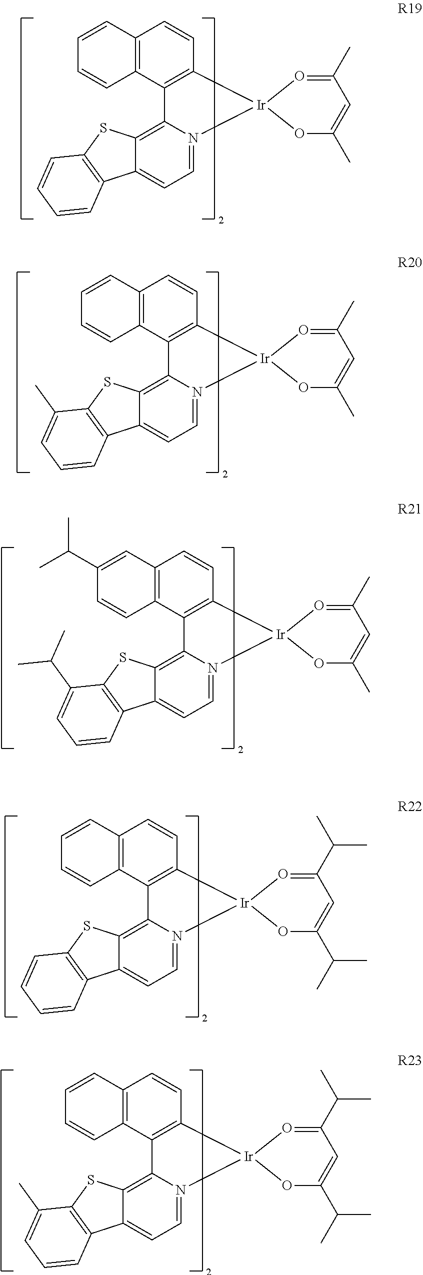

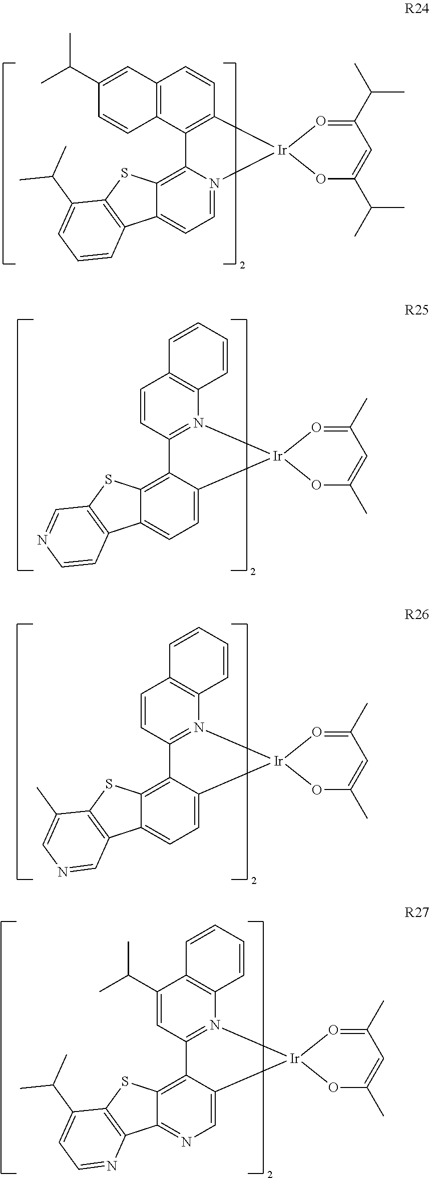

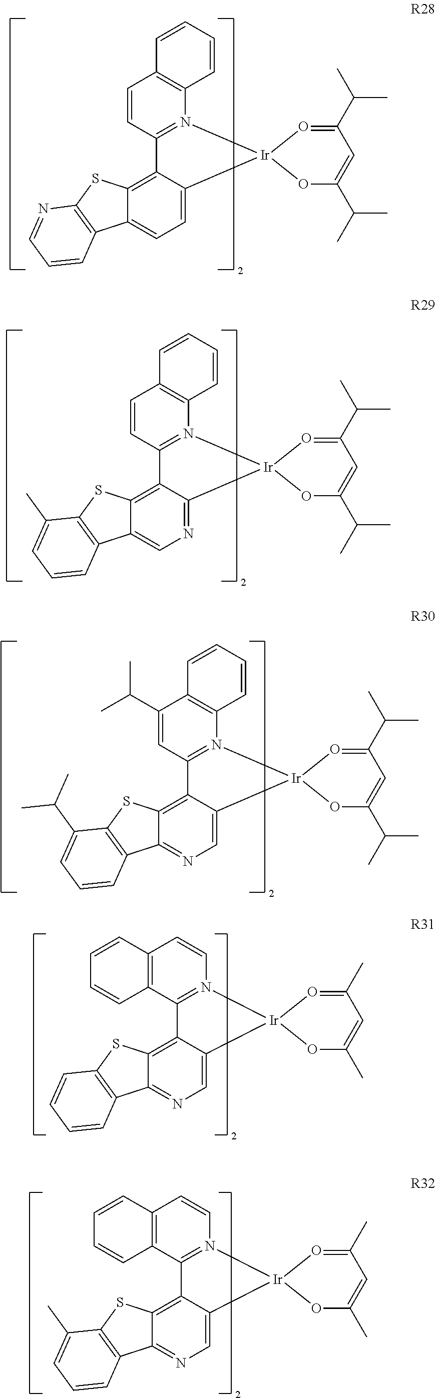

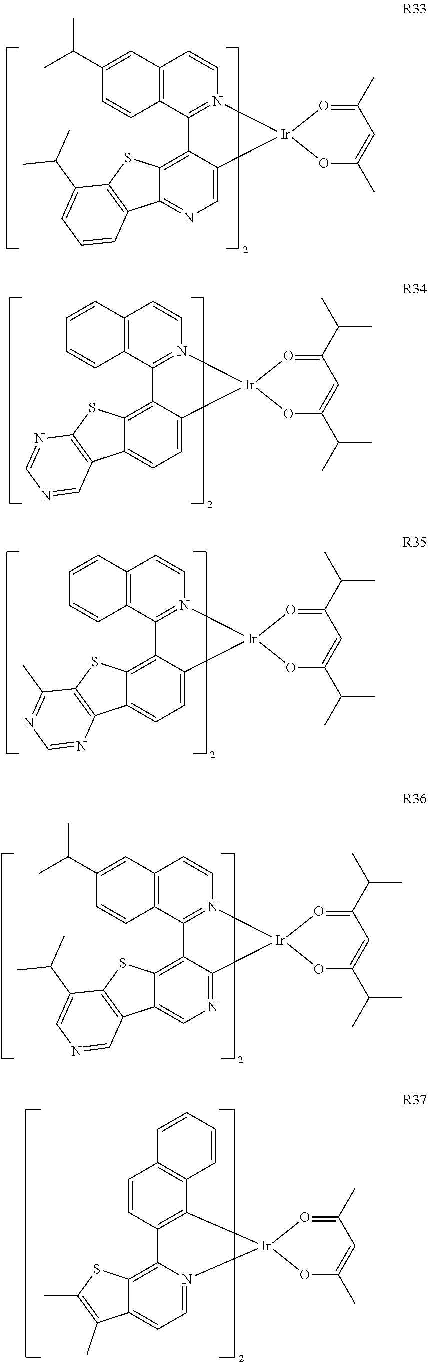

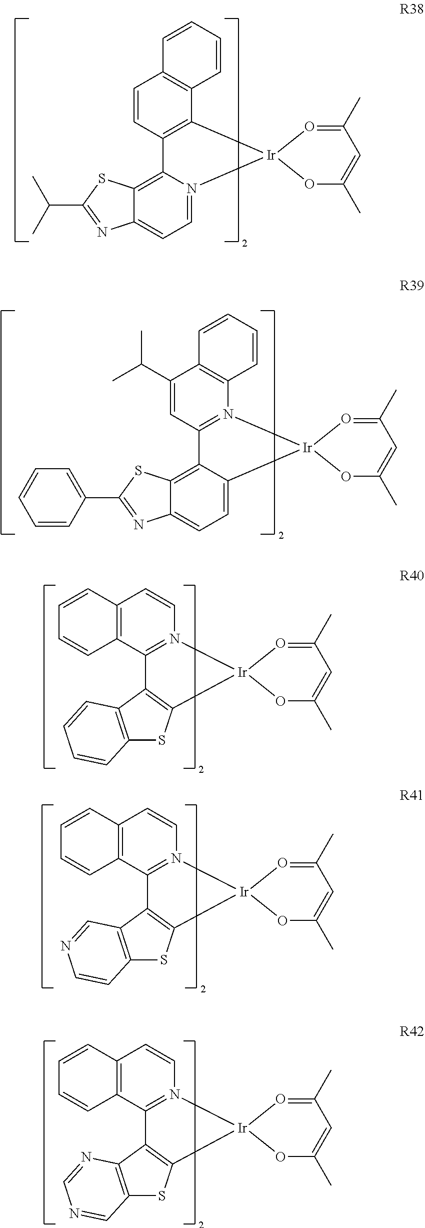

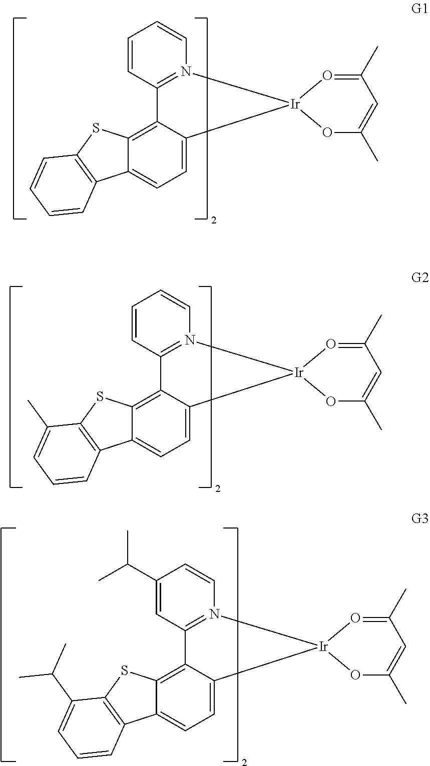

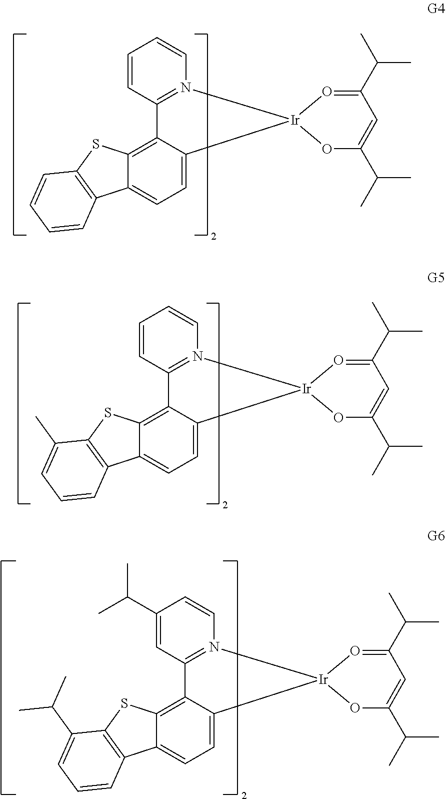

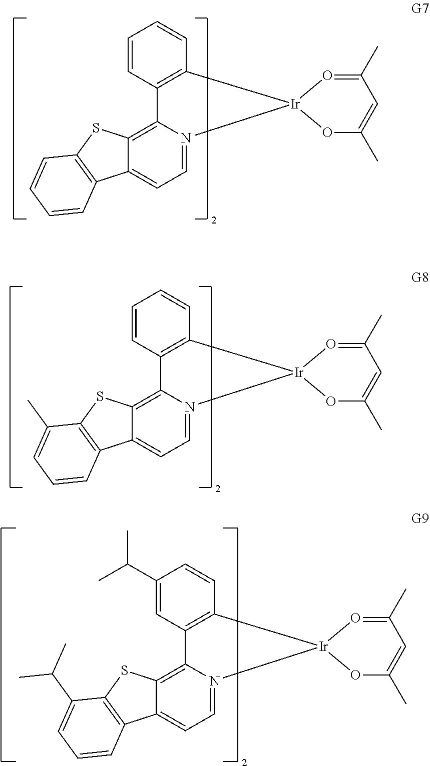

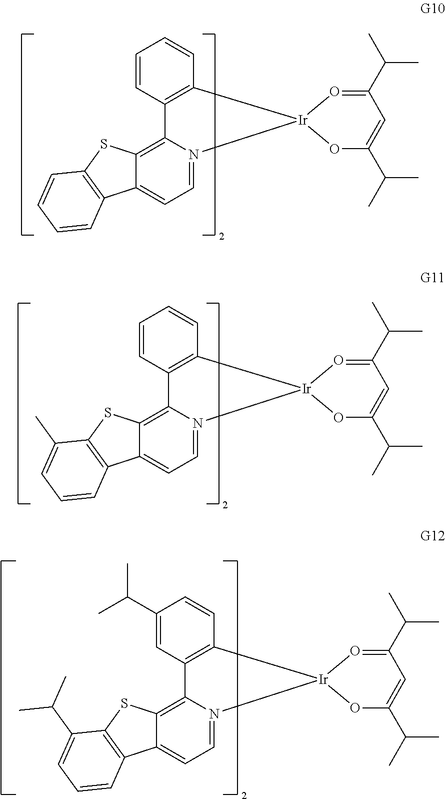

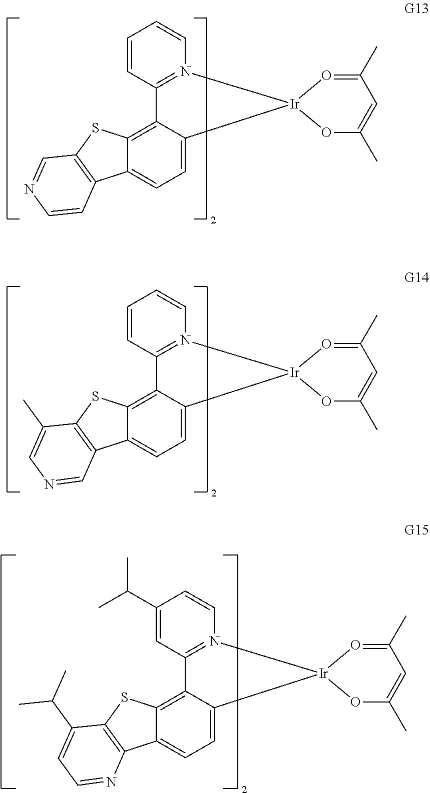

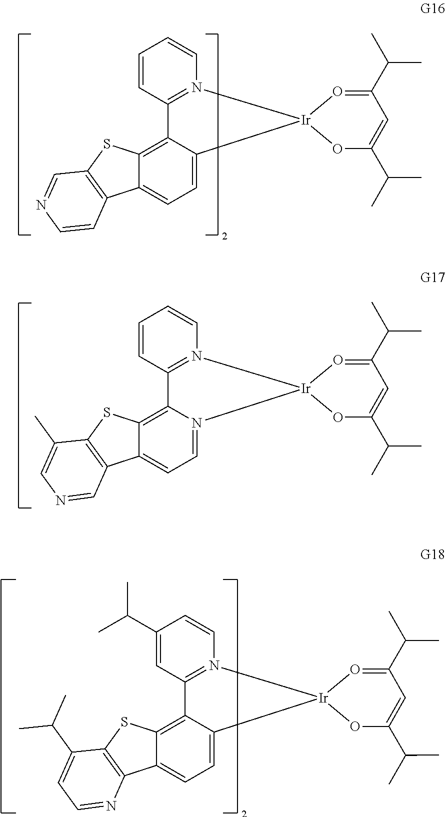

Each of the emission layers EML1 and EML2 may include one among Formula F-a to Formula F-c below. For example, the blue emission layers EML-B1 and EML-B2 may include the compound represented by one among Formula F-a to Formula F-c. The compounds represented by Formula F-a to Formula F-c below may be used as fluorescence dopant materials.

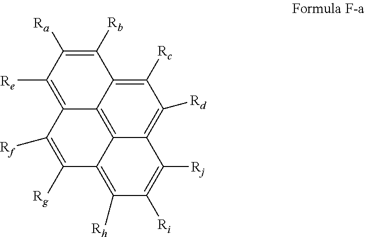

In Formula F-a, two selected from Rₐ to Rⱼ may be each independently substituted with *-NAr₁Ar₂. The remainder not substituted with *-NAr₁Ar₂, Are among Rₐ to Rⱼ may be each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In *-NAr₁Ar₂, Ar₁ and Ar₂ may be each independently a substituted or unsubstituted aryl group of 6 to 30 ring-forming carbon atoms, or a substituted or unsubstituted heteroaryl group of 2 to 30 ring-forming carbon atoms. For example, at least one among Ar₁ and Ar₂ may be a heteroaryl group including O or S as a ring-forming atom.

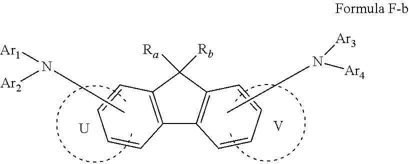

In Formula F-b, Rₐ and R_{b} may be each independently a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined together with an adjacent group to form a ring. Ar₁ to Ar₄ may be each independently a substituted or unsubstituted aryl group of 6 to 30 ring-forming carbon atoms, or a substituted or unsubstituted heteroaryl group of 2 to 30 ring-forming carbon atoms.

In Formula F-b, U and V may be each independently a substituted or unsubstituted hydrocarbon ring of 5 to 30 ring-forming carbon atoms, or a substituted or unsubstituted heterocycle of 2 to 30 ring-forming carbon atoms. At least one among Ar₁ to Ar₄ may be a heteroaryl group including O or S as a ring-forming atom.

In Formula F-b, the number of rings represented by U and V may be each independently 0 or 1. For example, in Formula F-b, if the number of U or Vis 1, one ring forms a fused ring at the designated part by U or V, and if the number of U or V is 0, a ring is not present at the designated part by U or V. In some embodiments, if the number of U is 0, and the number of V is 1, or if the number of U is 1, and the number of V is 0, a fused ring having the fluorene core of Formula F-b may be a ring compound having four rings. In some embodiments, if the number of both U and V is 0, the fused ring of Formula F-b may be a ring compound having three rings. In some embodiments, if the number of both U and V is 1, a fused ring having the fluorene core of Formula F-b may be a ring compound having five rings.

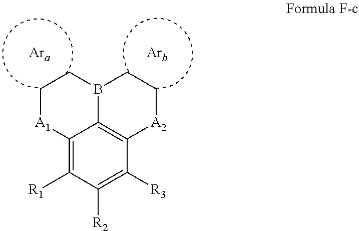

In Formula F-c, A1 and A2 may be each independently O, S, Se, or NRₘ, and Rm may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. R₁ to R₃ are each independently a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined together with an adjacent group to form a ring. Ara and Arb may be each independently a substituted or unsubstituted hydrocarbon ring of 6 to 30 ring-forming carbon atoms or a substituted or unsubstituted heterocycle of 2 to 30 ring-forming carbon atoms. For example, Ara and Arb may be each independently a substituted or unsubstituted benzene ring, a substituted or unsubstituted benzothiophene ring, or a substituted or unsubstituted benzothiazole ring.

In Formula F-c, A1 and A2 may be each independently combined together with the substituents of an adjacent ring to form a fused ring. For example, if A1 and A2 are each independently NRₘ, A1 may be combined together with Ara or Rᵢ to form a ring. In some embodiments, A2 may be combined together with Arb or R₃ to form a ring.

In an embodiment, the first emission layer EML1 may include the first compound including the first moiety among the compounds represented by Formula F-c. The second emission layer EML2 may include the second compound including the second moiety among the compounds represented by Formula F-c. In some embodiments, the first and second emission layers EML1 and EML2 may include the first compound represented by Formula F-c and the second compound represented by Formula F-c, respectively.

For example, in Formula F-c, A2 may be NRₘ, and Rₘ may be a substituted or unsubstituted heteroaryl group of 2 to 30 ring-forming carbon atoms, including the first moiety or the second moiety. For example, A2 may be NRₘ, and Rₘ may be a substituted or unsubstituted benzothiophene group, a substituted or unsubstituted thienopyridine group, a substituted or unsubstituted thienopyrimidine group, a substituted or unsubstituted thienopyridazine group, a substituted or unsubstituted thienopyrazine group, a substituted or unsubstituted thienotriazine group, a substituted or unsubstituted thienotetrazine group, a substituted or unsubstituted benzothiazole group, a substituted or unsubstituted thiazolopyridine group, a substituted or unsubstituted thiazolopyrimidine group, a substituted or unsubstituted thiazolopyridazine group, a substituted or unsubstituted thiazolopyrazine group, a substituted or unsubstituted thiazolotriazine group, a substituted or unsubstituted thiazoloetetrazine group, a substituted or unsubstituted benzothiadiazole group, a substituted or unsubstituted thiadiazolepyridine group, a substituted or unsubstituted thiadiazolepyrimidine group, a substituted or unsubstituted thiadiazolepyridazine group, a substituted or unsubstituted thiadiazolepyrazine group, a substituted or unsubstituted thiadiazoletriazine group, and/or a substituted or unsubstituted thiadiazoletetrazine group. For example, Rₘ may be a substituted or unsubstituted benzothiophene group, a substituted or unsubstituted thienopyridine group, a substituted or unsubstituted benzothiazole group, or a substituted or unsubstituted thiazolopyridine group.

In Formula F-c, one among R₁ to R₃ may be a substituted or unsubstituted heteroarylene group of 2 to 30 ring-forming carbon atoms, including the first moiety or the second moiety. For example, R₆ may be a substituted or unsubstituted benzothiophene group, a substituted or unsubstituted thienopyridine group, a substituted or unsubstituted thienopyrimidine group, a substituted or unsubstituted thienopyridazine group, a substituted or unsubstituted thienopyrazine group, a substituted or unsubstituted thienotriazine group, a substituted or unsubstituted thienotetrazine group, a substituted or unsubstituted benzothiazole group, a substituted or unsubstituted thiazolopyridine group, a substituted or unsubstituted thiazolopyrimidine group, a substituted or unsubstituted thiazolopyridazine group, a substituted or unsubstituted thiazolopyrazine group, a substituted or unsubstituted thiazolotriazine group, a substituted or unsubstituted thiazoloetetrazine group, a substituted or unsubstituted benzothiadiazole group, a substituted or unsubstituted thiadiazolepyridine group, a substituted or unsubstituted thiadiazolepyrimidine group, a substituted or unsubstituted thiadiazolepyridazine group, a substituted or unsubstituted thiadiazolepyrazine group, a substituted or unsubstituted thiadiazoletriazine group, and/or a substituted or unsubstituted thiadiazoletetrazine group.

The first compound or the second compound represented by Formula F-c may be represented by one among the compounds in Compound Group B. However, the compounds shown in Compound Group B are examples, and the first compound or the second compound represented by Formula F-c is not limited to the compounds represented in Compound Group B.

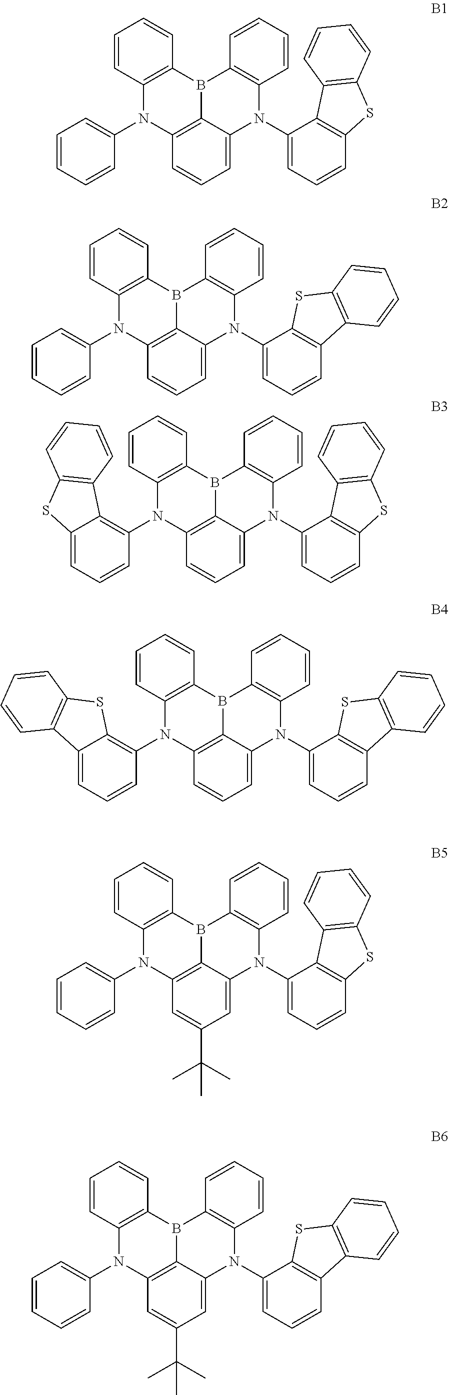

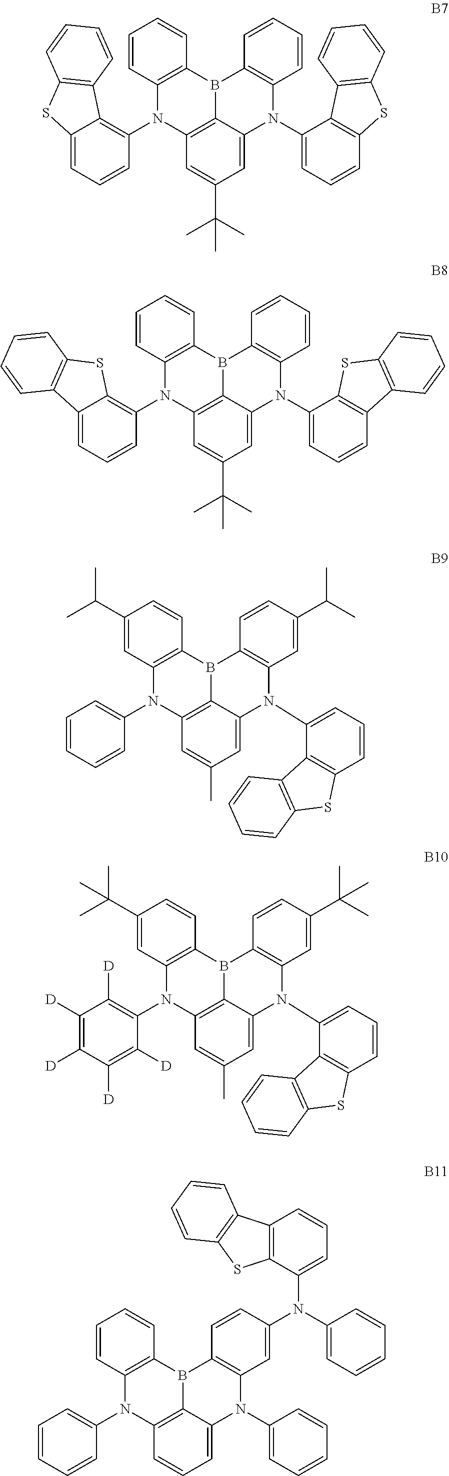 [SMILES: CC(C)(C)c1cc2c3c(c1)N(c1cccc4sc5ccccc5c14)c1ccccc1B3c1ccccc1N2c1cccc2sc3ccccc3c12 ; CC(C)(C)c1cc2c3c(c1)N(c1cccc4c1sc1ccccc14)c1ccccc1B3c1ccccc1N2c1cccc2c1sc1ccccc12 ; Cc1cc2c3c(c1)N(c1cccc4sc5ccccc5c14)c1cc(C(C)C)ccc1B3c1ccc(C(C)C)cc1N2c1ccccc1 ; [2H]c1c([2H])c([2H])c(N2c3cc(C(C)(C)C)ccc3B3c4ccc(C(C)(C)C)cc4N(c4cccc5sc6ccccc6c45)c4cc(C)cc2c43)c([2H])c1[2H] ; c1ccc(N2c3ccccc3B3c4ccc(N(c5ccccc5)c5cccc6c5sc5ccccc56)cc4N(c4ccccc4)c4cccc2c43)cc1]

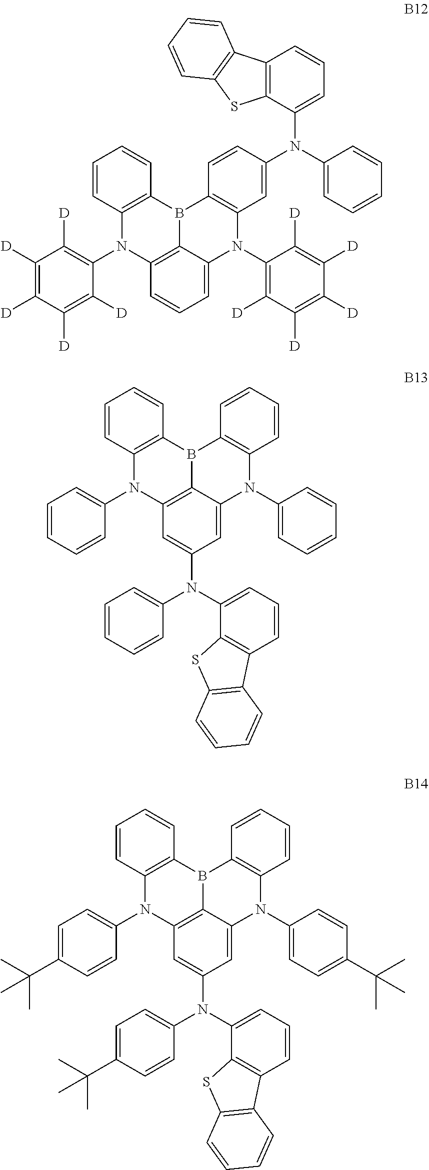 [SMILES: [2H]c1c([2H])c([2H])c(N2c3ccccc3B3c4ccc(N(c5ccccc5)c5cccc6c5sc5ccccc56)cc4N(c4c([2H])c([2H])c([2H])c([2H])c4[2H])c4cccc2c43)c([2H])c1[2H] ; c1ccc(N2c3ccccc3B3c4ccccc4N(c4ccccc4)c4cc(N(c5ccccc5)c5cccc6c5sc5ccccc56)cc2c43)cc1 ; CC(C)(C)c1ccc(N2c3ccccc3B3c4ccccc4N(c4ccc(C(C)(C)C)cc4)c4cc(N(c5ccc(C(C)(C)C)cc5)c5cccc6c5sc5ccccc56)cc2c43)cc1]

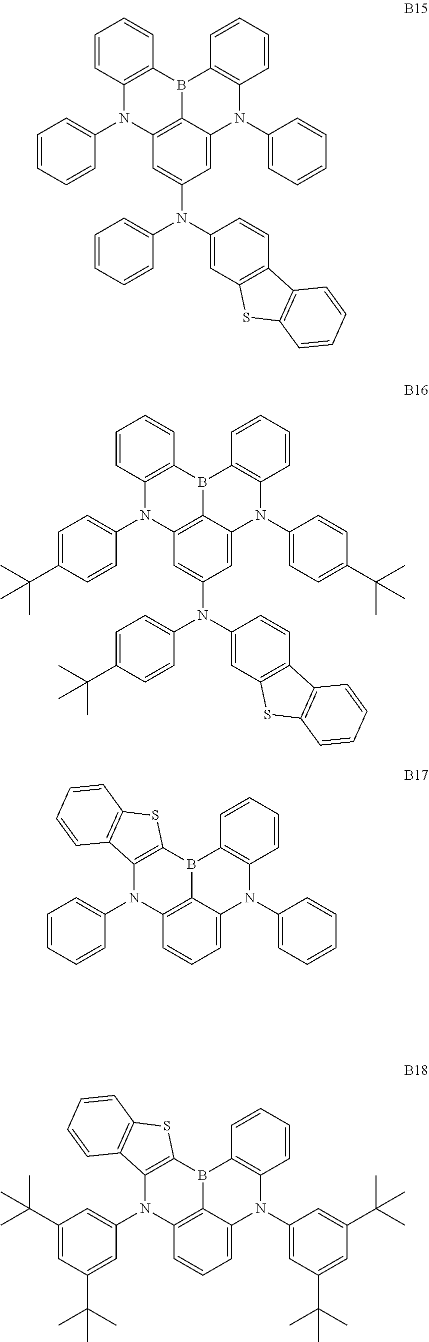

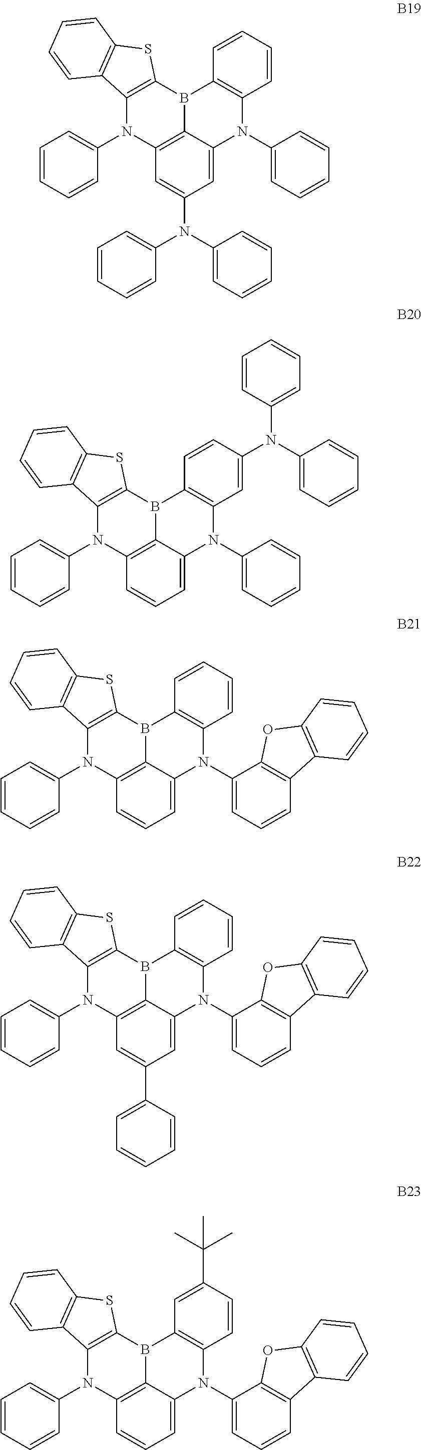

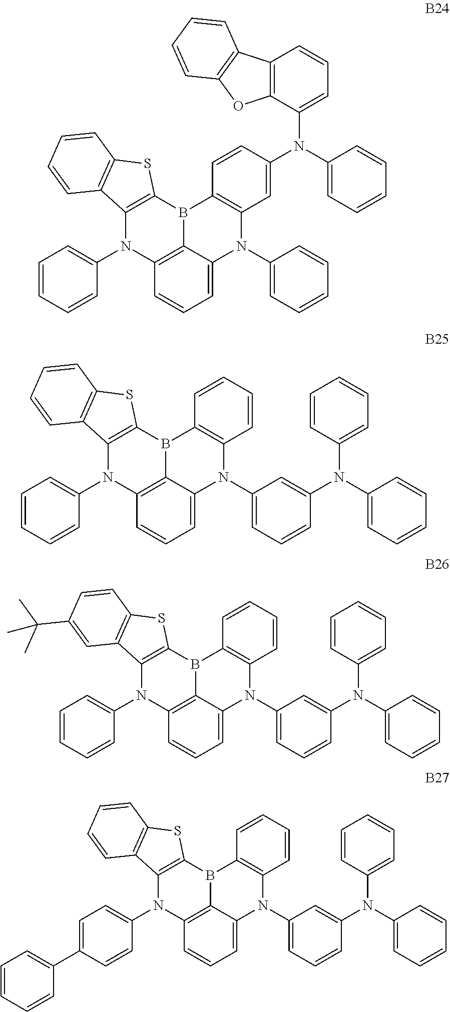 [SMILES: c1ccc(N2c3cc(N(c4ccccc4)c4cccc5c4oc4ccccc45)ccc3B3c4sc5ccccc5c4N(c4ccccc4)c4cccc2c43)cc1 ; c1ccc(N(c2ccccc2)c2cccc(N3c4ccccc4B4c5sc6ccccc6c5N(c5ccccc5)c5cccc3c54)c2)cc1 ; CC(C)(C)c1ccc2sc3c(c2c1)N(c1ccccc1)c1cccc2c1B3c1ccccc1N2c1cccc(N(c2ccccc2)c2ccccc2)c1 ; c1ccc(-c2ccc(N3c4cccc5c4B(c4ccccc4N5c4cccc(N(c5ccccc5)c5ccccc5)c4)c4sc5ccccc5c43)cc2)cc1]

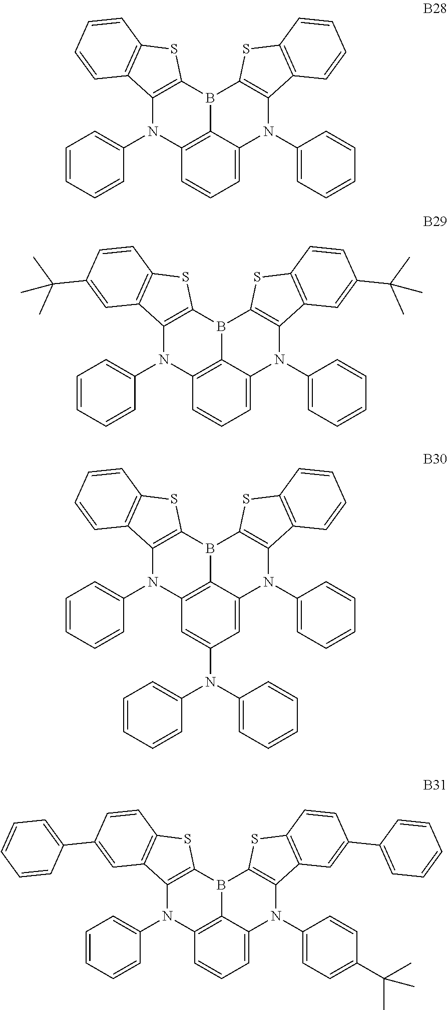

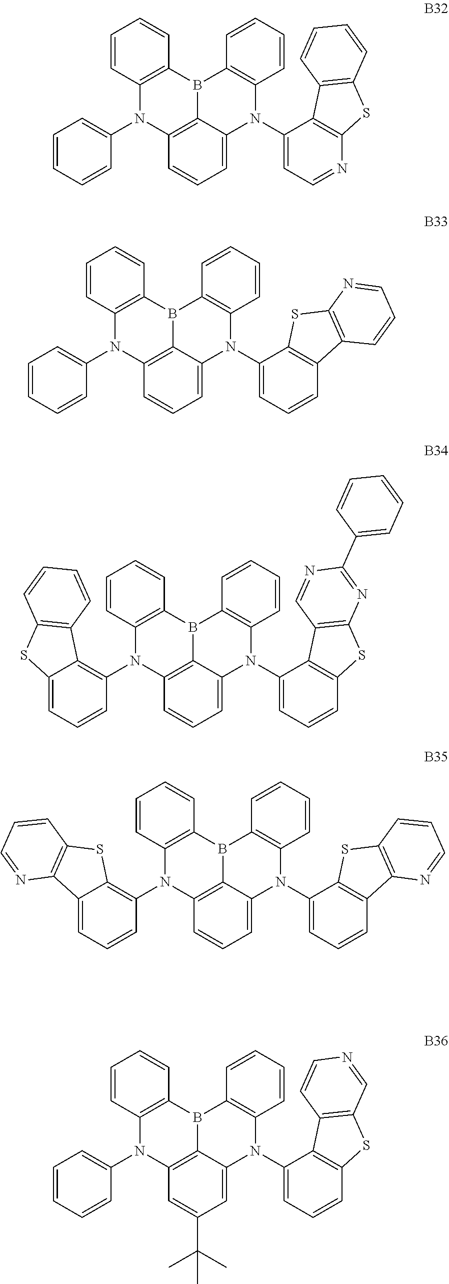 [SMILES: c1ccc(N2c3ccccc3B3c4ccccc4N(c4ccnc5sc6ccccc6c45)c4cccc2c43)cc1 ; c1ccc(N2c3ccccc3B3c4ccccc4N(c4cccc5c4sc4ncccc45)c4cccc2c43)cc1 ; c1ccc(-c2ncc3c(n2)sc2cccc(N4c5ccccc5B5c6ccccc6N(c6cccc7sc8ccccc8c67)c6cccc4c65)c23)cc1 ; c1ccc2c(c1)B1c3ccccc3N(c3cccc4c3sc3cccnc34)c3cccc(c31)N2c1cccc2c1sc1cccnc12 ; CC(C)(C)c1cc2c3c(c1)N(c1cccc4sc5cnccc5c14)c1ccccc1B3c1ccccc1N2c1ccccc1]

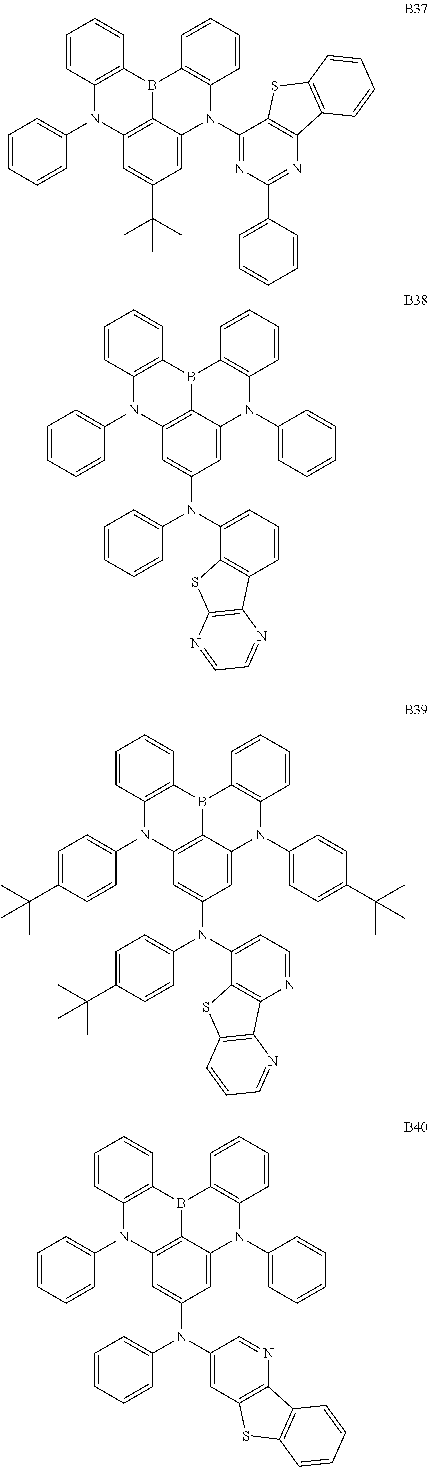

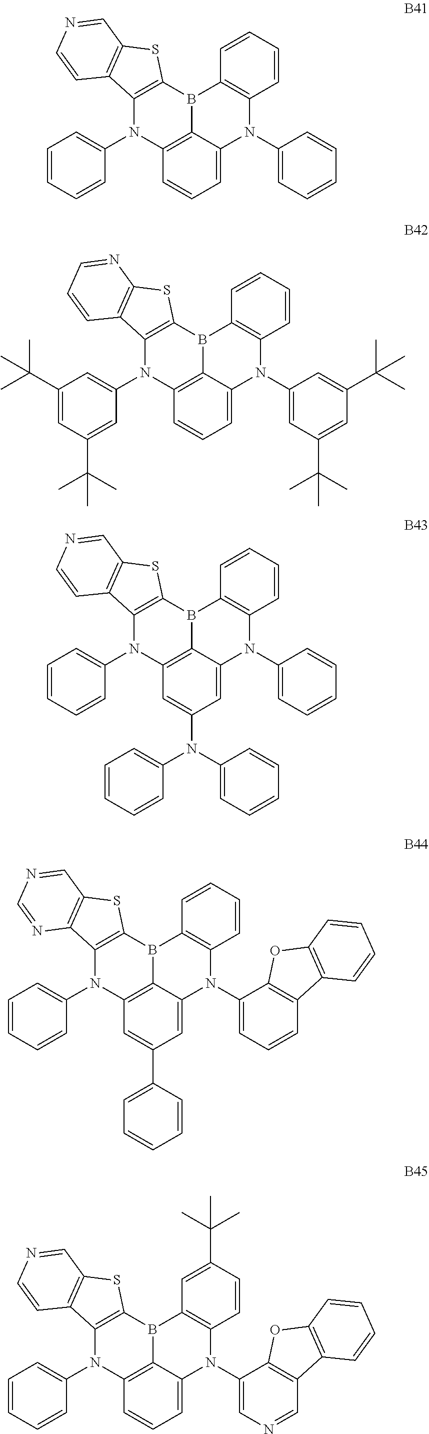

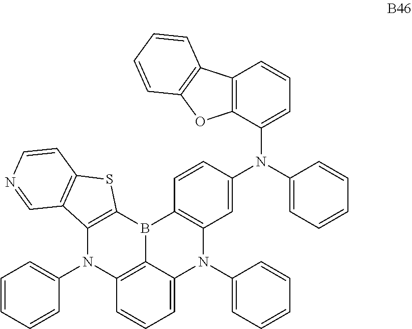 [SMILES: c1ccc(N2c3cc(N(c4ccccc4)c4cccc5c4oc4ccccc45)ccc3B3c4sc5ccncc5c4N(c4ccccc4)c4cccc2c43)cc1]

In an embodiment, each of the emission layers EML1 and EML2 may further include as a dopant material, styryl derivatives (for example, 1,4-bis [2-(3-N-ethylcarbazoryl) vinyl] benzene (BCzVB), 4-(di-p-tolylamino)-4′-[(di-p-tolylamino) styryl] stilbene (DPAVB), N-(4-((E)-2-(6-((E)-4-(diphenylamino) styryl) naphthalen-2-yl) vinyl)phenyl)-N-phenylbenzenamine (N-BDAVBi), and 4,4′-bis [2-(4-(N,N-diphenylamino)phenyl) vinyl] biphenyl(DPAVBi)), perylene and the derivatives thereof (for example, 2,5,8,11-tetra-t-butylperylene (TBP)), pyrene and the derivatives thereof (for example, 1,1-dipyrene, 1,4-dipyrenylbenzene, and 1,4-bis(N,N-diphenylamino) pyrene), etc.

Each of the emission layers EML1 and EML2 may further include any suitable phosphorescence dopant material. For example, the phosphorescence dopant may use a metal complex including iridium (Ir), platinum (Pt), osmium (Os), gold (Au), titanium (Ti), zirconium (Zr), hafnium (Hf), europium (Eu), terbium (Tb) or thulium (Tm). In some embodiments, iridium (III) bis(4,6-difluorophenylpyridinato-N,C2) picolinate (Flrpic), bis(2,4-difluorophenylpyridinato)-tetrakis(1-pyrazolyl) borate iridium (III) (Fir6), and/or platinum octaethyl porphyrin (PtOEP) may be used as the phosphorescence dopant. However, embodiments of the present disclosure are not limited thereto.

Each of the emission layers EML1 and EML2 may include a quantum dot material. The core of the quantum dot may be selected from a II-VI group compound, a III-VI group compound, a I—III—VI group compound, a III—V group compound, a III—II—V group compound, a IV—VI group compound, a IV group element, a IV group compound, and combinations thereof.

The II-VI group compound may be selected from the group consisting of: a binary compound selected from the group consisting of CdSe, CdTe, CdS, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

The III-VI group compound may include a binary compound such as In₂S₃, and/or In₂Se₃, a ternary compound such as InGaSs, and/or InGaSes, or optional combinations thereof.

The I—III—VI group compound may be selected from a ternary compound selected from the group consisting of AgInS, AgInS₂, CulnS, CulnS₂, AgGaS₂, CuGaS₂, CuGaO₂, AgGaO₂, AgAIO₂ and mixtures thereof, and/or a quaternary compound such as AglnGaS₂, and/or CulnGaS₂.

The III-V group compound may be selected from the group consisting of a binary compound selected from the group consisting of GaN, GaP, GaAs, GaSb, AlN, AIP, AIAs, AISb, InN, InP, InAs, InSb, and mixtures thereof, a ternary compound selected from the group consisting of GaNP, GaNAs, GaNSb, GaPAs, GaPSb, AlNP, AlNAs, AlNSb, AIPAs, AIPSb, InGaP, InAIP, InNP, InNAs, InNSb, InPAs, InPSb, and mixtures thereof, and a quaternary compound selected from the group consisting of GaAINP, GaAINAs, GaAINSb, GaAIPAs, GaAIPSb, GalnNP, GalnNAs, GalnNSb, GalnPAs, GalnPSb, InAINP, InAINAs, InAINSb, InAIPAs, InAIPSb, and mixtures thereof. In some embodiments, the III-V group compound may further include a II group metal. For example, InZnP, etc. may be selected as a III—II—V group compound.

The IV-VI group compound may be selected from the group consisting of a binary compound selected from the group consisting of SnS, SnSe, SnTe, PbS, PbSe, PbTe, and mixtures thereof, a ternary compound selected from the group consisting of SnSeS, SnSeTe, SnSTe, PbSeS, PbSeTe, PbSTe, SnPbS, SnPbSe, SnPbTe, and mixtures thereof, and a quaternary compound selected from the group consisting of SnPbSSe, SnPbSeTe, SnPbSTe, and mixtures thereof. The IV group element may be selected from the group consisting of Si, Ge, and a mixture thereof. The IV group compound may be a binary compound selected from the group consisting of SiC, SiGe, and a mixture thereof.

Each element included in the polynary compound such as the binary compound, the ternary compound and the quaternary compound may be present at uniform concentration or at non-uniform concentration in a particle. In some embodiments, the chemical formulae mean the types (or kinds) of the elements included in the compound, and the atomic ratio in the compound may be different. For example, AgInGaS₂ may mean AgInₓGa₁₋ₓS₂ (x is a real number between 0-1).

In some embodiments, the quantum dot may have a single structure in which the concentration of each element included in the quantum dot is uniform (or substantially uniform), or a core-shell double structure. For example, a material included in the core and a material included in the shell may be different from each other.

The shell of the quantum dot may play the role of a protection layer for preventing or reducing the chemical deformation of the core to maintain semiconductor properties and/or a charging layer for imparting the quantum dot with electrophoretic properties. The shell may have a single layer or a multilayer. The interface between the core and the shell may have a concentration gradient in which the concentration of an element present in the shell is decreased along a direction toward the center of the core.

In some embodiments, the quantum dot may have the above-described core-shell structure including a core including a nanocrystal and a shell wrapping the core. The shell of the quantum dot may play the role of a protection layer for preventing or reducing the chemical deformation of the core to maintain semiconductor properties and/or a charging layer for imparting the quantum dot with electrophoretic properties. The shell may have a single layer or a multilayer. Examples of the shell of the quantum dot may include a metal and/or non-metal oxide, a semiconductor compound, or combinations thereof.

For example, the metal and/or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and/or NiO, and/or a ternary compound such as MgAl₂O₄, CoFe₂O₄, NiFe₂O₄ and/or CoMn₂O₄, but embodiments of the present disclosure are not limited thereto.

Also, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AIP, AISb, etc., but embodiments of the present disclosure are not limited thereto.

Each element included in the polynary compound such as the binary compound and the ternary compound may be present at uniform concentration or at non-uniform concentration in a particle. As noted above, in some embodiments, the chemical formulae mean the types (or kinds) of the elements included in the compound, and the atomic ratio in the compound may be different.

The quantum dot may have a full width of half maximum (FWHM) of emission wavelength spectrum of about 45 nm or less, for example, about 40 nm or less, or about 30 nm or less. Within these ranges, color purity and/or color reproducibility may be improved. In some embodiments, light emitted via such quantum dot is emitted in all (or substantially all) directions, and light view angle properties may be improved.

In some embodiments, the shape of the quantum dot may be any suitable shapes generally used in the art, without specific limitation. In some embodiments, the shape of spherical, pyramidal, multi-arm, and/or cubic nanoparticle, nanotube, nanowire, nanofiber, nanoplate particle, etc. may be used.

By controlling the size of the quantum dot or by controlling the element ratio in the quantum dot compound, an energy band gap may be controlled, and various suitable wavelength bands of light may be obtained from a quantum dot emission layer. Accordingly, by using the quantum dot (using quantum dots having different sizes or controlling an element ratio in a quantum dot compound differently), a light emitting element emitting various suitable wavelengths of light may be accomplished. In some embodiments, the size of the quantum dot or the element ratio in the quantum dot compound may be controlled to emit red, green and/or blue light. In some embodiments, the quantum dots may be provided to combine together various suitable emission colors to emit white light.

The electron transport regions ETR1 and ETR2 may respectively include at least one selected from a hole blocking layer, electron transport layers ETL1 and ETL2, and electron injection layers EIL1 and EIL2. However, embodiments of the present disclosure are not limited thereto.

Each of the electron transport regions ETR1 and ETR2 may have a single layer formed using a single material, a single layer formed using a plurality of different materials, or a multilayer structure having a plurality of layers formed using a plurality of different materials.

For example, the electron transport regions ETR1 and ETR2 may have single layer structures of electron injection layers EIL1 and EIL2 or electron transport layers ETL1 and ETL2, or single layer structures formed using an electron injection material and an electron transport material, respectively. Further, the electron transport regions ETR1 and ETR2 may respectively have single layer structures formed using a plurality of different materials, or structures stacked from the emission layers EML1 and EML2 of electron transport layers ETL1 and ETL2/electron injection layers EIL1 and EIL2, a hole blocking layer/electron transport layers ETL1 and

ETL2/electron injection layers EIL1 and EIL2, and/or the like, without limitation. The thickness of each of the electron transport regions ETR1 and ETR2 may be, for example, from about 1,000 Å to about 1,500 Å.

The electron transport regions ETR1 and ETR2 may be formed using various suitable methods such as a vacuum deposition method, a spin coating method, a cast method, a Langmuir-Blodgett (LB) method, an inkjet printing method, a laser printing method, and/or a laser induced thermal imaging (LITI) method.

Each of the electron transport regions ETR1 and ETR2 may include a compound represented by Formula ET-1 below.

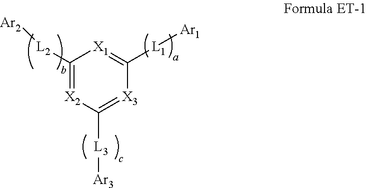

In Formula ET-1, at least one among X₁ to X₃ is N, and the remainder are CRₐ. Rₐ may be a hydrogen atom, a deuterium atom, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. Ar₁ to Ar₃ may be each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-1, “a” to “c” may be each independently an integer of 0 to 10. In Formula ET-1, L₁ to L₃ may be each independently a direct linkage, a substituted or unsubstituted arylene group of 6 to 30 ring-forming carbon atoms, or a substituted or unsubstituted heteroarylene group of 2 to 30 ring-forming carbon atoms. In some embodiments, if “a” to “c” are integers of 2 or more, L₁ to L₃ may be each independently a substituted or unsubstituted arylene group of 6 to 30 ring-forming carbon atoms, or a substituted or unsubstituted heteroarylene group of 2 to 30 ring-forming carbon atoms.

In an embodiment, the first electron transport region ETR1 may include the first compound including the first moiety represented by Formula ET-1. The second electron transport region ETR2 may include the second compound including the second moiety represented by Formula ET-1. In some embodiments, the first and second electron transport regions ETR1 and ETR2 may include the first compound represented by Formula ET-1 and the second compound represented by Formula ET-1, respectively.

In Formula ET-1, one among Ar₁ to Ar₃ may be a substituted or unsubstituted heteroaryl group of 2 to 30 ring-forming carbon atoms, including the first moiety or the second moiety. For example, one among Ar₁ to Ar₃ may be each independently one among a substituted or unsubstituted benzothiophene group, a substituted or unsubstituted thienopyridine group, a substituted or unsubstituted thienopyrimidine group, a substituted or unsubstituted thienopyridazine group, a substituted or unsubstituted thienopyrazine group, a substituted or unsubstituted thienotriazine group, a substituted or unsubstituted thienotetrazine group, a substituted or unsubstituted benzothiazole group, a substituted or unsubstituted thiazolopyridine group, a substituted or unsubstituted thiazolopyrimidine group, a substituted or unsubstituted thiazolopyridazine group, a substituted or unsubstituted thiazolopyrazine group, a substituted or unsubstituted thiazolotriazine group, a substituted or unsubstituted thiazoloetetrazine group, a substituted or unsubstituted benzothiadiazole group, a substituted or unsubstituted thiadiazolepyridine group, a substituted or unsubstituted thiadiazolepyrimidine group, a substituted or unsubstituted thiadiazolepyridazine group, a substituted or unsubstituted thiadiazolepyrazine group, a substituted or unsubstituted thiadiazoletriazine group, and a substituted or unsubstituted thiadiazoletetrazine group. For example, one among Ar₁ to Ar₃ may be each independently a substituted or unsubstituted benzothiophene group, a substituted or unsubstituted thienopyridine group, a substituted or unsubstituted benzothiazole group, or a substituted or unsubstituted thiazolopyridine group.

The first compound or the second compound represented by Formula ET-1 may be represented by one among the compounds in Compound Group E. However, the compounds shown in Compound Group E are examples, and the first compound or the second compound represented by Formula ET-1 is not limited to the compounds represented in Compound Group E.

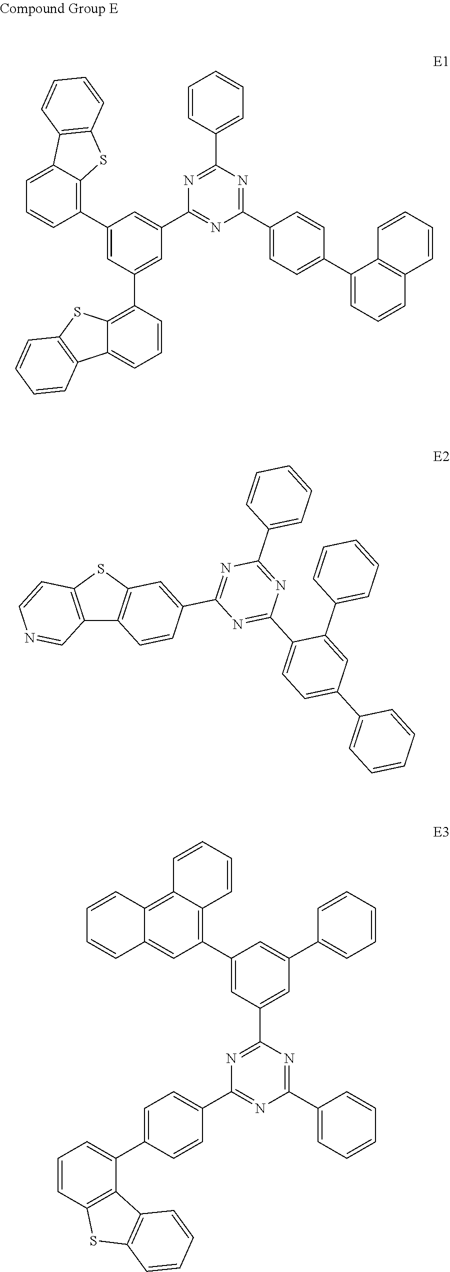 [SMILES: c1ccc(-c2nc(-c3ccc(-c4cccc5ccccc45)cc3)nc(-c3cc(-c4cccc5c4sc4ccccc45)cc(-c4cccc5c4sc4ccccc45)c3)n2)cc1 ; c1ccc(-c2ccc(-c3nc(-c4ccccc4)nc(-c4ccc5c(c4)sc4ccncc45)n3)c(-c3ccccc3)c2)cc1 ; c1ccc(-c2cc(-c3nc(-c4ccccc4)nc(-c4ccc(-c5cccc6sc7ccccc7c56)cc4)n3)cc(-c3cc4ccccc4c4ccccc34)c2)cc1]

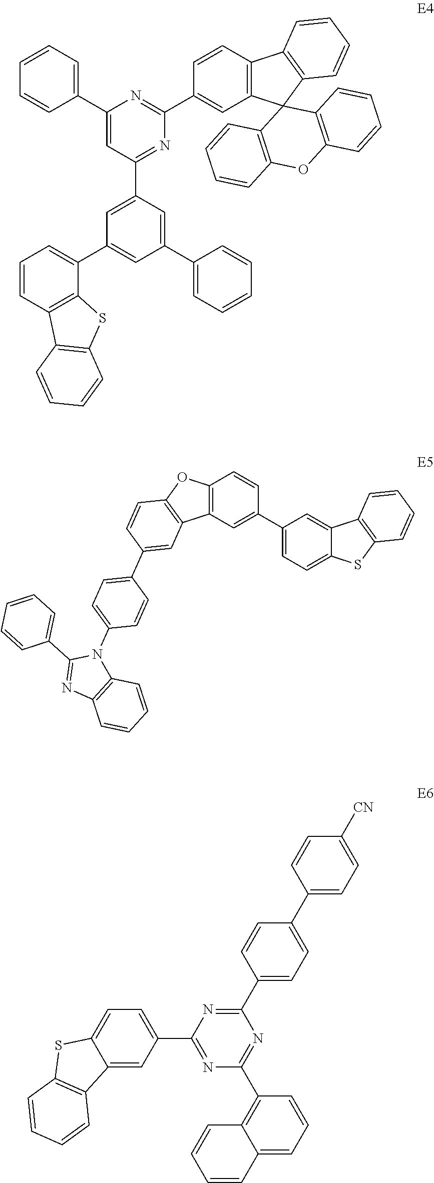 [SMILES: c1ccc(-c2cc(-c3cc(-c4ccccc4)nc(-c4ccc5c(c4)C4(c6ccccc6Oc6ccccc64)c4ccccc4-5)n3)cc(-c3cccc4c3sc3ccccc34)c2)cc1 ; c1ccc(-c2nc3ccccc3n2-c2ccc(-c3ccc4oc5ccc(-c6ccc7sc8ccccc8c7c6)cc5c4c3)cc2)cc1 ; N#Cc1ccc(-c2ccc(-c3nc(-c4ccc5sc6ccccc6c5c4)nc(-c4cccc5ccccc45)n3)cc2)cc1]

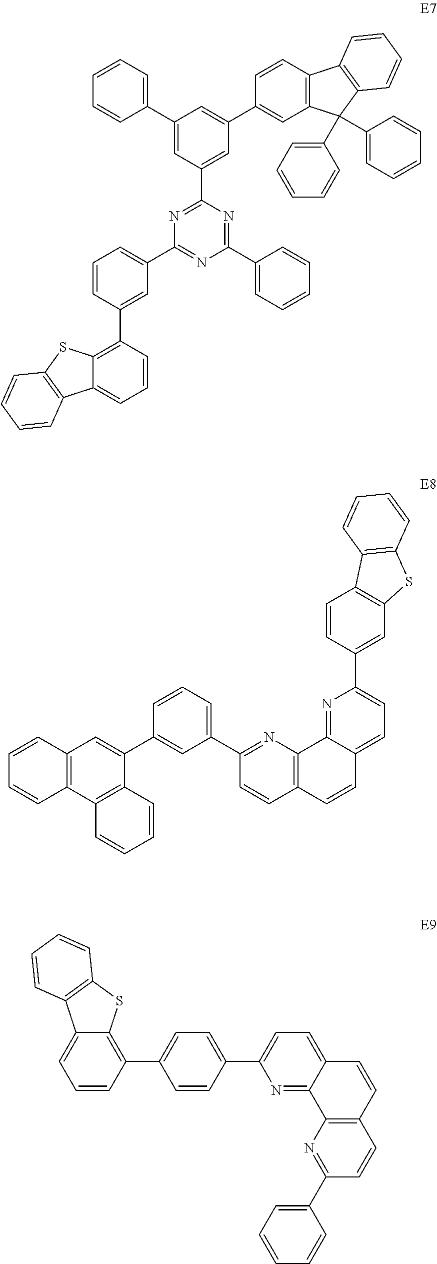 [SMILES: c1ccc(-c2cc(-c3ccc4c(c3)C(c3ccccc3)(c3ccccc3)c3ccccc3-4)cc(-c3nc(-c4ccccc4)nc(-c4cccc(-c5cccc6c5sc5ccccc56)c4)n3)c2)cc1 ; c1cc(-c2ccc3ccc4ccc(-c5ccc6c(c5)sc5ccccc56)nc4c3n2)cc(-c2cc3ccccc3c3ccccc23)c1 ; c1ccc(-c2ccc3ccc4ccc(-c5ccc(-c6cccc7c6sc6ccccc67)cc5)nc4c3n2)cc1]

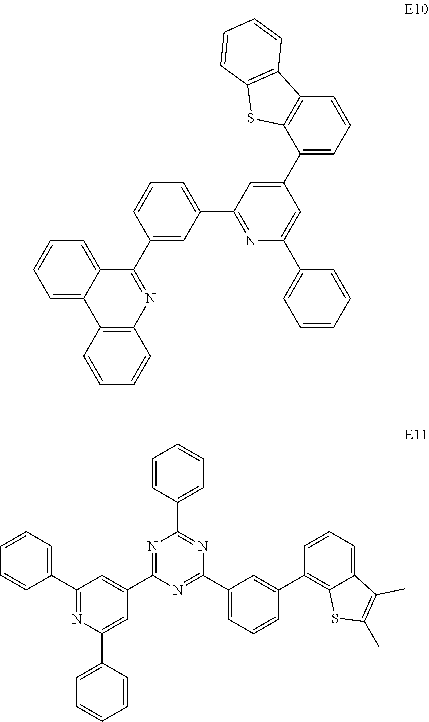 [SMILES: c1ccc(-c2cc(-c3cccc4c3sc3ccccc34)cc(-c3cccc(-c4nc5ccccc5c5ccccc45)c3)n2)cc1 ; Cc1sc2c(-c3cccc(-c4nc(-c5ccccc5)nc(-c5cc(-c6ccccc6)nc(-c6ccccc6)c5)n4)c3)cccc2c1C]

Each of the electron transport regions ETR1 and ETR2 may include an anthracene-based compound. However, embodiments of the present disclosure are not limited thereto, and the electron transport region ETR may include, for example, tris(8-hydroxyquinolinato)aluminum (Alq₃), 1,3,5-tri [(3-pyridyl)-phen-3-yl]benzene, 2,4,6-tris(3′-(pyridin-3-yl) biphenyl-3-yl)-1,3,5-triazine, 2-(4-(N-phenylbenziimidazol-1-ylphenyl)-9,10-dinaphthylanthracene, 1,3,5-tri (1-phenyl-1H-benz [d] imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,08)-(1,1′-biphenyl-4-olato)aluminum (BAlq), berylliumbis(benzoquinolin-10-olate (Bebq2), 9,10-di(naphthalene-2-yl) anthracene (ADN), 1,3-bis [3,5-di(pyridin-3-yl)phenyl]benzene (BmPyPhB), and/or mixtures thereof, without limitation.

The electron transport regions ETR1 and ETR2 may include at least one among Compounds ET1 to ET37 below.

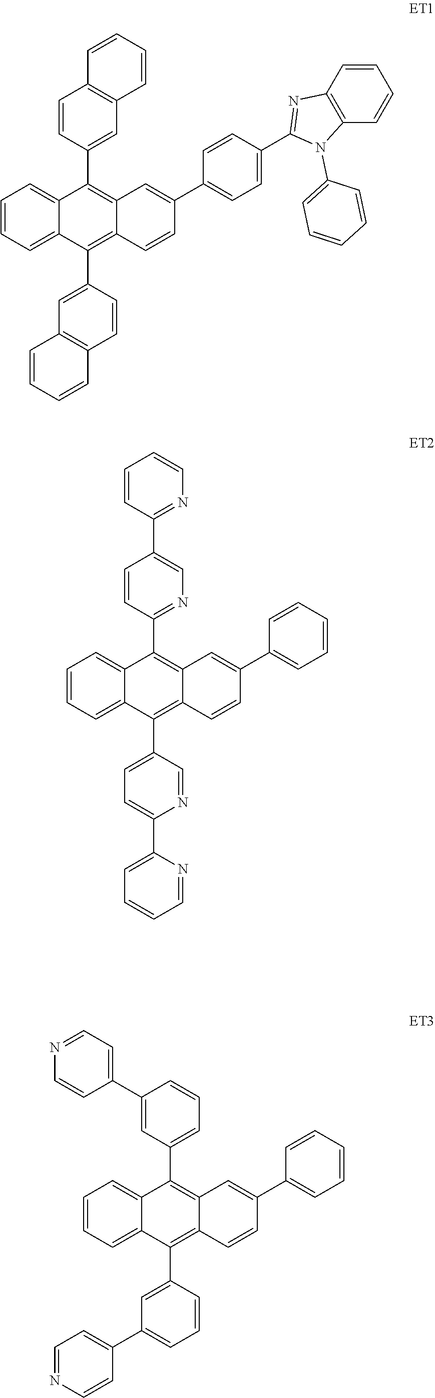 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)cn4)c3c2)cc1 ; c1ccc(-c2ccc3c(-c4cccc(-c5ccncc5)c4)c4ccccc4c(-c4cccc(-c5ccncc5)c4)c3c2)cc1]

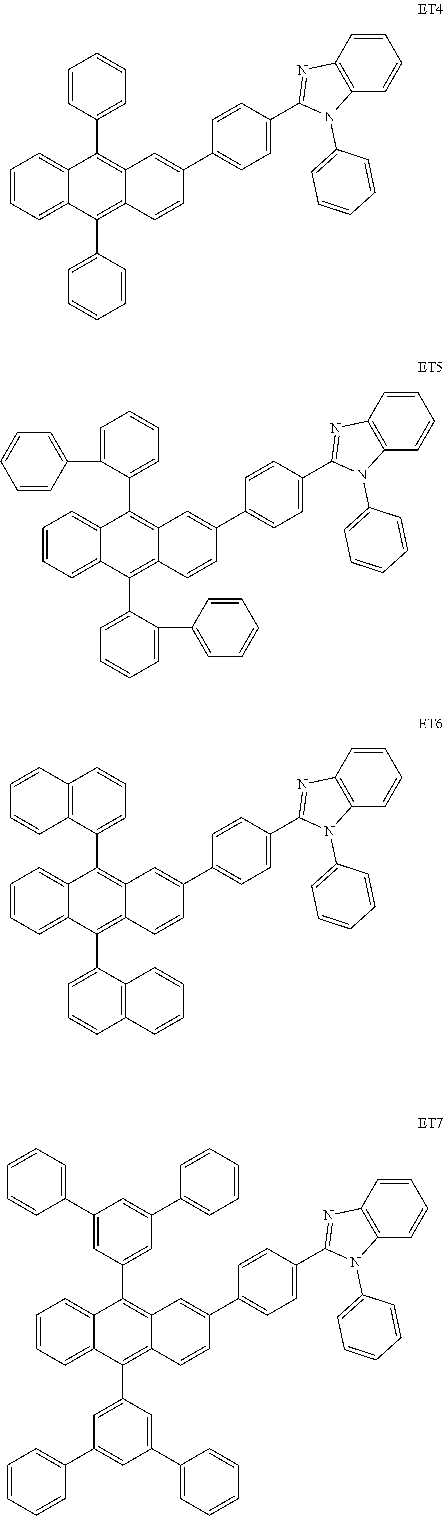 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

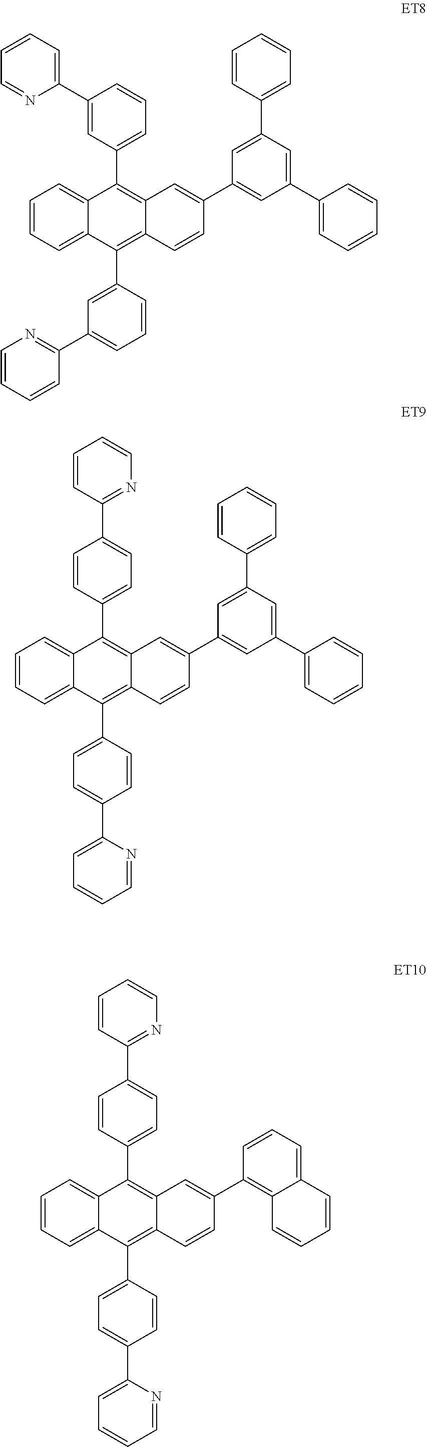 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

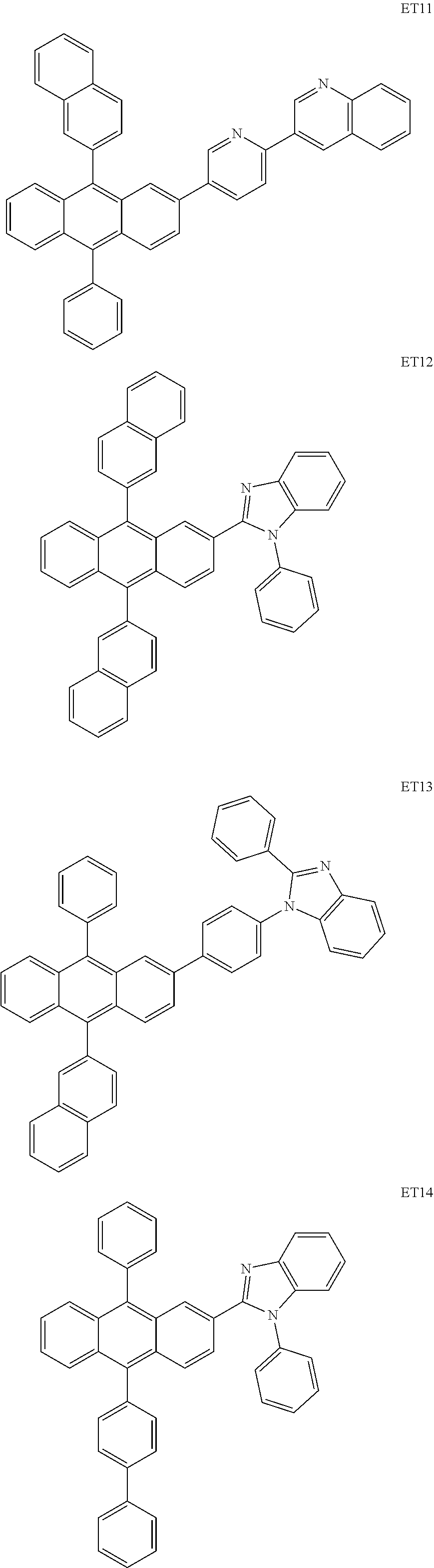 [SMILES: c1ccc(-c2c3ccccc3c(-c3ccc4ccccc4c3)c3cc(-c4ccc(-c5cnc6ccccc6c5)nc4)ccc23)cc1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1]

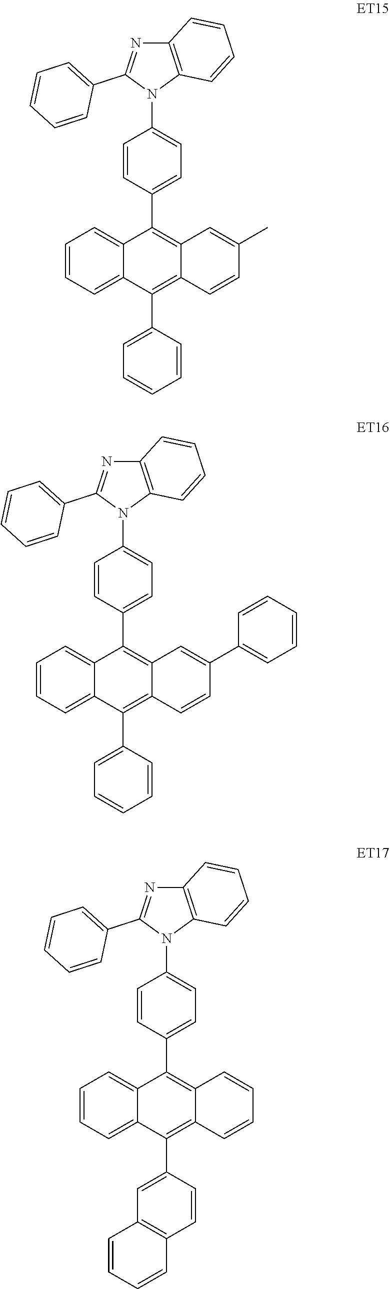

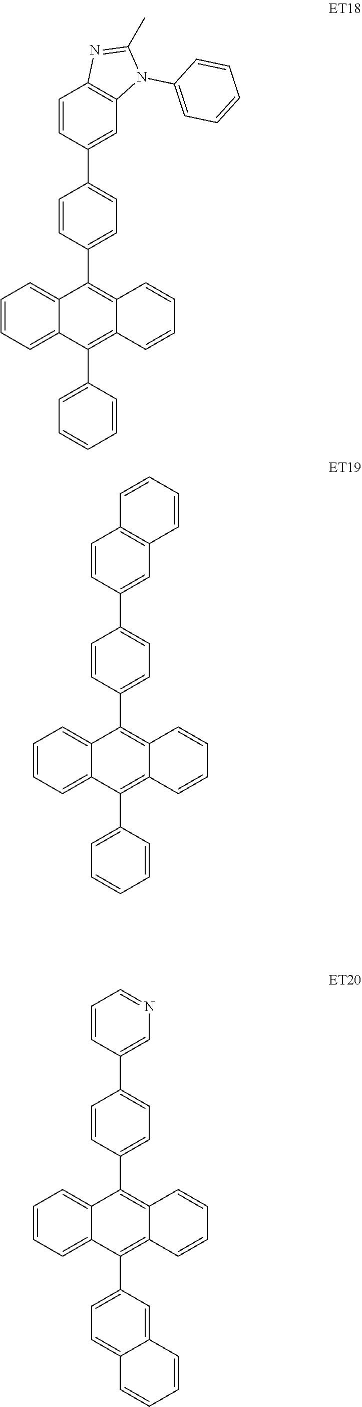

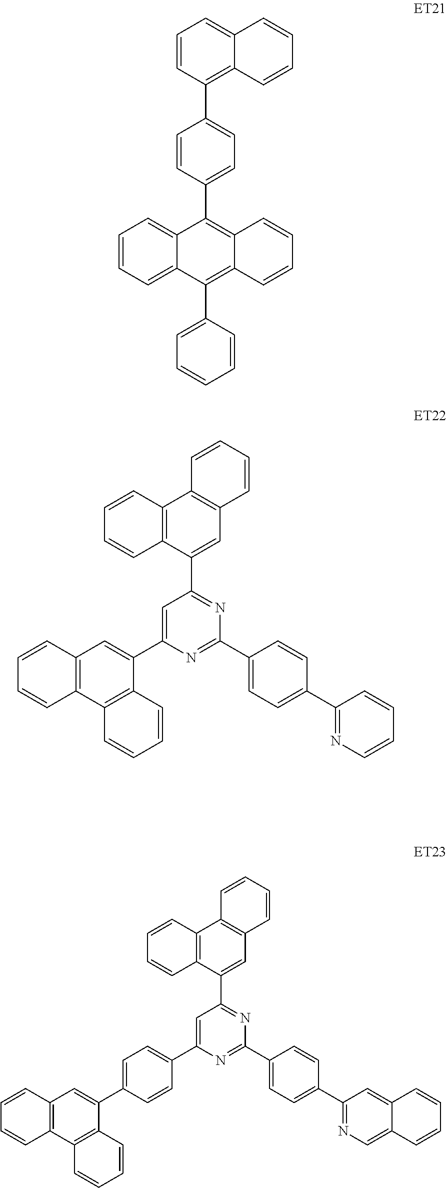

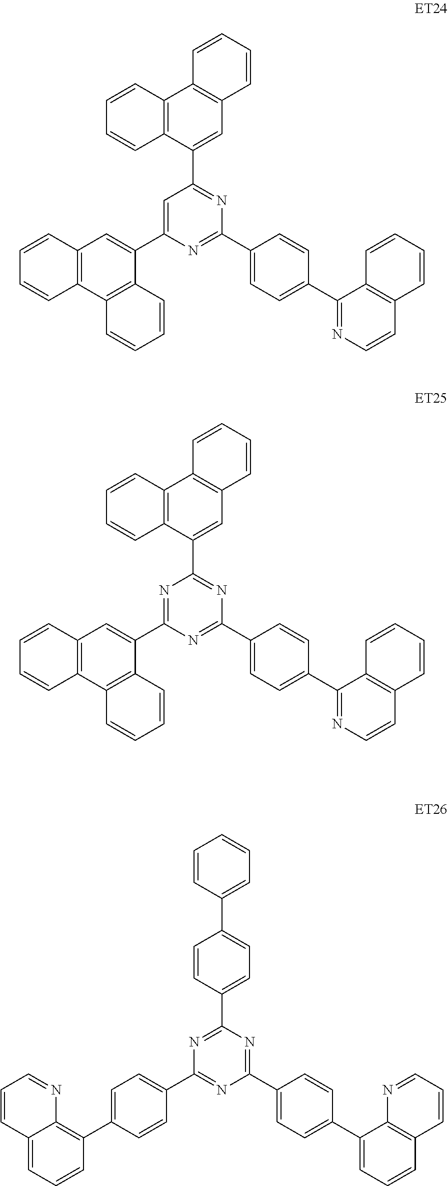 [SMILES: c1ccc2c(-c3ccc(-c4nc(-c5cc6ccccc6c6ccccc56)cc(-c5cc6ccccc6c6ccccc56)n4)cc3)nccc2c1 ; c1ccc2c(-c3ccc(-c4nc(-c5cc6ccccc6c6ccccc56)nc(-c5cc6ccccc6c6ccccc56)n4)cc3)nccc2c1 ; c1ccc(-c2ccc(-c3nc(-c4ccc(-c5cccc6cccnc56)cc4)nc(-c4ccc(-c5cccc6cccnc56)cc4)n3)cc2)cc1]

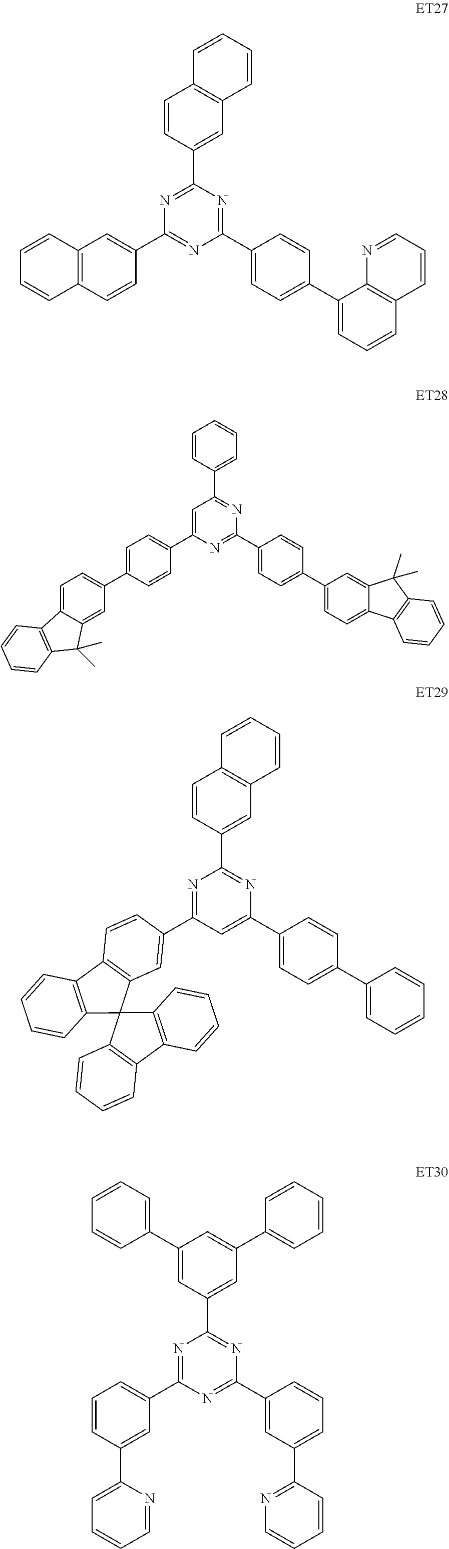 [SMILES: c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4cc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

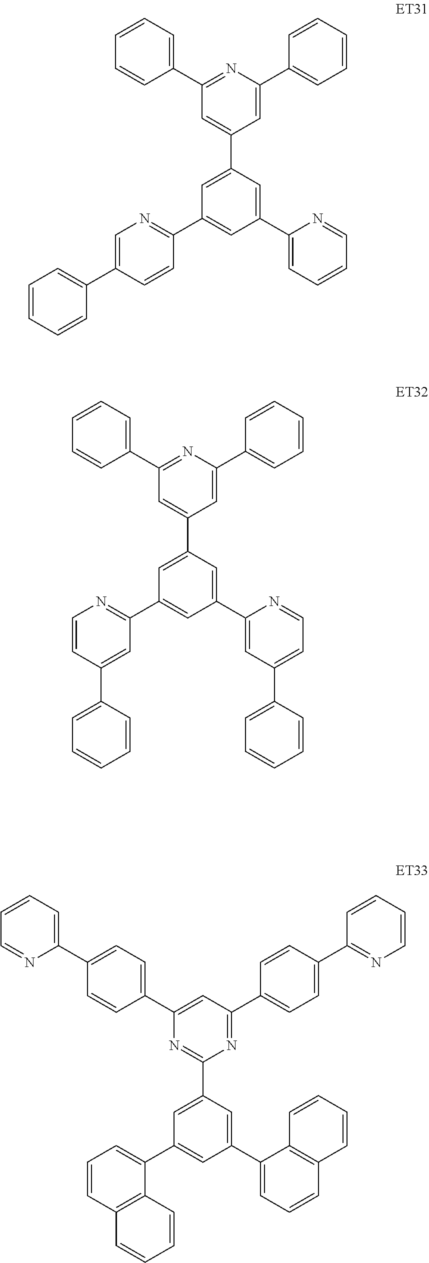 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

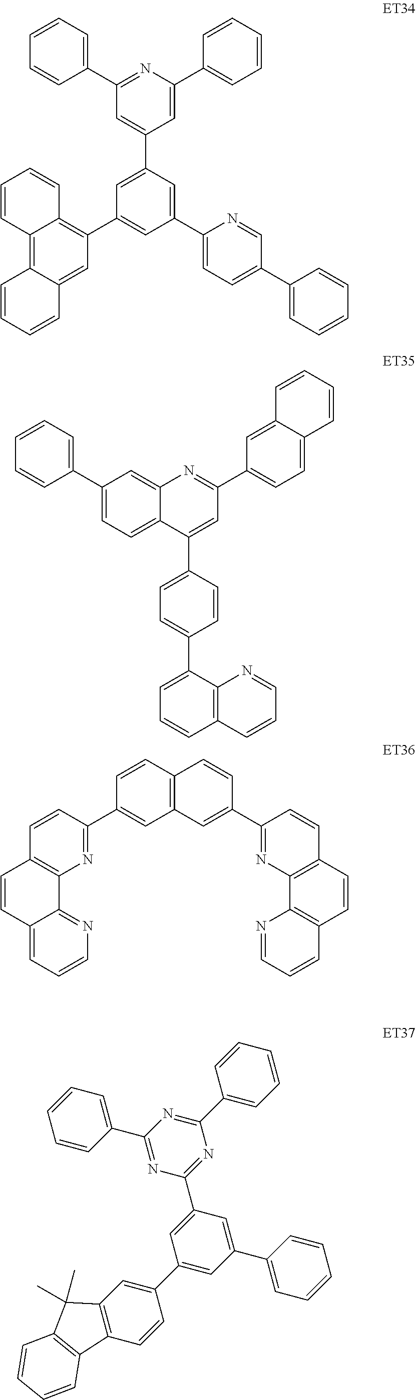

In some embodiments, each of the electron transport regions ETR1 and ETR2 may include a metal halide such as LiF, NaCl, CsF, RbCI, Rbl, Cul and KI, a metal of the lanthanoides such as Yb, and/or a co-depositing material of the metal halide and the metal of the lanthanoides. For example, the first electron transport region ETR1 may include KI: Yb, Rbl: Yb, LiF: Yb, etc., as the co-depositing material. In some embodiments, the electron transport region ETR may use a metal oxide such as LizO and/or BaO, and/or 8-hydroxy-lithium quinolate (Liq). However, embodiments of the present disclosure are not limited thereto. The electron transport region ETR also may be formed using a mixture material of an electron transport material and an insulating organo metal salt (e.g., an electrically insulating organo metal salt). The organo metal salt may be a material having an energy band gap of about 4 eV or more. In some embodiments, the organo metal salt may include, for example, metal acetates, metal benzoates, metal acetoacetates, metal acetylacetonates, and/or metal stearates.

Each of the electron transport regions ETR1 and ETR2 may further include at least one of 2,9-dimethyl-4,7-diphenyl-1,10-phenanthroline (BCP), diphenyl(4-(triphenylsilyl)phenyl)phosphine oxide (TSPO1) and/or 4,7-diphenyl-1,10-phenanthroline (Bphen) in addition to the aforementioned materials. However, embodiments of the present disclosure are not limited thereto.

The electron transport regions ETR1 and ETR2 may include the compounds of the electron transport region in at least one among electron injection layers EIL1 and EIL2, electron transport layers ETL1 and ETL2, and hole blocking layers, respectively.

If the electron transport regions ETR1 and ETR2 include the electron transport layers ETL1 and ETL2, the thicknesses of the electron transport layers ETL1 and ETL2 may be from about 100 Å to about 1,000 Å, for example, from about 150 Å to about 500 Å. If the thicknesses of the electron transport layers ETL1 and ETL2 satisfy the above-described ranges, suitable or satisfactory electron transport properties may be obtained without substantial increase of a driving voltage. If the electron transport regions ETR1 and ETR2 include the electron injection layers EIL1 and EIL2, the thicknesses of the electron transport regions ETR1 and ETR2 may be from about 1 Å to about 100 Å, and/or from about 3 Å to about 90 Å. If the thicknesses of the electron injection layers EIL1 and EIL2 satisfy the above described ranges, suitable or satisfactory electron injection properties may be obtained without inducing substantial increase of a driving voltage.

In FIG. 3A to FIG. 3D, elements constituting each of a first light emitting unit OL1 and a second light emitting unit OL2 are shown correspondingly, but the stacked structures of the first light emitting unit OL1 and the second light emitting unit OL2 are not limited thereto, and may be provided in diverse combinations according to the properties of display quality required for a light emitting element ED. For example, in the light emitting element ED of another embodiment, the second hole transport region HTR2 of the second light emitting unit OL2 may have a structure including second emission auxiliary layers SE-R2, SE-G2 and SE-B2, and the first hole transport region HTR1 of the first light emitting unit OL1 may have a structure not including first emission auxiliary layers SE-R1, SE-G1 and SE-B1. In some embodiments, the second hole transport region HTR2 of the second light emitting unit OL2 may have a structure not including second emission auxiliary layers SE-R2, SE-G2 and SE-B2, and the first hole transport region HTR1 of the first light emitting unit OL1 may have a structure including first emission auxiliary layers SE-R1, SE-G1 and SE-B1.

In some embodiments, a charge generation unit CGL is between the first light emitting unit OL1 and the second light emitting unit OL2. If a voltage is applied to the charge generation unit CGL, a complex may be formed through an oxidation-reduction reaction, and charges (electrons and holes) may be produced. The charge generation unit CGL may provide the produced charges to adjacent light emitting units OL1 and OL2. The charge generation unit CGL may increase the efficiency of current generated at each of the adjacent light emitting units OL1 and OL2, and may play the role of controlling the balance of charges between the adjacent light emitting units OL1 and OL2.

The charge generation unit CGL may include a p-type charge generation layer p-CGL and an n-type charge generation layer n-CGL. The charge generation unit CGL may have a stacked structure in which the p-type charge generation layer p-CGL and the n-type charge generation layer n-CGL are joined together with each other. The charge generation unit CGL may have a stacked structure of the p-type charge generation layer p-CGL and the n-type charge generation layer n-CGL in order.

The n-type charge generation layer n-CGL may be a charge generation layer providing electrons to adjacent light emitting units OL1 and OL2. The n-type charge generation layer n-CGL may include an n-dopant. The n-type charge generation layer n-CGL may be a layer in which an n-dopant is doped in a base material. The p-type charge generation layer n-CGL may be a charge generation layer providing holes to adjacent light emitting units OL1 and OL2. The p-type charge generation layer p-CGL may include a p-dopant. The p-type charge generation layer p-CGL may be a layer in which a p-dopant is doped in a base material. The p-type charge generation layer p-CGL may include the first compound according to an embodiment of the present disclosure as a host, and may be a layer in which a p-dopant is doped in the host. In some embodiments, a buffer layer may be further between the n-type charge generation layer n-CGL and the p-type charge generation layer p-CGL.

The charge generation unit CGL may include an n-type arylamine-based material or a p-type metal oxide. For example, each of the charge generation layers CGL1, CGL2, CGL3 and CGL4 may include a charge generation compound composed of an arylamine-based organic compound, a metal, a metal oxide, a metal carbonate, a metal fluoride, or mixtures thereof.

For example, the arylamine-based compound may be a-NPD, 2-TNATA, TDATA, MTDATA, sprio-TAD, and/or sprio-NPB. For example, the metal may be cesium (Cs), molybdenum (Mo), vanadium (V), titanium (Ti), tungsten (W), barium (Ba), and/or lithium (Li). In some embodiments, the metal oxide, metal carbonate and metal fluoride may include Re207, MoO3, V205, WO3, TiO₂, Cs2CO3, BaF, LiF, and/or CsF.

The second electrode EL2 is provided on the electron transport region ETR. The second electrode EL2 may be a common electrode. The second electrode EL2 may be a cathode or an anode, but embodiments of the present disclosure are not limited thereto. For example, if the first electrode EL1 is an anode, the second cathode EL2 may be a cathode, and if the first electrode EL1 is a cathode, the second electrode EL2 may be an anode.

The second electrode EL2 may be a transmissive electrode, a transflective electrode or a reflective electrode. If the second electrode EL2 is the transmissive electrode, the second electrode EL2 may include a transparent metal oxide, for example, ITO, IZO, ZnO, ITZO, etc.

If the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/AI, Mo, Ti, Yb, W, compounds including thereof, or mixtures thereof (for example, AgMg, AgYb, and/or MgYb). In some embodiments, the second electrode EL2 may have a multilayered structure including a reflective layer or a transflective layer formed using the above-described materials and a transparent conductive layer formed using ITO, IZO, ZnO, ITZO, etc. For example, the second electrode EL2 may include the aforementioned metal materials, combinations of two or more metal materials selected from the aforementioned metal materials, and/or oxides of the aforementioned metal materials.

In some embodiments, the second electrode EL2 may be connected with an auxiliary electrode. If the second electrode EL2 is connected with the auxiliary electrode, the resistance (e.g., electrical resistance) of the second electrode EL2 may decrease.

On the second electrode EL2 of the light emitting element ED of an embodiment, a capping layer CPL may be provided. The capping layer CPL may include a multilayer or a single layer.

In an embodiment, the capping layer CPL may be an organic layer and/or an inorganic layer. For example, if the capping layer CPL includes an inorganic material, the inorganic material may include an alkali metal compound such as LiF, an alkaline earth metal compound such as MgF2, SiON, SiNx, SiOy, etc.

The capping layer CPL may include a third compound including a third moiety. For example, the third compound may be an arylamine compound in which a substituent including the third moiety is bonded to a triphenylamine group. However, the type of the third compound is not limited thereto, but may include diverse chemical structures without limitation, as long as the third compound includes the third moiety as a portion of the structure.

The third moiety includes one among benzothiophene, thienopyridine, thienopyrimidine, thienopyridazine, thienopyrazine, thienotriazine, thienotetrazine, benzothiazole, thiazolopyridine, thiazolopyrimidine, thiazolopyridazine, thiazolopyrazine, thiazolotriazine, thiazoloetetrazine, benzothiadiazole, thiadiazolepyridine, thiadiazolepyrimidine, thiadiazolepyridazine, thiadiazolepyrazine, thiadiazoletriazine, and thiadiazoletetrazine.

The capping layer CPL may include a first compound represented by Formula 1.

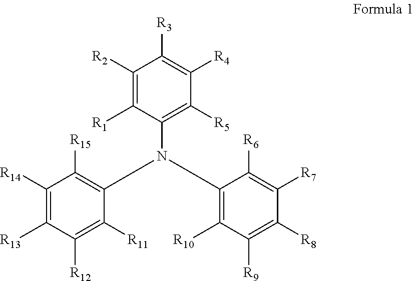

In Formula 1, R₁ to R₁₅ may be each independently a hydrogen atom, a deuterium atom, a halogen atom, a substituted or unsubstituted amine group, a substituted or unsubstituted aryl group of 6 to 30 ring-forming carbon atoms, or a substituted or unsubstituted heteroaryl group of 2 to 30 ring-forming carbon atoms. For example, R₁ to R₁₅ may be each independently a hydrogen atom, a deuterium atom, a substituted or unsubstituted phenyl group, a substituted or unsubstituted benzothiophene group, a substituted or unsubstituted dibenzothiophene group, a substituted or unsubstituted benzothiazole group, a substituted or unsubstituted benzofuran group, or a substituted or unsubstituted dibenzofuran group. In some embodiments, one among R₁ to R₁₅ may correspond to an amine group which is substituted with a substituent such as an aryl group, and the third compound represented by Formula 1 may be a diamine compound.

At least one among R₁ to R₁₅ may be a substituent represented by Formula 2.

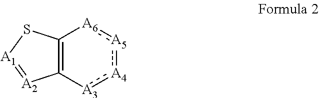

In Formula 2, A1 to A6 may be each independently N or CRᵢ, and Rᵢ may be a hydrogen atom, a deuterium atom, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms. In some embodiments, Rᵢ may be combined together with an adjacent group to form a ring. In some embodiments, Rᵢ may be a position connected with Formula 1.

The substituent represented by Formula 2 may be a substituent represented by Formula 2-1 or Formula 2-2.

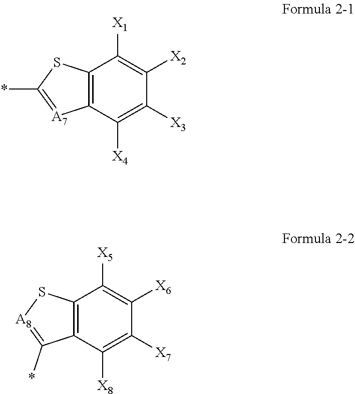

In Formula 2-1 and Formula 2-2, A7 and A₈ may be each independently N or CR₁₆.

In Formula 2-1 and Formula 2-2, if A₇ or A₈ is CR₁₆, R₁₆ may be a hydrogen atom, a deuterium atom, a halogen atom, a cyano group, or a substituted or unsubstituted alkyl group of 1 to 20 carbon atoms. For example, R₁₆ may be a hydrogen atom, a deuterium atom, or a substituted or unsubstituted methyl group.

In Formula 2-1 and Formula 2-2, X₁ to X₈ may be each independently a hydrogen atom, a deuterium atom, a halogen atom, a cyano group, or a substituted or unsubstituted alkyl group of 1 to 20 carbon atoms. For example, X₁ to X₈ may be each independently a hydrogen atom, a deuterium atom, or a substituted or unsubstituted methyl group.

In Formula 2-1 and Formula 2-2, “*----” may be a position connected with Formula 1.

In an embodiment, the capping layer CPL may include a third compound represented by one among Formula 1-1 to Formula 1-4.

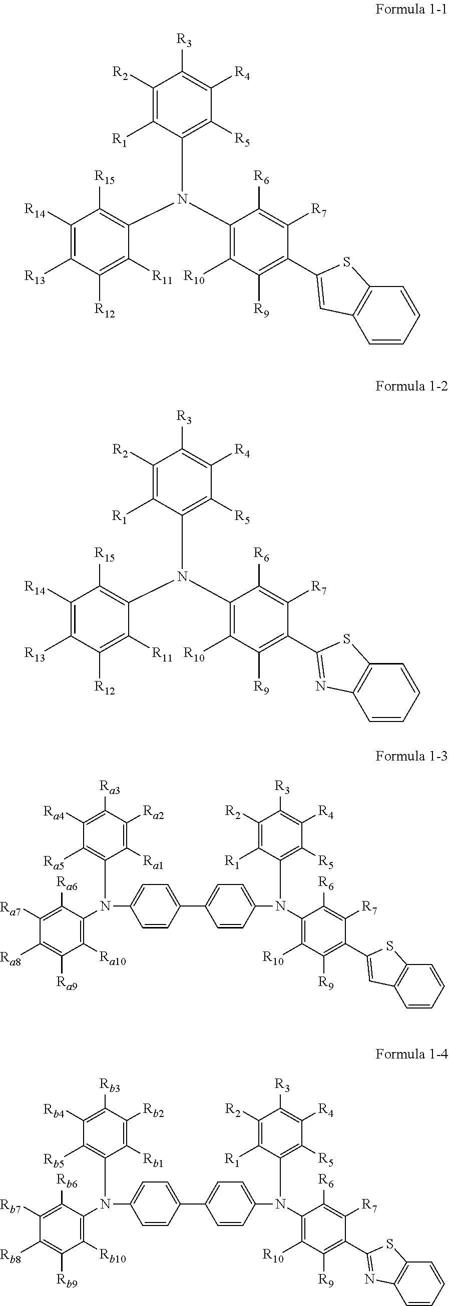

In Formula 1-1 to Formula 1-4, the same contents explained with respect to Formula 1 may be applied for R₁ to R₇, R₉ and R₁₀.

In Formula 1-3 and Formula 1-4, Rat to Rₐ10, and R_{b1} to R_{b10} may be each independently a hydrogen atom, a deuterium atom, a halogen atom, a substituted or unsubstituted amine group, a substituted or unsubstituted aryl group of 6 to 30 ring-forming carbon atoms, or a substituted or unsubstituted heteroaryl group of 2 to 30 ring-forming carbon atoms. For example, Rₐ₁ to Rₐ₁₀, and R_{b1} to R_{b10} may be each independently a hydrogen atom, a deuterium atom, a substituted or unsubstituted phenyl group, a substituted or unsubstituted benzothiophene group, a substituted or unsubstituted dibenzothiophene group, a substituted or unsubstituted benzothiazole group, a substituted or unsubstituted benzofuran group, or a substituted or unsubstituted dibenzofuran group.

The third compound of an embodiment may be one among the compounds represented in Compound Group C. The capping layer CPL of the light emitting element ED of an embodiment may include at least one among the third compounds shown in Compound Group C. For example, in the capping layer CPL of the light emitting element ED, at least one among the amine compounds shown in Compound Group C may be included.

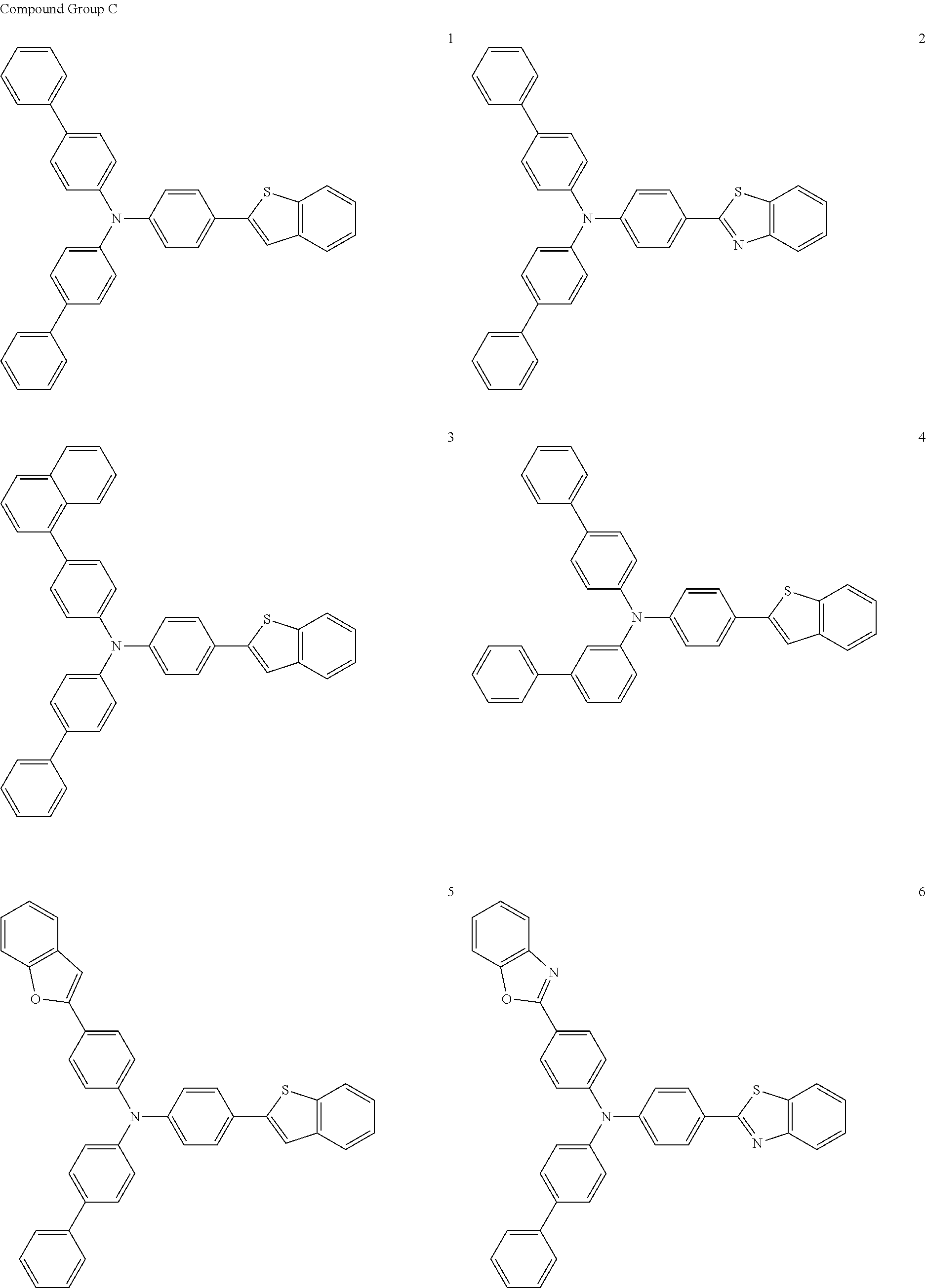 [SMILES: c1ccc(-c2ccc(N(c3ccc(-c4ccccc4)cc3)c3ccc(-c4cc5ccccc5s4)cc3)cc2)cc1 ; c1ccc(-c2ccc(N(c3ccc(-c4ccccc4)cc3)c3ccc(-c4nc5ccccc5s4)cc3)cc2)cc1 ; c1ccc(-c2ccc(N(c3ccc(-c4cc5ccccc5s4)cc3)c3ccc(-c4cccc5ccccc45)cc3)cc2)cc1 ; c1ccc(-c2ccc(N(c3ccc(-c4cc5ccccc5s4)cc3)c3cccc(-c4ccccc4)c3)cc2)cc1 ; c1ccc(-c2ccc(N(c3ccc(-c4cc5ccccc5o4)cc3)c3ccc(-c4cc5ccccc5s4)cc3)cc2)cc1 ; c1ccc(-c2ccc(N(c3ccc(-c4nc5ccccc5o4)cc3)c3ccc(-c4nc5ccccc5s4)cc3)cc2)cc1]

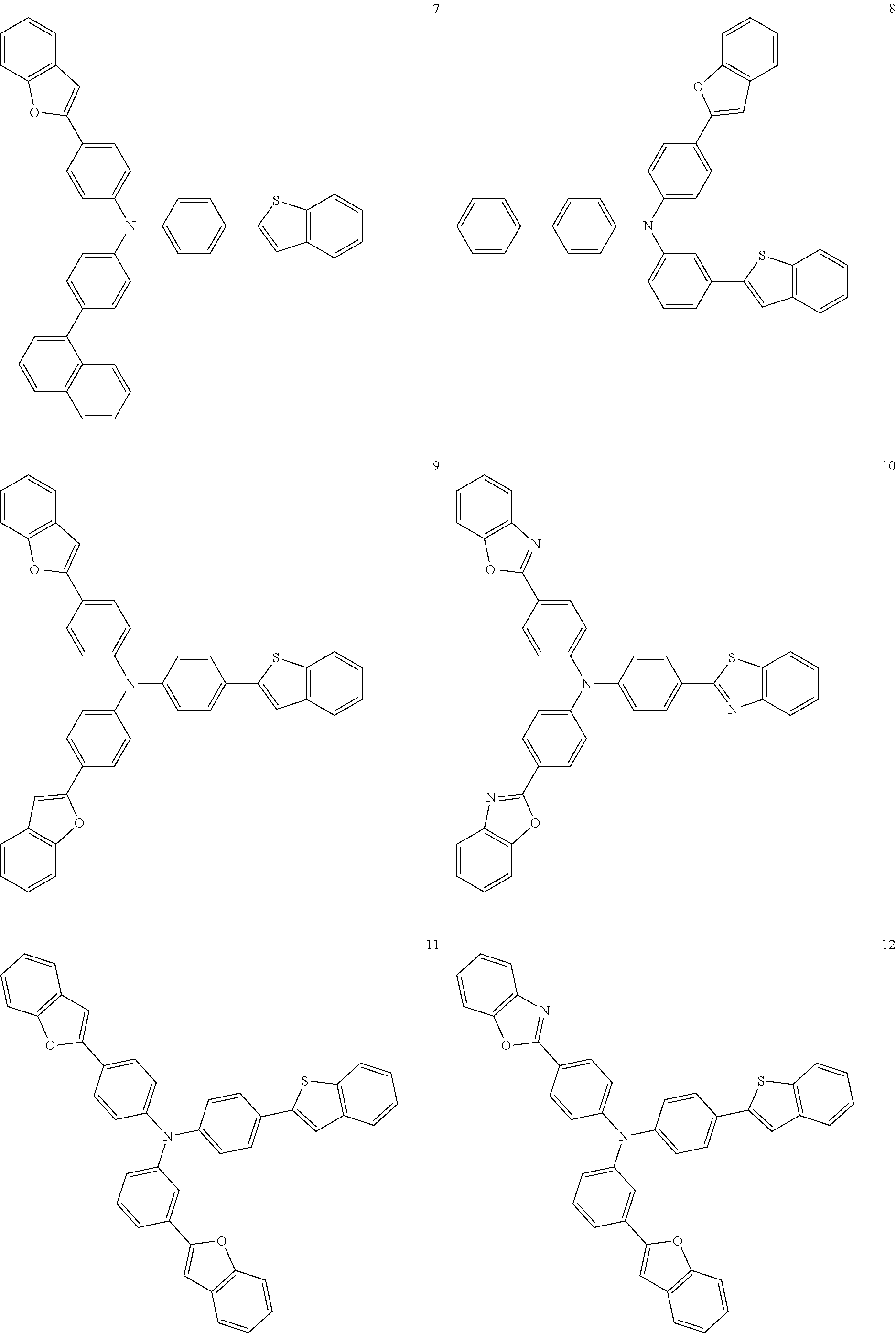 [SMILES: c1ccc2oc(-c3ccc(N(c4ccc(-c5cc6ccccc6s5)cc4)c4ccc(-c5cccc6ccccc56)cc4)cc3)cc2c1 ; c1ccc(-c2ccc(N(c3ccc(-c4cc5ccccc5o4)cc3)c3cccc(-c4cc5ccccc5s4)c3)cc2)cc1 ; c1ccc2oc(-c3ccc(N(c4ccc(-c5cc6ccccc6o5)cc4)c4ccc(-c5cc6ccccc6s5)cc4)cc3)cc2c1 ; c1ccc2oc(-c3ccc(N(c4ccc(-c5nc6ccccc6o5)cc4)c4ccc(-c5nc6ccccc6s5)cc4)cc3)nc2c1 ; c1cc(-c2cc3ccccc3o2)cc(N(c2ccc(-c3cc4ccccc4o3)cc2)c2ccc(-c3cc4ccccc4s3)cc2)c1 ; c1cc(-c2cc3ccccc3o2)cc(N(c2ccc(-c3nc4ccccc4o3)cc2)c2ccc(-c3cc4ccccc4s3)cc2)c1]

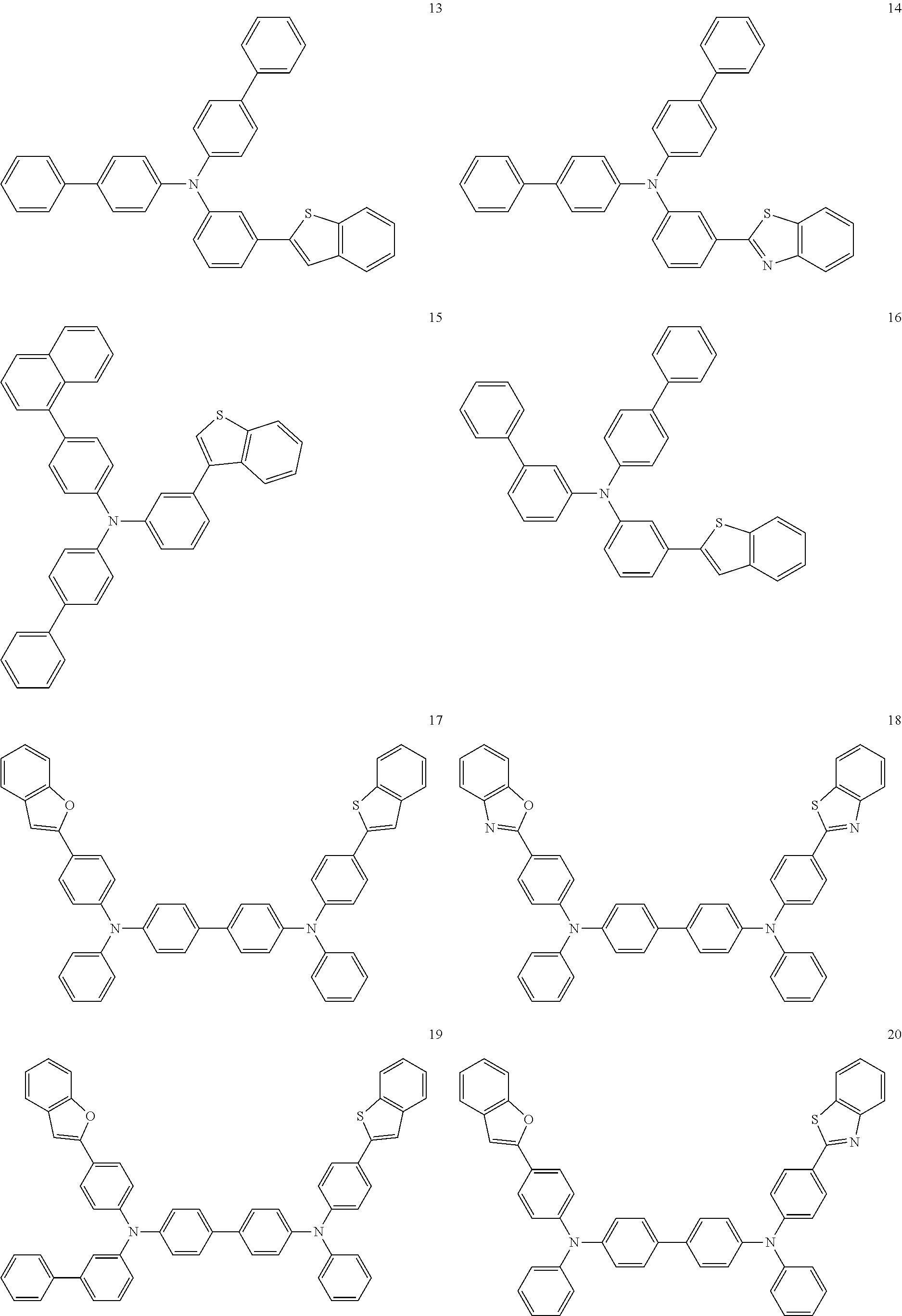

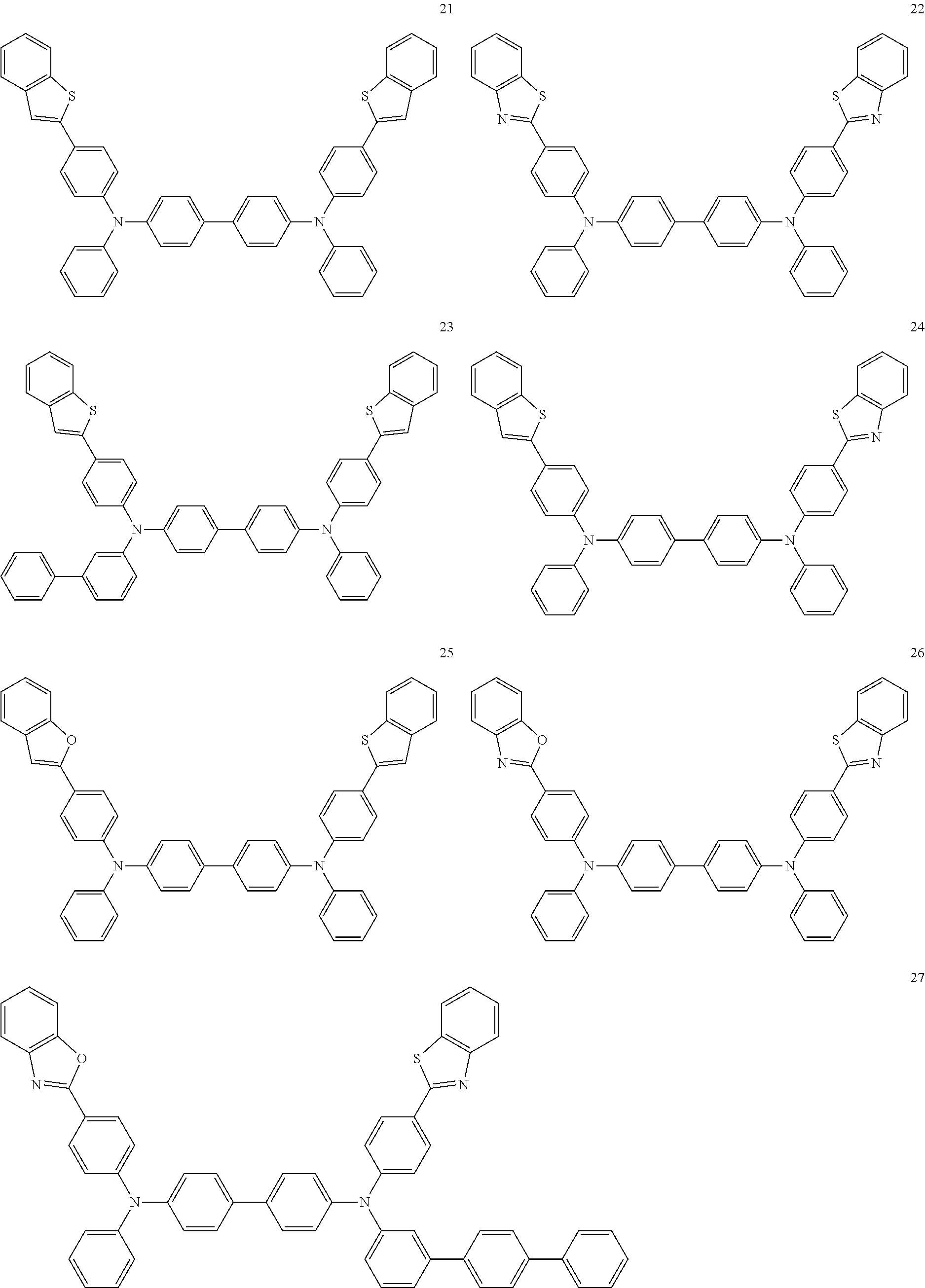

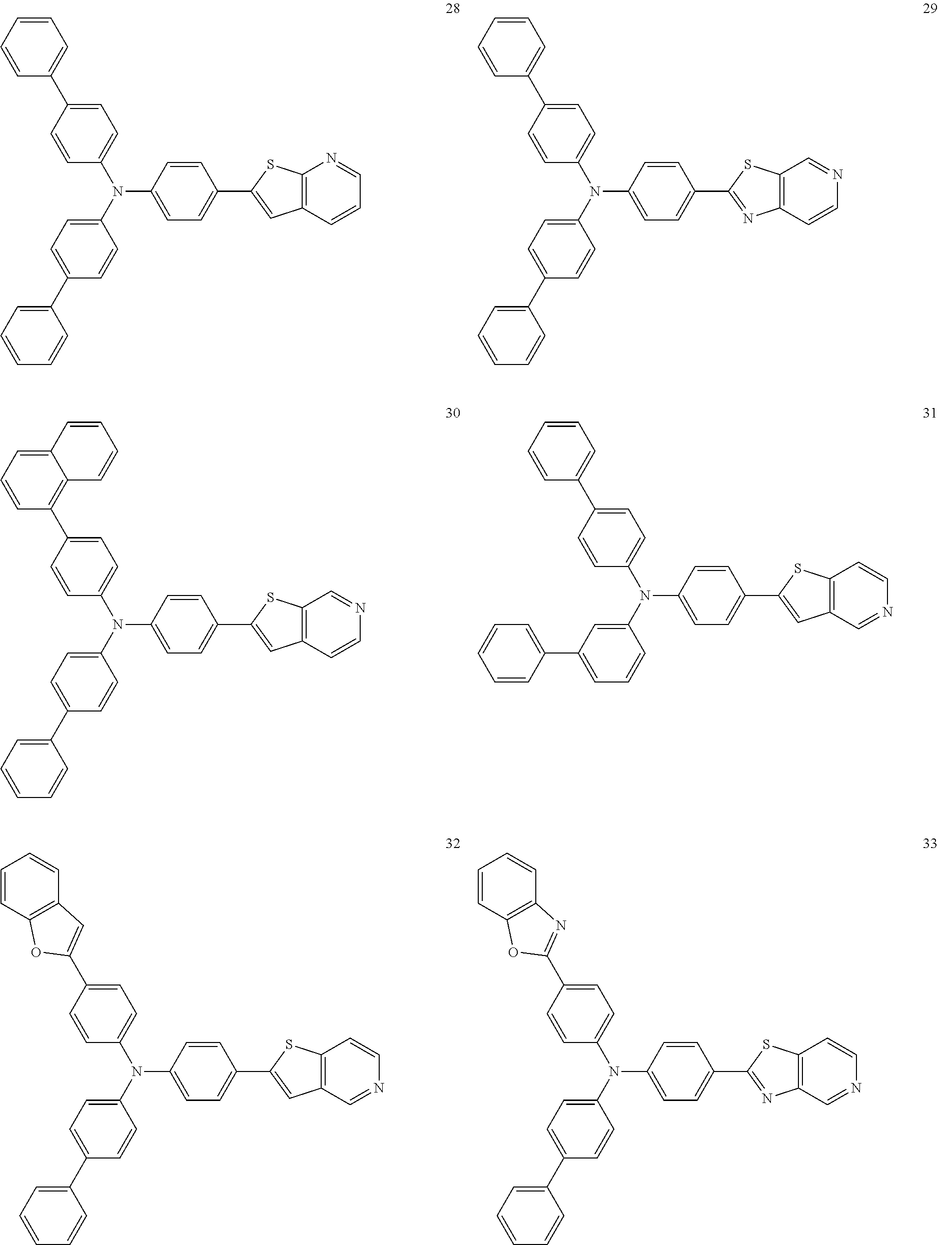 [SMILES: c1ccc(-c2ccc(N(c3ccc(-c4ccccc4)cc3)c3ccc(-c4cc5cccnc5s4)cc3)cc2)cc1 ; c1ccc(-c2ccc(N(c3ccc(-c4ccccc4)cc3)c3ccc(-c4nc5ccncc5s4)cc3)cc2)cc1 ; c1ccc(-c2ccc(N(c3ccc(-c4cc5ccncc5s4)cc3)c3ccc(-c4cccc5ccccc45)cc3)cc2)cc1 ; c1ccc(-c2ccc(N(c3ccc(-c4cc5cnccc5s4)cc3)c3cccc(-c4ccccc4)c3)cc2)cc1 ; c1ccc(-c2ccc(N(c3ccc(-c4cc5ccccc5o4)cc3)c3ccc(-c4cc5cnccc5s4)cc3)cc2)cc1 ; c1ccc(-c2ccc(N(c3ccc(-c4nc5ccccc5o4)cc3)c3ccc(-c4nc5cnccc5s4)cc3)cc2)cc1]

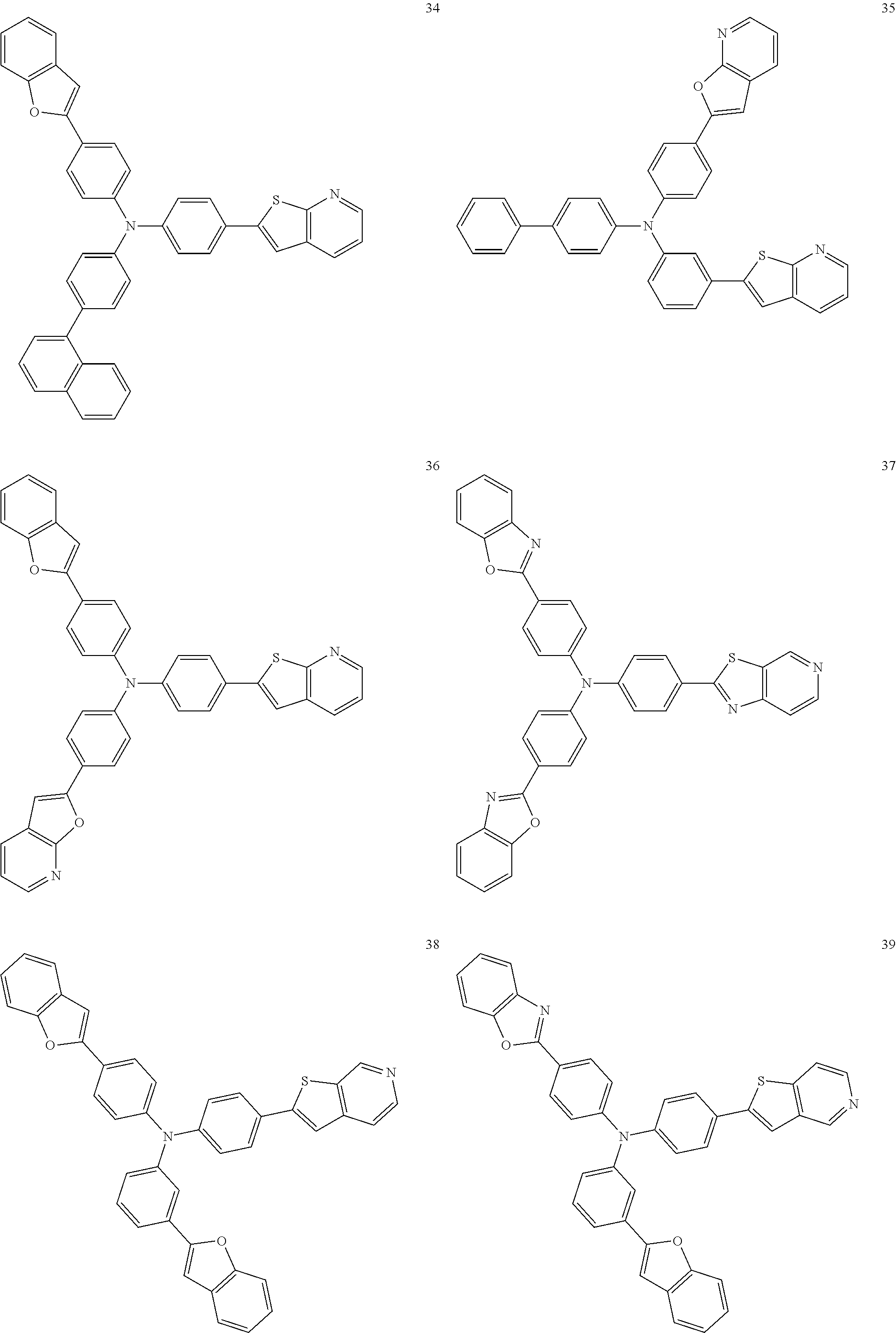 [SMILES: c1ccc2oc(-c3ccc(N(c4ccc(-c5cc6cccnc6s5)cc4)c4ccc(-c5cccc6ccccc56)cc4)cc3)cc2c1 ; c1ccc(-c2ccc(N(c3ccc(-c4cc5cccnc5o4)cc3)c3cccc(-c4cc5cccnc5s4)c3)cc2)cc1 ; c1ccc2oc(-c3ccc(N(c4ccc(-c5cc6cccnc6o5)cc4)c4ccc(-c5cc6cccnc6s5)cc4)cc3)cc2c1 ; c1ccc2oc(-c3ccc(N(c4ccc(-c5nc6ccccc6o5)cc4)c4ccc(-c5nc6ccncc6s5)cc4)cc3)nc2c1 ; c1cc(-c2cc3ccccc3o2)cc(N(c2ccc(-c3cc4ccccc4o3)cc2)c2ccc(-c3cc4ccncc4s3)cc2)c1 ; c1cc(-c2cc3ccccc3o2)cc(N(c2ccc(-c3nc4ccccc4o3)cc2)c2ccc(-c3cc4cnccc4s3)cc2)c1]

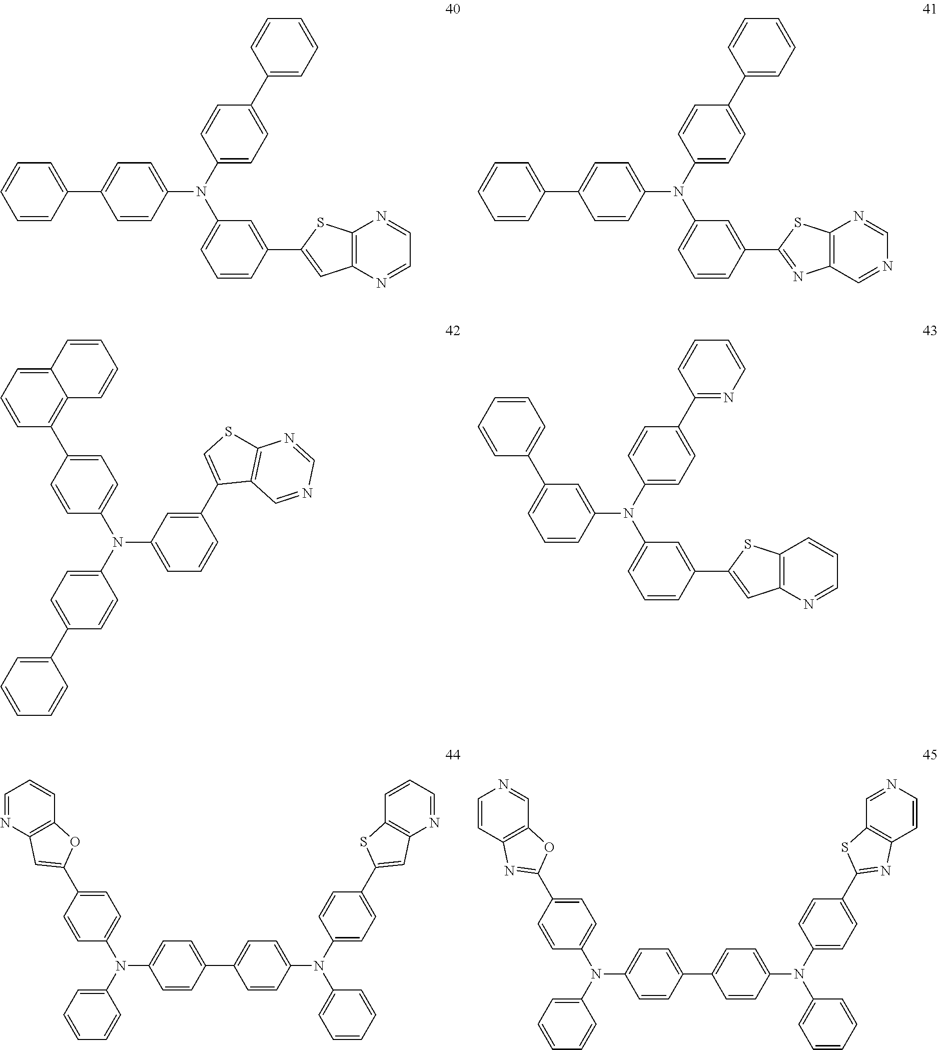

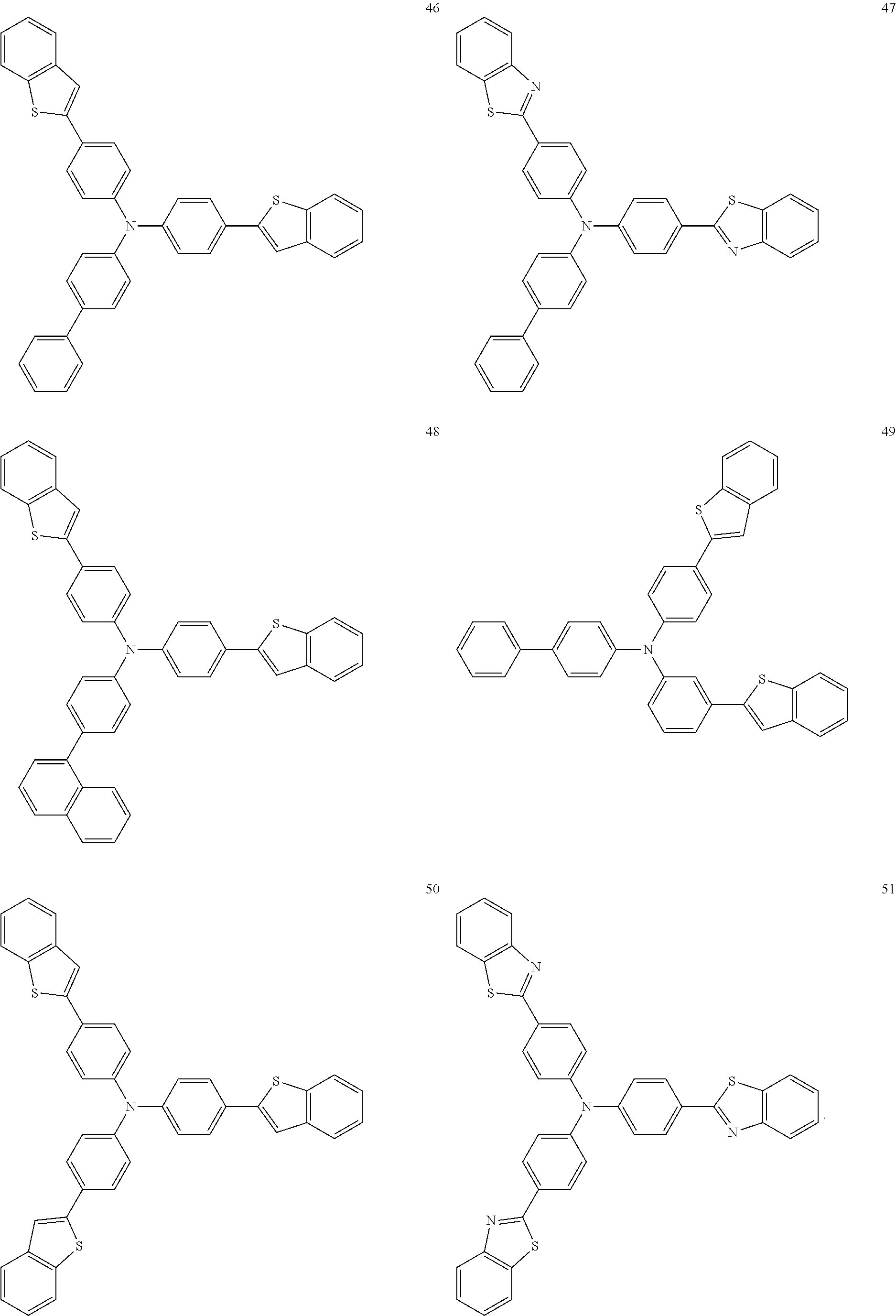 [SMILES: c1ccc(-c2ccc(N(c3ccc(-c4cc5ccccc5s4)cc3)c3ccc(-c4cc5ccccc5s4)cc3)cc2)cc1 ; c1ccc(-c2ccc(N(c3ccc(-c4nc5ccccc5s4)cc3)c3ccc(-c4nc5ccccc5s4)cc3)cc2)cc1 ; c1ccc2sc(-c3ccc(N(c4ccc(-c5cc6ccccc6s5)cc4)c4ccc(-c5cccc6ccccc56)cc4)cc3)cc2c1 ; c1ccc(-c2ccc(N(c3ccc(-c4cc5ccccc5s4)cc3)c3cccc(-c4cc5ccccc5s4)c3)cc2)cc1 ; c1ccc2sc(-c3ccc(N(c4ccc(-c5cc6ccccc6s5)cc4)c4ccc(-c5cc6ccccc6s5)cc4)cc3)cc2c1 ; c1ccc2sc(-c3ccc(N(c4ccc(-c5nc6ccccc6s5)cc4)c4ccc(-c5nc6ccccc6s5)cc4)cc3)nc2c1]

If the capping layer CPL further includes an organic material, the organic material may include a-NPD, NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol-9-yl)triphenylamine (TCTA), etc., and/or includes an epoxy resin, and/or acrylate such as methacrylate. In some embodiments, a capping layer CPL may include at least one among Compounds P1 to P5 below, but embodiments of the present disclosure are not limited thereto.

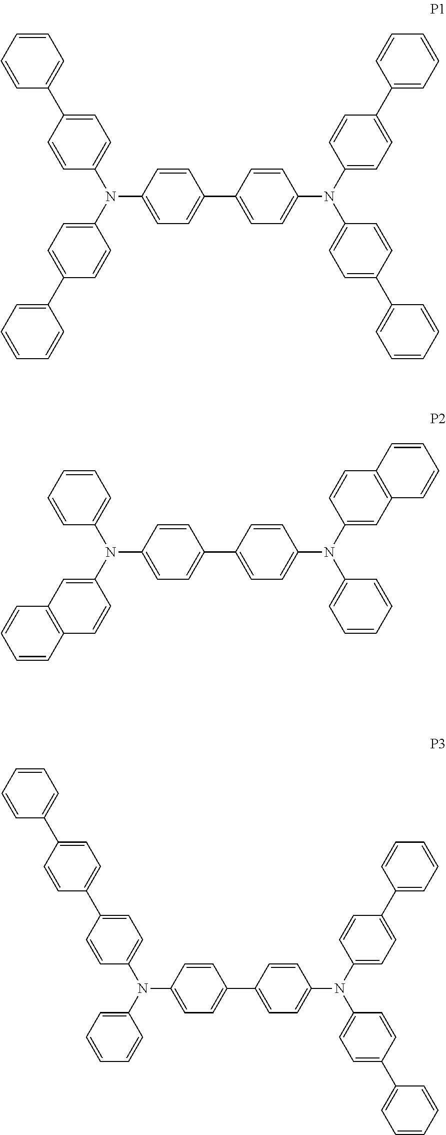 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

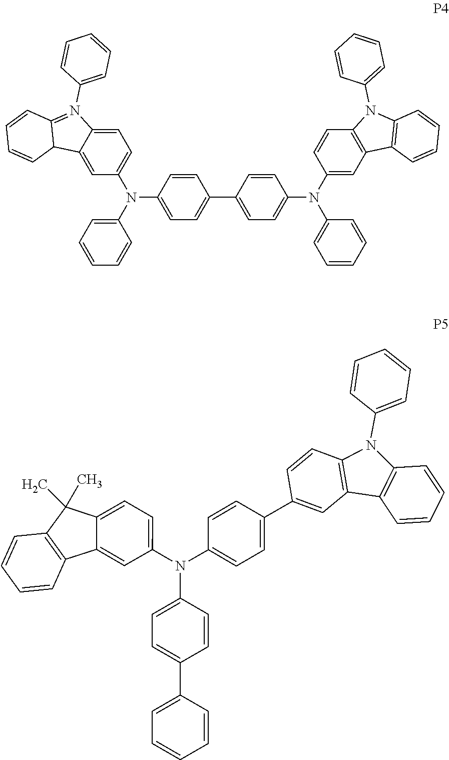

In some embodiments, the refractive index of the capping layer CPL may be about 1.6 or more. For example, the refractive index of the capping layer CPL with respect to light in a wavelength range of about 550 nm to about 660 nm may be about 1.6 or more.

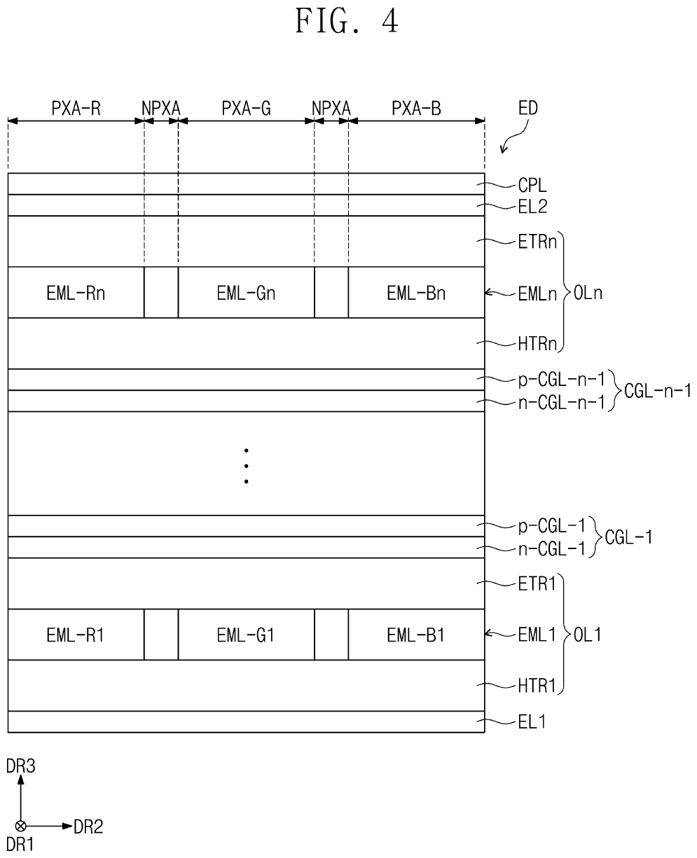

FIG. 4 is a cross-sectional view schematically showing a light emitting element according to another embodiment.

Different from FIG. 3A to FIG. 3D, the light emitting element ED of FIG. 4 is shown to include n light emitting units OL1-OLn. In some embodiments, n in FIG. 4 means an arbitrary integer of 3 or more.

Referring to FIG. 4, the light emitting element ED of an embodiment may include a first electrode EL1, a second electrode EL2, n light emitting units OL1-OLn stacked in order in the thickness direction between the first electrode EL1 and the second electrode EL2, and n-1 charge generation layers CGL-1-CGL-n-1 between neighboring light emitting units OL1-OLn. The first to n-th light emitting units OL1-OLn may include first to n-th hole transport regions HTR1-HTRn, first to n-th emission layers EML1-EMLn, and first to n-th electron transport regions ETR1-ETRn, stacked in order, respectively. The first to n-th emission layers EML1-EMLn may include first to n-th red emission layers EML-R1-EML-Rn, first to n-th green emission layers EML-G1-EML-Gn, and first to n-th blue emission layers EML-B1-EML-Bn, respectively. Charge generation layers CGL-1-CGL-n-1 between neighboring light emitting units OL1-OLn may include p-type charge generation layers p-CGL-1-p-CGL-n-1 and n-type charge generation layers n-CGL-1-n-CGL-n-1, respectively.

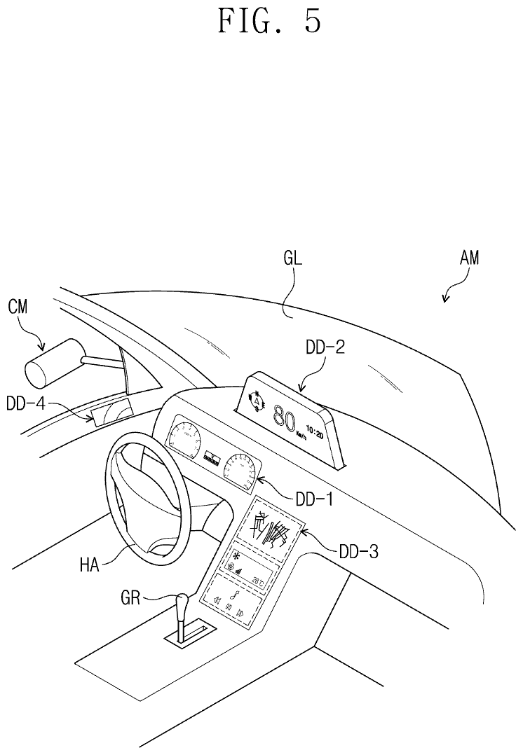

FIG. 5 is a diagram showing a vehicle in which a display device according to an embodiment is provided.

Referring to FIG. 5, an electronic device of an embodiment may include display devices DD-1, DD-2, DD-3 and DD-4 for a vehicle AM. At least one among the first to fourth display devices DD-1, DD-2, DD-3 and DD-4 may include the same configuration as the display device DD of an embodiment, explained referring to FIG. 1.

In FIG. 5, the first to fourth display devices DD-1, DD-2, DD-3 and DD-4 are shown as display devices for a vehicle AM in the vehicle AM. However, this is an example, and the first to fourth display devices DD-1, DD-2, DD-3 and DD-4 may be on other transport means such as bicycles, motorcycles, trains, ships and/or airplanes. In some embodiments, at least one among the first to fourth display devices DD-1, DD-2, DD-3 and DD-4 including the same configuration as the display device DD may be introduced in personal computers, laptop computers, personal digital terminals, game consoles, portable electronic devices, televisions, monitors, external billboards, and/or the like. In some embodiments, these are suggested as examples, and the display device may be introduced in other electronic devices as long as not deviated from the spirit and scope of the present disclosure.

At least one among the first to fourth display devices DD-1, DD-2, DD-3 and DD-4 may include the light emitting element ED of an embodiment, explained referring to FIG. 2, FIG. 3A to FIG. 3D and FIG. 4.

Referring to FIG. 5, a vehicle AM may include a steering wheel HA and a gear GR for the operation of the vehicle AM. In some embodiments, the vehicle AM may include a front window GL facing a driver.

A first display device DD-1 may be in a first region overlapping with the steering wheel HA. For example, the first display device DD-1 may be a digital cluster displaying the first information of the vehicle AM. The first information may include a first graduation showing the running speed of the vehicle AM, a second graduation showing the number of revolution of an engine (e.g., revolutions per minute (RPM)), and/or images showing a fuel state. The first graduation and the second graduation may be represented by digital images.

A second display device DD-2 may be in a second region facing a driver's seat and overlapping with the front window GL. The driver's seat may be a seat where the steering wheel HA is provided. For example, the second display device DD-2 may be a head up display (HUD) showing the second information of the vehicle AM. The second display device DD-2 may be optically clear. The second information may include digital numbers showing the running speed of the vehicle AM and may further include information including the current time. In some embodiments, the second information of the second display device DD-2 may be projected and displayed on the front window GL.

A third display device DD-3 may be in a third region adjacent to the gear GR. For example, the third display device DD-3 may be a center information display (CID) for a vehicle, between a driver's seat and a passenger seat and showing third information. The passenger seat may be a seat separated from the driver's seat with the gear GR therebetween. The third information may include information on road conditions (for example, navigation information), on playing music and/or radio, on playing a dynamic image (and/or image), on the temperature in the vehicle AM, and/or the like.

A fourth display device DD-4 may be in a fourth region separated from the steering wheel HA and the gear GR and adjacent to the side of the vehicle AM. For example, the fourth display device DD-4 may be a digital wing mirror displaying fourth information. The fourth display device DD-4 may display the external image of the vehicle AM, taken by a camera module CM at the outside of the vehicle AM. The fourth information may include the external image of the vehicle AM.

The above-described first to fourth information is an example, and the first to fourth display devices DD-1, DD-2, DD-3 and DD-4 may further display information on the inside and/or outside of the vehicle. The first to fourth information may include different information from each other. However, embodiments of the present disclosure are not limited thereto, and a portion of the first to fourth information may include the same information.

Hereinafter, referring to the Examples and Comparative Examples together with FIG. 3A to FIG. 3D, the light emitting element according to an embodiment of the present disclosure will be explained in more detail. The Examples below are illustrations to assist the understanding of the subject matter of the present disclosure, but the scope of the present disclosure is not limited thereto.

### 1. Manufacture of Light Emitting Elements

The light emitting elements of the Examples and the light emitting elements of the Comparative Examples were manufactured by a method described below. In Table 1, the inclusion or not of the first, second or third moiety in the compound used for each layer is shown when manufacturing the light emitting elements of the Examples and Comparative Examples. In Table 1, a part designated by “O” represents the inclusion of the first, second or third moiety in the compound used for each layer, and a part not designated by anyone represents the exclusion of the first, second or third moiety in the compound used for each layer.

### Manufacture of Light Emitting Element of Example 1

In order to manufacture a light emitting element of Example 1, an ITO/Ag/ITO (120 Å/500 Å/120 Å) glass substrate of about 15 Ω/cm², was cut into a size of 50 mm×50 mm×0.7 mm, cleansed using ultrasonic waves using isopropyl alcohol and ultrapure water for about 5 minutes each, exposed to UV for about 30 minutes and cleansed by exposing to ozone, and then, the glass substrate was installed in a vacuum deposition apparatus.

On the first electrode, a first light emitting unit was formed. Particularly, on the first electrode, Compound H-1-1 in Compound Group H, doped with F4-TCNQ (2%) was deposited to about 30 nm to form a first hole transport layer as a common layer. Then, on the first hole transport layer, a host mixture of Compound E-2-25 and Compound E-2-26 in Compound Group E-2 in a weight ratio of about 1:1, doped with a dopant of Compound R1 in Compound Group R (2%, R region) was deposited to about 40 nm to form a first red emission layer so as to be overlapped with a first light emitting region, a host mixture of Compound E-2-25 and Compound E-2-26 in Compound Group E-2 in a weight ratio of about 1:1, doped with a dopant of Compound G1 in Compound Group G (8%, G region) was deposited to about 30 nm to form a first green emission layer so as to be overlapped with a second light emitting region, and a host of Compound E20 doped with a dopant of Compound B1 in Compound Group B (2%, B region) was deposited to about 30 nm to form a first blue emission layer so as to be overlapped with a third light emitting region, thereby forming a first emission layer as a pattern layer. Then, Compound ET37 was deposited to about 10 nm to form a first electron transport layer as a common layer.

After that, on the first electron transport region, a charge generation unit was formed. Particularly, bathophenanthroline (Bphen) doped with Li (1%) was formed into about 10 nm, and Compound H-1-1 in Compound Group H, doped with F4-TCNQ (5%) was deposited to about 10 nm to form a charge generation layer as a common layer.

After that, on the charge generation layer, a second light emitting unit was formed. Particularly, on the charge generation layer, Compound H-1-1 in Compound Group H was deposited to about 30 nm to form a second hole transport layer as a common layer. Then, on the second hole transport layer, Compound H-1-2 in Compound Group H was deposited to about 10 nm to form a second red emission auxiliary layer so as to be overlapped with the first light emitting region, on the second hole transport layer, Compound H-1-2 in Compound Group H was deposited to about 10 nm to form a second green emission auxiliary layer so as to be overlapped with the second light emitting region, and on the second hole transport layer, Compound H-1-2 in Compound Group H was deposited to about 10 nm to form a second blue emission auxiliary layer so as to be overlapped with the third light emitting region, thereby forming a second emission auxiliary layer as a pattern layer. After that, on the second emission auxiliary layer, a host mixture of Compound E-2-25 and Compound E-2-26 in Compound Group E-2 in a weight ratio of about 1:1, doped with a dopant of Compound R1 in Compound Group R (2%, R region) was deposited to about 40 nm to form a second red emission layer so as to be overlapped with the first light emitting region, on the charge generation layer, a host mixture of Compound E-2-25 and Compound E-2-26 in Compound Group E-2 in a weight ratio of about 1:1, doped with a dopant of Compound G1 in Compound Group G (8%, G region) was deposited to about 30 nm to form a second green emission layer so as to be overlapped with the second light emitting region, and on the charge generation layer, a host of Compound E20 doped with a dopant of Compound B1 in Compound Group B (2%, B region) was deposited to about 30 nm to form a second blue emission layer so as to be overlapped with the third light emitting region, thereby forming a second emission layer as a pattern layer. Then, Compound ET37 was deposited to about 10 nm to form a second electron transport layer as a common layer.

Then, Mg: Ag (10%) was deposited on the second light emitting unit to form a second electrode having a thickness of about 120 Å. After that, on the second electrode, Compound 1 in Compound Group C was deposited to about 60 nm to form a capping layer as a common layer to manufacture a light emitting element. All layers were formed by a vacuum deposition method.

### Manufacture of Light Emitting Element of Example 2

A light emitting element of Example 2 was manufactured to have the same stacked structure as the light emitting element of Example 1. Compared to the light emitting element of Example 1, the light emitting element of Example 2 was manufactured by the same method except for using a different compound for forming the second emission auxiliary layer.

In the light emitting element of Example 2, a second red emission auxiliary layer was formed by depositing Compound HT1 in Compound Group HT to about 5 nm so as to be overlapped with the first light emitting region, a second green emission auxiliary layer was formed by depositing Compound HT1 in Compound Group HT to about 5 nm so as to be overlapped with the second light emitting region, and a second blue emission auxiliary layer was formed by depositing Compound HT9 in Compound Group HT to about 5 nm so as to be overlapped with the third light emitting region.

### Manufacture of Light Emitting Element of Example 3

A light emitting element of Example 3 was manufactured to have the same stacked structure as the light emitting element of Example 1. Compared to the light emitting element of Example 1, the light emitting element of Example 3 was manufactured by the same method except for using different compounds for forming the first emission layer, the first electron transport layer, the second emission layer and the second electron transport layer.

A first red emission layer and a second red emission layer of the light emitting element of Example 3 were formed by depositing a host mixture of Compound E-2-25 and Compound E-2-26 in Compound Group E-2 in a weight ratio of about 1;1, doped with a dopant of Compound M-a-9 (2%, R region) to about 40 nm. A first green emission layer and a second green emission layer of the light emitting element of Example 3 were formed by depositing a host mixture of Compound E-2-25 and Compound E-2-26 in Compound Group E-2 in a weight ratio of about 1;1, doped with a dopant of Compound M-a-13 (8%, G region) to about 30 nm. A first blue emission layer and a second blue emission layer of the light emitting element of Example 3 were formed by depositing a host of Compound E20 doped with a dopant of Compound BD (2%, B region) to about 30 nm. The first electron transport layer and the second electron transport layer of the light emitting element of Example 3 were formed by depositing Compound E1 in Compound Group E to about 10 nm.

### Manufacture of Light Emitting Element of Example 4

A light emitting element of Example 4 was manufactured to have the same stacked structure as the light emitting element of Example 1. Compared to the light emitting element of Example 1, the light emitting element of Example 4 was manufactured by the same method except for using a different compound for forming the first electron transport layer.

The first electron transport layer of the light emitting element of Example 4 was formed by depositing Compound E1 in Compound Group E to about 10 nm.

### Manufacture of Light Emitting Element of Example 5

Compared to the stacked structure of the light emitting element of Example 1, a light emitting element of Example 5 was manufactured to have the same structure as the light emitting element of Example 1 except that the first light emitting unit includes a first emission auxiliary layer. Compared to the light emitting element of Example 1, the light emitting element of Example 5 was manufactured by the same method except for using different compounds for forming the first emission layer, the second emission layer, the second electron transport layer and the capping layer.

A first emission auxiliary layer included in the light emitting element of Example 5 was formed on the first hole transport layer by forming a first red emission auxiliary layer by depositing Compound HT1 in Compound Group HT to about 5 nm so as to be overlapped with the first light emitting region, forming a first green emission auxiliary layer by depositing Compound HT1 in Compound Group HT to about 5 nm so as to be overlapped with the second light emitting region, and forming a first blue emission auxiliary layer by depositing Compound HT9 in Compound Group HT to about 5 nm so as to be overlapped with the third light emitting region.

A first red emission layer and a second red emission layer of the light emitting element of Example 5 were formed by depositing a host mixture of Compound E-2-25 and Compound E-2-26 in Compound Group E-2 in a weight ratio of about 1;1, doped with a dopant of Compound M-a-9 (2%, R region) to about 40 nm. A first green emission layer and a second green emission layer of the light emitting element of Example 5 were formed by depositing a host mixture of Compound E-2-25 and Compound E-2-26 in Compound Group E-2 in a weight ratio of about 1;1, doped with a dopant of Compound M-a-13 (8%, G region) to about 30 nm. A first blue emission layer and a second blue emission layer of the light emitting element of Example 5 were formed by depositing a host of Compound E20 doped with a dopant of Compound BD (2%, B region) to about 30 nm. The second electron transport of the light emitting element of Example 5 was formed by depositing Compound E1 in Compound Group E to about 10 nm. The capping layer of the light emitting element of Example 5 was formed by depositing Compound 46 in Compound Group C to about 60 nm.

### Manufacture of Light Emitting Element of Example 6

A light emitting element of Example 6 was manufactured to have the same stacked structure as the light emitting element of Example 1. Compared to the light emitting element of Example 1, the light emitting element of Example 6 was manufactured by the same method except for using different compounds used for forming the first emission layer, the second emission layer and the capping layer.

A first red emission layer and a second red emission layer of the light emitting element of Example 6 were formed by depositing a host mixture of Compound E-2-25 and Compound E-2-26 in Compound Group E-2 in a weight ratio of about 1;1, doped with a dopant of Compound R₁₈ in Compound Group R (2%, R region) to about 40 nm. A first green emission layer and a second green emission layer of the light emitting element of Example 6 were formed by depositing a host mixture of Compound E-2-25 and Compound E-2-26 in Compound Group E-2 in a weight ratio of about 1;1, doped with a dopant of Compound G9 in Compound Group G (8%, G region) to about 30 nm. A first blue emission layer and a second blue emission layer of the light emitting element of Example 6 were formed by depositing a host of Compound E20 doped with Compound B46 in Compound Group B (2%, B region) to about 30 nm. The capping layer of the light emitting element of Example 6 was formed by depositing Compound 46 in Compound Group C to about 60 nm.

### Manufacture of Light Emitting Element of Example 7

A light emitting element of Example 7 was manufactured to have the same stacked structure as the light emitting element of Example 1. Compared to the light emitting element of Example 1, the light emitting element of Example 7 was manufactured by the same method except for using different compounds used for forming the second emission layer and the capping layer.

A second red emission layer of the light emitting element of Example 7 was formed by depositing a host mixture of Compound E-2-25 and Compound E-2-26 in Compound Group E-2 in a weight ratio of about 1;1, doped with a dopant of Compound R18 in Compound Group R (2%, R region) to about 40 nm. A second green emission layer of the light emitting element of Example 7 was formed by depositing a host mixture of Compound E-2-25 and Compound E-2-26 in Compound Group E-2 in a weight ratio of about 1;1, doped with a dopant of Compound G9 in Compound Group G (8%, G region) to about 30 nm. A second blue emission layer of the light emitting element of Example 7 was formed by depositing a host of Compound E20 doped with Compound B46 in Compound Group B (2%, B region) to about 30 nm. The capping layer of the light emitting element of Example 7 was formed by depositing Compound 46 in Compound Group C to about 60 nm.

### Manufacture of Light Emitting Element of Example 8

Compared to the stacked structure of the light emitting element of Example 1, a light emitting element of Example 8 was manufactured to have the same structure except that the first light emitting unit includes a first emission auxiliary layer. Compared to the light emitting element of Example 1, the light emitting element of Example 8 was manufactured by the same method except for using a different compound used for forming the second emission auxiliary layer and the second emission layer.

The first emission auxiliary layer included in the light emitting element of Example 8 was obtained by forming on the first hole transport layer, a first red emission auxiliary layer by depositing Compound HT1 in Compound Group HT to about 5 nm so as to be overlapped with the first light emitting region, a first green emission auxiliary layer by depositing Compound HT1 in Compound Group HT to about 5 nm so as to be overlapped with the second light emitting region, and a first blue emission auxiliary layer by depositing Compound HT9 in Compound Group HT to about 5 nm so as to be overlapped with the third light emitting region.

A second red emission layer of the light emitting element of Example 8 was formed by depositing a host mixture of Compound E-2-25 and Compound E-2-26 in Compound Group E-2 in a weight ratio of about 1;1, doped with a dopant of Compound R18 in Compound Group R (2%, R region) to about 40 nm. A second green emission layer of the light emitting element of Example 8 was formed by depositing a host mixture of Compound E-2-25 and Compound E-2-26 in Compound Group E-2 in a weight ratio of about 1;1, doped with a dopant of Compound G9 in Compound Group G (8%, G region) to about 30 nm. A second blue emission layer of the light emitting element of Example 8 was formed by depositing a host of Compound E20 doped with a dopant of Compound B46 in Compound Group B (2%, B region) to about 30 nm.

In the light emitting element of Example 8, a second red emission auxiliary layer was formed by depositing Compound HT18 in Compound Group HT to about 5 nm so as to be overlapped with the first light emitting region, a second green emission auxiliary layer was formed by depositing Compound HT18 in Compound Group HT to about 5 nm so as to be overlapped with the second light emitting region, and a second blue emission auxiliary layer was formed by depositing Compound HT9 in Compound Group HT to about 5 nm so as to be overlapped with the third light emitting region.

### Manufacture of Light Emitting Element of Comparative Example 1

A light emitting element of Comparative Example 1 was manufactured to have the same stacked structure as the light emitting element of Example 1. Compared to the light emitting element of Example 1, the light emitting element of Comparative Example 1 was manufactured by the same method except for using different compounds for forming the first emission layer, the second emission layer and the capping layer.

A first red emission layer and a second red emission layer of the light emitting element of Comparative Example 1 were formed by depositing a host mixture of Compound E-2-25 and Compound E-2-26 in Compound Group E-2 in a weight ratio of about 1;1, doped with a dopant of Compound M-a-9 (2%, R region) to about 40 nm. A first green emission layer and a second green emission layer of the light emitting element of Comparative Example 1 were formed by depositing a host mixture of Compound E-2-25 and Compound E-2-26 in Compound Group E-2 in a weight ratio of about 1;1, doped with a dopant of Compound M-a-13 (8%, G region) to about 30 nm. A first blue emission layer and a second blue emission layer of the light emitting element of Comparative Example 1 were formed by depositing a host of Compound E20 doped with a dopant of Compound BD (2%, B region) to about 30 nm. The capping layer of the light emitting element of Comparative Example 1 was formed by depositing Compound P4 to about 60 nm.

### Manufacture of Light Emitting Element of Comparative Example 2

A light emitting element of Comparative Example 2 was manufactured to have the same stacked structure as the light emitting element of Example 1. Compared to the light emitting element of Example 1, the light emitting element of Comparative Example 2 was manufactured by the same method except for using different compounds for forming the first emission layer and the second emission layer.

A first red emission layer and a second red emission layer of the light emitting element of Comparative Example 2 were formed by depositing a host mixture of Compound E-2-25 and Compound E-2-26 in Compound Group E-2 in a weight ratio of about 1;1, doped with a dopant of Compound M-a-9 (2%, R region) to about 40 nm. A first green emission layer and a second green emission layer of the light emitting element of Comparative Example 2 were formed by depositing a host mixture of Compound E-2-25 and Compound E-2-26 in Compound Group E-2 in a weight ratio of about 1:1, doped with a dopant of Compound M-a-13 (8%, G region) to about 30 nm. A first blue emission layer and a second blue emission layer of the light emitting element of Comparative Example 2 were formed by depositing a host of Compound E20 doped with a dopant of Compound BD (2%, B region) to about 30 nm.

### Manufacture of Light Emitting Element of Comparative Example 3

A light emitting element of Comparative Example 3 was manufactured to have the same stacked structure as the light emitting element of Example 1. Compared to the light emitting element of Example 1, the light emitting element of Comparative Example 3 was manufactured by the same method except for using a different compound for forming the capping layer.

The capping layer of the light emitting element of Comparative Example 3 was formed by depositing Compound P4 to about 60 nm.

The compounds used for the manufacture of the light emitting elements of the Examples and the Comparative Examples are shown below. The materials used for the manufacture of an element include the above-described compounds, or include commercial products purified and sublimated in advance.

### Compounds Used in Examples and Comparative Examples

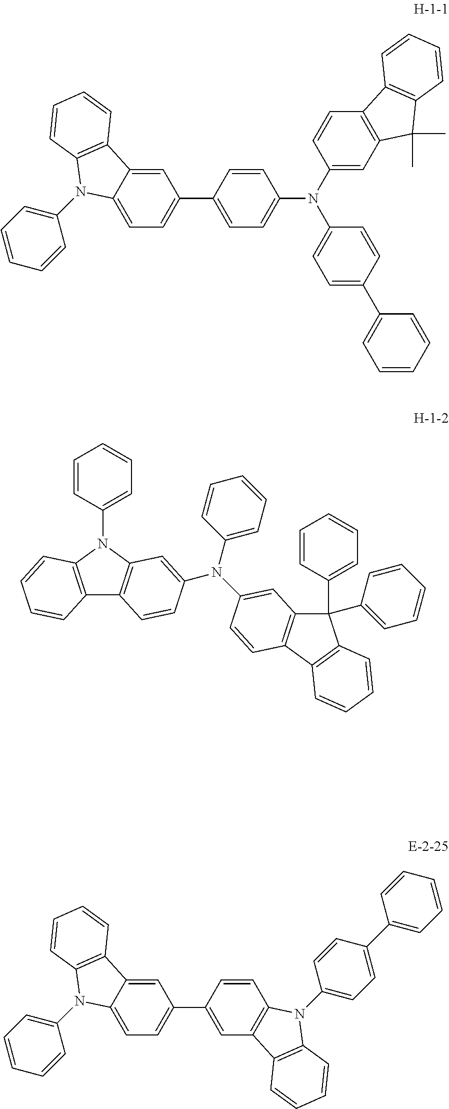 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; c1ccc(-c2ccc(-n3c4ccccc4c4cc(-c5ccc6c(c5)c5ccccc5n6-c5ccccc5)ccc43)cc2)cc1]

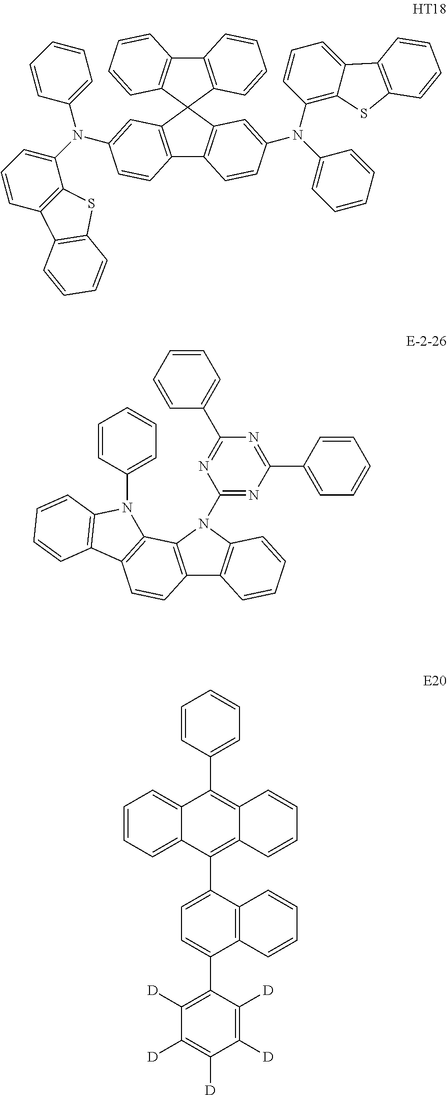 [SMILES: c1ccc(N(c2ccc3c(c2)C2(c4ccccc4-c4ccccc42)c2cc(N(c4ccccc4)c4cccc5c4sc4ccccc45)ccc2-3)c2cccc3c2sc2ccccc23)cc1 ; c1ccc(-c2nc(-c3ccccc3)nc(-n3c4ccccc4c4ccc5c6ccccc6n(-c6ccccc6)c5c43)n2)cc1 ; [2H]c1c([2H])c([2H])c(-c2ccc(-c3c4ccccc4c(-c4ccccc4)c4ccccc34)c3ccccc23)c([2H])c1[2H]]

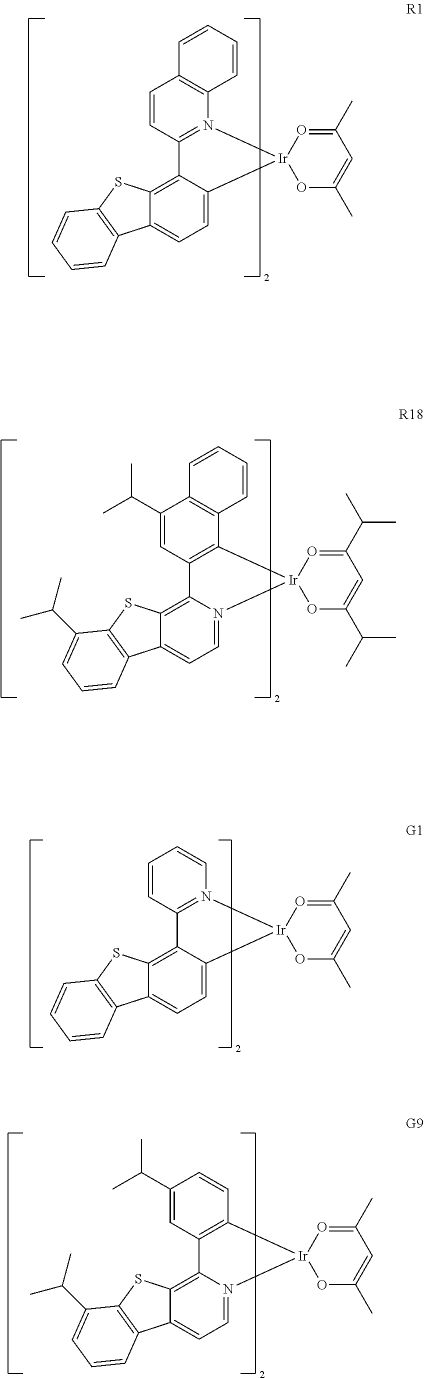

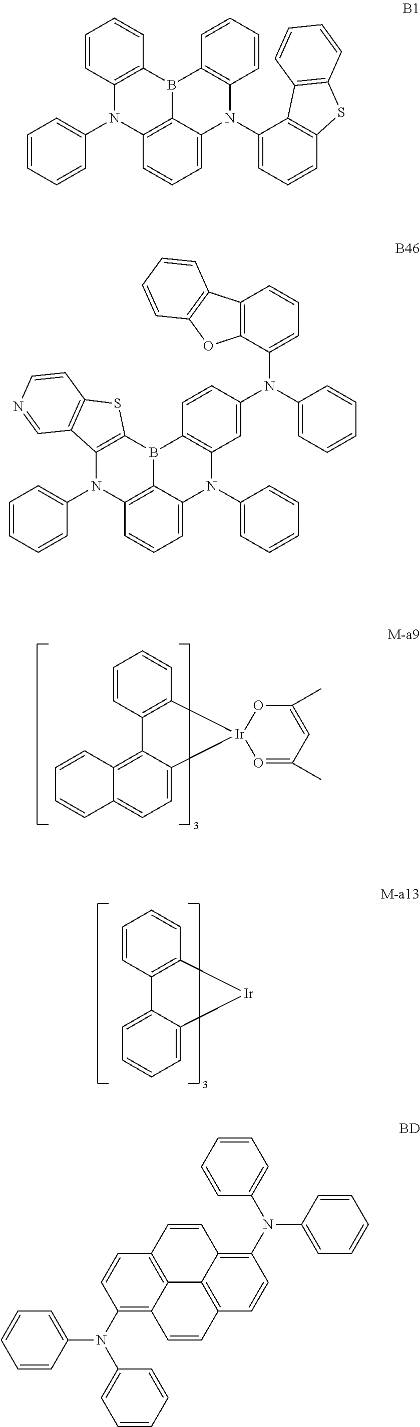

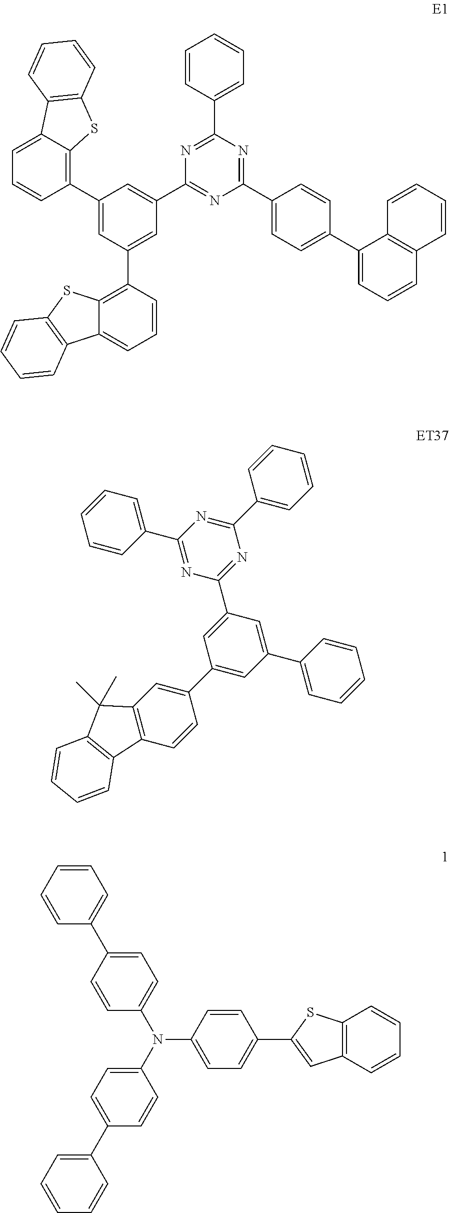 [SMILES: c1ccc(-c2nc(-c3ccc(-c4cccc5ccccc45)cc3)nc(-c3cc(-c4cccc5c4sc4ccccc45)cc(-c4cccc5c4sc4ccccc45)c3)n2)cc1 ; CC1(C)c2ccccc2-c2ccc(-c3cc(-c4ccccc4)cc(-c4nc(-c5ccccc5)nc(-c5ccccc5)n4)c3)cc21 ; c1ccc(-c2ccc(N(c3ccc(-c4ccccc4)cc3)c3ccc(-c4cc5ccccc5s4)cc3)cc2)cc1]

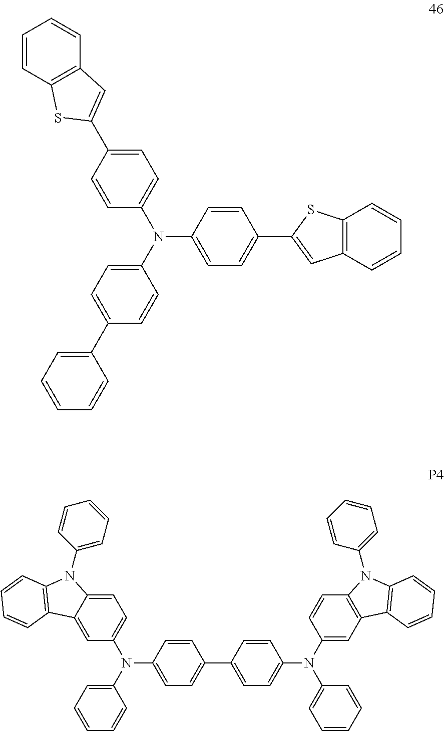 [SMILES: c1ccc(-c2ccc(N(c3ccc(-c4cc5ccccc5s4)cc3)c3ccc(-c4cc5ccccc5s4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

TABLE 1

| | | | | | | | | | | Comp- | Comp- | Comp- |
|---|---|---|---|---|---|---|---|---|---|---|---|---|
| | | Exam- | Exam- | Exam- | Exam- | Exam- | Exam- | Exam- | Exam- | arative | arative | arative |
| | | ple | ple | ple | ple | ple | ple | ple | ple | Exam- | Exam- | Exam- |
| | | 1 | 2 | 3 | 4 | 5 | 6 | 7 | 8 | ple 1 | ple 2 | ple 3 |
| Capping layer | | O | O | O | O | O | O | O | O | | O | |
| (CPL) | | | | | | | | | | | | |
| Second | ETR | | | O | | O | | | | | | |
| light | 2 | | | | | | | | | | | |
| emitting | EML | O | O | | O | | O | O | O | | | O |
| unit | 2 | | | | | | | | | | | |
| (OL2) | HTR | | O | | | | | | O | | | |
| | 2 | | | | | | | | | | | |
| First light | ETR | | | O | O | | | | | | | |
| emitting | 1 | | | | | | | | | | | |
| unit | EML | O | O | | O | | O | O | O | | | O |
| (OL1) | 1 | | | | | | | | | | | |
| | HTR | | | | | O | | | O | | | |
| | 1 | | | | | | | | | | | |

Referring to Table 1, the light emitting elements according to Example 1 to Example 8 include the first compound, the second compound and the third compound in each of the first light emitting unit, the second light emitting unit and the capping layer. In contrast, the light emitting elements of the Comparative Examples do not include the first compound, the second compound and the third compound in at least one of the first light emitting unit, the second light emitting unit and the capping layer.

### 3. Evaluation of Properties of Light Emitting Elements

The element efficiency and element lifetime of the light emitting elements of the Examples and Comparative Examples were evaluated. In Table 2, the evaluation results of the light emitting elements of the Examples and Comparative Examples are shown. In order to evaluate the properties of the light emitting elements manufactured in Example 1 to Example 8, and Comparative Example 1 to Comparative Example 3, top emission efficiency (Cd/A/y) with respect to blue light, green light and red light was measured using a luminescence meter PR650, time consumed for reducing initial luminance to 95% was measured with respect to blue light, green light and red light as relative lifetime (T95), and relative lifetime based on the light emitting element of the Comparative Example 1 was calculated. The results are shown in Table 2. Meanwhile, in the evaluation of the light emitting elements, the blue light used light in a wavelength region of about 460 nm as an illustration, the green light used light in a wavelength region of about 530 nm as an illustration, and the red light used light in a wavelength region of about 620 nm as an illustration.

TABLE 2

| | Top emission efficiency | | | Relative lifetime | | |
|---|---|---|---|---|---|---|
| | (cd/A/y) | | | (T95) | | |
| | Blue | Green | Red | Blue | Green | Red |
| | light | light | light | light | light | light |
| Example 1 | 115% | 110% | 113% | 125% | 110% | 110% |
| Example 2 | 118% | 112% | 117% | 140% | 125% | 145% |
| Example 3 | 105% | 102% | 104% | 165% | 170% | 160% |
| Example 4 | 120% | 110% | 117% | 180% | 170% | 175% |
| Example 4 | 106% | 103% | 105% | 150% | 145% | 150% |
| Example 4 | 110% | 114% | 116% | 120% | 110% | 115% |
| Example 7 | 112% | 113% | 115% | 120% | 115% | 120% |
| Example 8 | 117% | 115% | 120% | 170% | 130% | 160% |
| Comparative | 100% | 100% | 100% | 100% | 100% | 100% |
| Example 1 | | | | | | |
| Comparative | 107% | 103% | 105% | 100% | 100% | 100% |
| Example 2 | | | | | | |
| Comparative | 107% | 105% | 107% | 120% | 105% | 105% |
| Example 3 | | | | | | |

Referring to the results of Table 2, the light emitting elements of embodiments of the present disclosure were confirmed to show improved emission efficiency and lifetime characteristics with respect to blue light, green light and red light in comparison to the light emitting elements of the Comparative Compounds.

Referring to Table 1 and Table 2, the cases of the light emitting elements of the Examples include the first compound, the second compound and the third compound in each of the first light emitting unit, the second light emitting unit and the capping layer. Because the light emitting elements of the Examples include a benzothiophene-based moiety in each of the first light emitting unit, the second light emitting unit and the capping layer, improving effects of emission efficiency may be achieved. In addition, high element efficiency and long lifetime can be accomplished.

In Comparative Example 1, the first compound, the second compound and the third compound are not included in each of the first light emitting unit, the second light emitting unit and the capping layer. Accordingly, it is thought that the light emitting element of Comparative Example 1 has inferior lifetime characteristics with respect to blue light, green light and red light, and low emission efficiency in contrast to the Examples.

Comparative Example 2 includes the third compound in the capping layer but does not include the first compound and the second compound in the first light emitting unit and the second light emitting unit. Because Comparative Example 2 does not include the first compound and the second compound in the first light emitting unit and the second light emitting unit, it is thought that the light emitting element of Comparative Example 2 has inferior lifetime characteristics with respect to blue light, green light and red light, and low emission efficiency in contrast to the Examples.

Comparative Example 3 includes the first compound and the second compound in the first light emitting unit and the second light emitting unit but does not include the third compound in the capping layer. Because Comparative Example 3 does not include the third compound in the capping layer, it is thought that the light emitting element of Comparative Example 3 has inferior lifetime characteristics with respect to blue light, green light and red light, and low emission efficiency in contrast to the Examples.

According to an embodiment of the present disclosure, a tandem light emitting element including a plurality of light emitting stacks includes the first compound, the second compound and the third compound, and accordingly, emission efficiency may be maximized or increased, and the emission efficiency and element lifetime of the light emitting element may be improved.

Although example embodiments of the present disclosure have been described, it is understood that the present disclosure should not be limited to these embodiments, but various changes and modifications can be made by one ordinary skilled in the art within the spirit and scope of the present disclosure as hereinafter claimed.

What is claimed is:

1. A light emitting element comprising:
a first electrode;
a first light emitting unit on the first electrode and comprising a first emission layer;
a charge generation unit on the first light emitting unit;
a second light emitting unit on the charge generation unit and comprising a second emission layer;
a second electrode on the second light emitting unit; and
a capping layer on the second electrode,
wherein:
the first light emitting unit comprises a first compound comprising a first moiety, the second light emitting unit comprises a second compound comprising a second moiety,
the capping layer comprises a third compound comprising a third moiety, and
the first moiety, the second moiety and the third moiety each independently comprises one among benzothiophene, thienopyridine, thienopyrimidine, thienopyridazine, thienopyrazine, thienotriazine, thienotetrazine, benzothiazole, thiazolopyridine, thiazolopyrimidine, thiazolopyridazine, thiazolopyrazine, thiazolotriazine, thiazoloetetrazine, benzothiadiazole, thiadiazolepyridine, thiadiazolepyrimidine, thiadiazolepyridazine, thiadiazolepyrazine, thiadiazoletriazine, and thiadiazoletetrazine.

2. The light emitting element of claim 1, wherein the first moiety, the second moiety and the third moiety each independently comprises one among benzothiophene, thienopyridine, benzothiazole, and thiazolopyridine.

3. The light emitting element of claim 1, wherein the capping layer comprises the third compound represented by the following Formula 1: 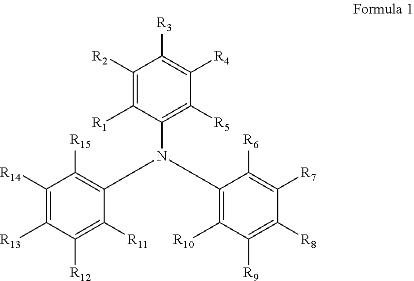
in Formula 1,
R₁ to R₁₅ are each independently a hydrogen atom, a deuterium atom, a halogen atom, a substituted or unsubstituted amine group, a substituted or unsubstituted aryl group of 6 to 30 ring-forming carbon atoms, or a substituted or unsubstituted heteroaryl group of 2 to 30 ring-forming carbon atoms, and
at least one among R₁ to R₁₅ is a substituent represented by the following Formula 2: 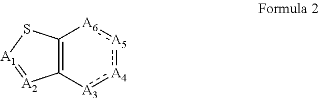
in Formula 2,
A1 to A6 are each independently CRᵢ or N, and
Rᵢ is a hydrogen atom, a deuterium atom, a halogen atom, a substituted or unsubstituted amine group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined together with an adjacent group to form a ring.

4. The light emitting element of claim 1, wherein the capping layer comprises at least one among the compounds in the following Compound Group C: Compound Group C

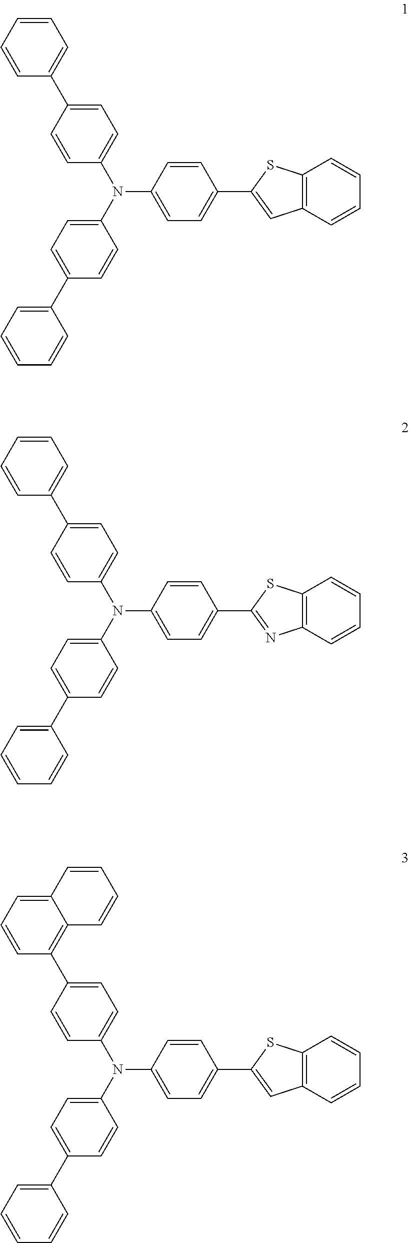 [SMILES: c1ccc(-c2ccc(N(c3ccc(-c4ccccc4)cc3)c3ccc(-c4cc5ccccc5s4)cc3)cc2)cc1 ; c1ccc(-c2ccc(N(c3ccc(-c4ccccc4)cc3)c3ccc(-c4nc5ccccc5s4)cc3)cc2)cc1 ; c1ccc(-c2ccc(N(c3ccc(-c4cc5ccccc5s4)cc3)c3ccc(-c4cccc5ccccc45)cc3)cc2)cc1]

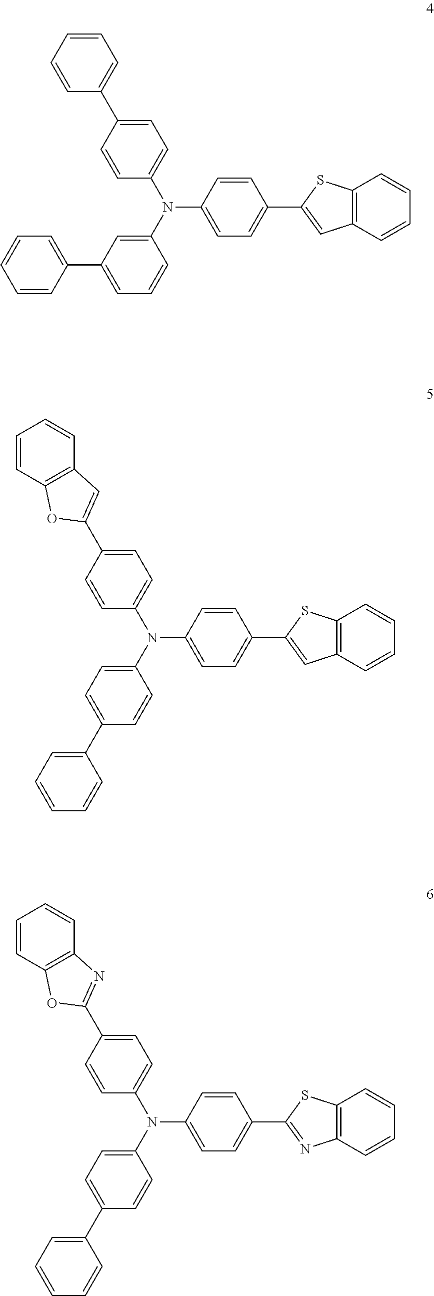 [SMILES: c1ccc(-c2ccc(N(c3ccc(-c4cc5ccccc5s4)cc3)c3cccc(-c4ccccc4)c3)cc2)cc1 ; c1ccc(-c2ccc(N(c3ccc(-c4cc5ccccc5o4)cc3)c3ccc(-c4cc5ccccc5s4)cc3)cc2)cc1 ; c1ccc(-c2ccc(N(c3ccc(-c4nc5ccccc5o4)cc3)c3ccc(-c4nc5ccccc5s4)cc3)cc2)cc1]

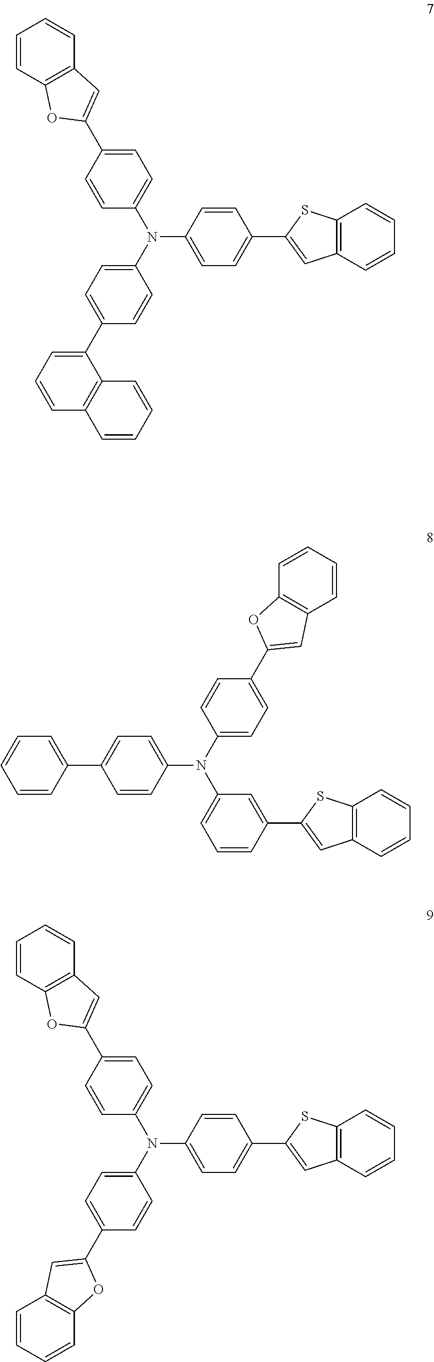 [SMILES: c1ccc2oc(-c3ccc(N(c4ccc(-c5cc6ccccc6s5)cc4)c4ccc(-c5cccc6ccccc56)cc4)cc3)cc2c1 ; c1ccc(-c2ccc(N(c3ccc(-c4cc5ccccc5o4)cc3)c3cccc(-c4cc5ccccc5s4)c3)cc2)cc1 ; c1ccc2oc(-c3ccc(N(c4ccc(-c5cc6ccccc6o5)cc4)c4ccc(-c5cc6ccccc6s5)cc4)cc3)cc2c1]

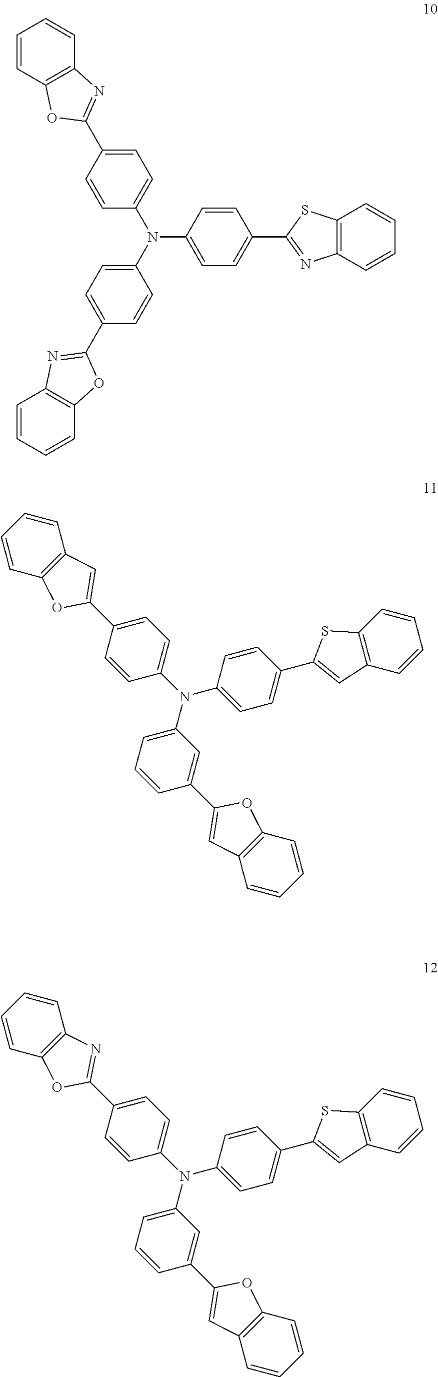 [SMILES: c1ccc2oc(-c3ccc(N(c4ccc(-c5nc6ccccc6o5)cc4)c4ccc(-c5nc6ccccc6s5)cc4)cc3)nc2c1 ; c1cc(-c2cc3ccccc3o2)cc(N(c2ccc(-c3cc4ccccc4o3)cc2)c2ccc(-c3cc4ccccc4s3)cc2)c1 ; c1cc(-c2cc3ccccc3o2)cc(N(c2ccc(-c3nc4ccccc4o3)cc2)c2ccc(-c3cc4ccccc4s3)cc2)c1]

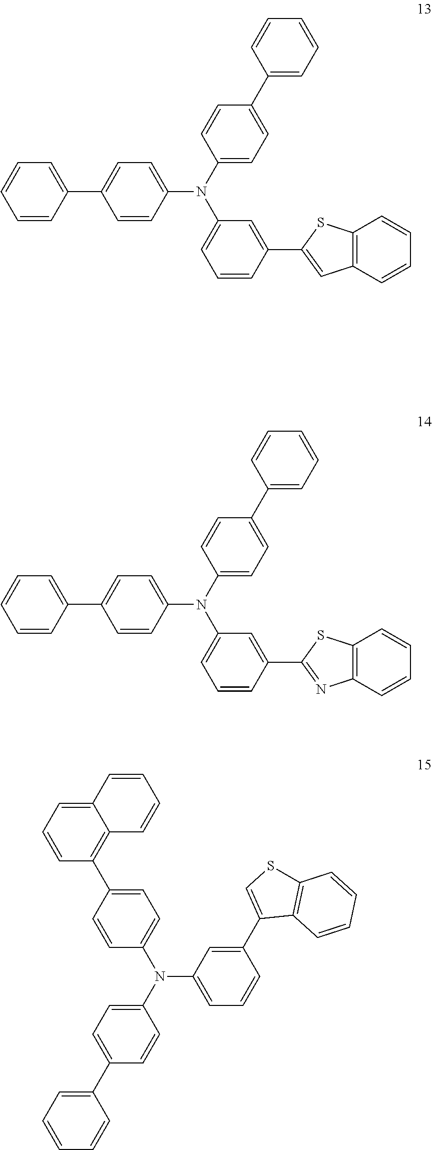 [SMILES: c1ccc(-c2ccc(N(c3ccc(-c4ccccc4)cc3)c3cccc(-c4cc5ccccc5s4)c3)cc2)cc1 ; c1ccc(-c2ccc(N(c3ccc(-c4ccccc4)cc3)c3cccc(-c4nc5ccccc5s4)c3)cc2)cc1 ; c1ccc(-c2ccc(N(c3ccc(-c4cccc5ccccc45)cc3)c3cccc(-c4csc5ccccc45)c3)cc2)cc1]

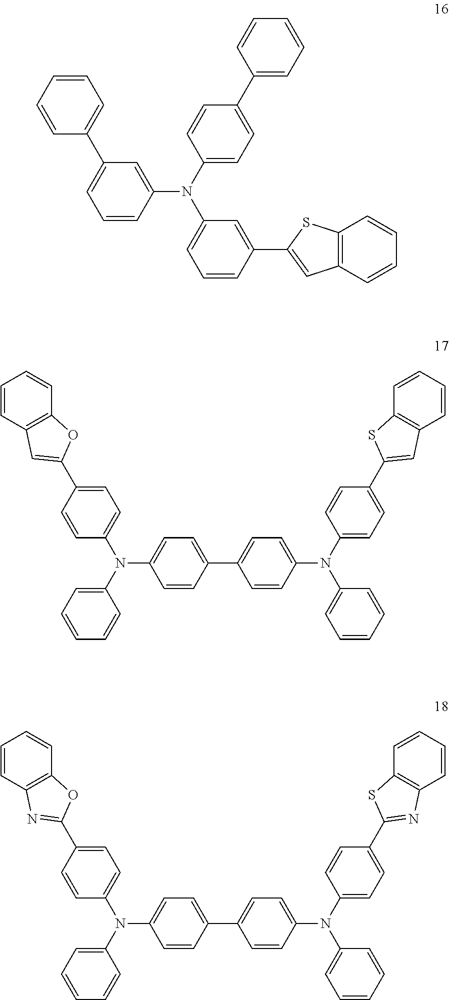 [SMILES: c1ccc(-c2ccc(N(c3cccc(-c4ccccc4)c3)c3cccc(-c4cc5ccccc5s4)c3)cc2)cc1 ; c1ccc(N(c2ccc(-c3ccc(N(c4ccccc4)c4ccc(-c5cc6ccccc6s5)cc4)cc3)cc2)c2ccc(-c3cc4ccccc4o3)cc2)cc1 ; c1ccc(N(c2ccc(-c3ccc(N(c4ccccc4)c4ccc(-c5nc6ccccc6s5)cc4)cc3)cc2)c2ccc(-c3nc4ccccc4o3)cc2)cc1]

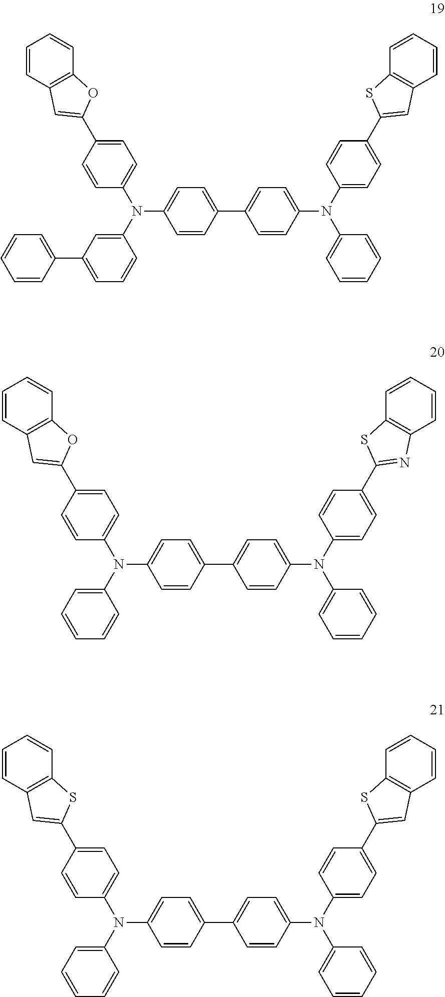 [SMILES: c1ccc(-c2cccc(N(c3ccc(-c4ccc(N(c5ccccc5)c5ccc(-c6cc7ccccc7s6)cc5)cc4)cc3)c3ccc(-c4cc5ccccc5o4)cc3)c2)cc1 ; c1ccc(N(c2ccc(-c3ccc(N(c4ccccc4)c4ccc(-c5nc6ccccc6s5)cc4)cc3)cc2)c2ccc(-c3cc4ccccc4o3)cc2)cc1 ; c1ccc(N(c2ccc(-c3ccc(N(c4ccccc4)c4ccc(-c5cc6ccccc6s5)cc4)cc3)cc2)c2ccc(-c3cc4ccccc4s3)cc2)cc1]

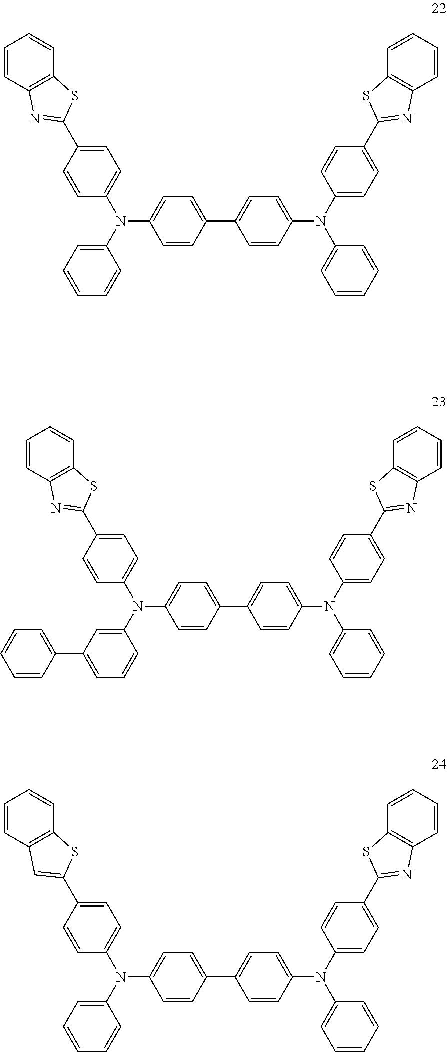 [SMILES: c1ccc(N(c2ccc(-c3ccc(N(c4ccccc4)c4ccc(-c5nc6ccccc6s5)cc4)cc3)cc2)c2ccc(-c3nc4ccccc4s3)cc2)cc1 ; c1ccc(-c2cccc(N(c3ccc(-c4ccc(N(c5ccccc5)c5ccc(-c6nc7ccccc7s6)cc5)cc4)cc3)c3ccc(-c4nc5ccccc5s4)cc3)c2)cc1 ; c1ccc(N(c2ccc(-c3ccc(N(c4ccccc4)c4ccc(-c5nc6ccccc6s5)cc4)cc3)cc2)c2ccc(-c3cc4ccccc4s3)cc2)cc1]

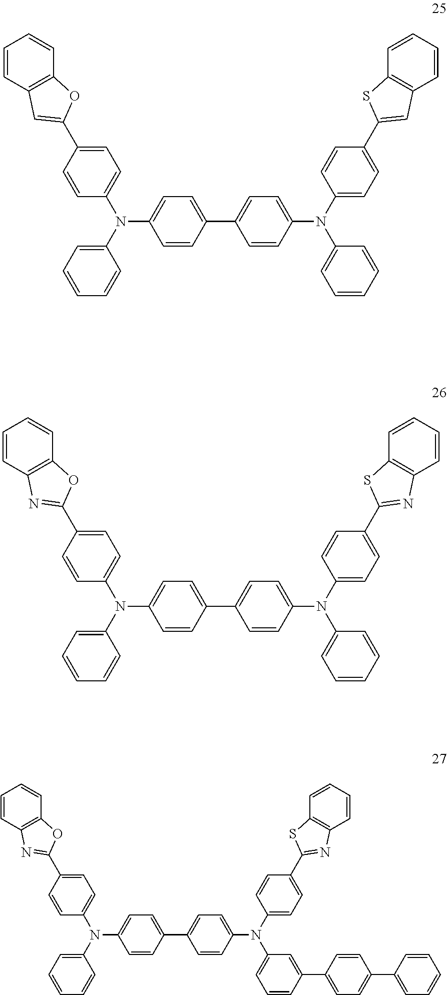 [SMILES: c1ccc(N(c2ccc(-c3ccc(N(c4ccccc4)c4ccc(-c5cc6ccccc6s5)cc4)cc3)cc2)c2ccc(-c3cc4ccccc4o3)cc2)cc1 ; c1ccc(N(c2ccc(-c3ccc(N(c4ccccc4)c4ccc(-c5nc6ccccc6s5)cc4)cc3)cc2)c2ccc(-c3nc4ccccc4o3)cc2)cc1 ; c1ccc(-c2ccc(-c3cccc(N(c4ccc(-c5ccc(N(c6ccccc6)c6ccc(-c7nc8ccccc8o7)cc6)cc5)cc4)c4ccc(-c5nc6ccccc6s5)cc4)c3)cc2)cc1]

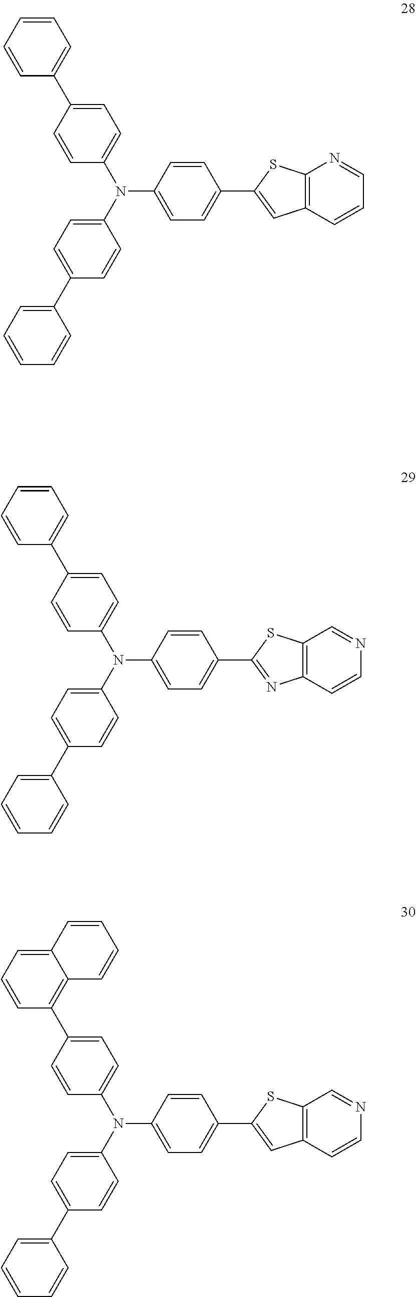 [SMILES: c1ccc(-c2ccc(N(c3ccc(-c4ccccc4)cc3)c3ccc(-c4cc5cccnc5s4)cc3)cc2)cc1 ; c1ccc(-c2ccc(N(c3ccc(-c4ccccc4)cc3)c3ccc(-c4nc5ccncc5s4)cc3)cc2)cc1 ; c1ccc(-c2ccc(N(c3ccc(-c4cc5ccncc5s4)cc3)c3ccc(-c4cccc5ccccc45)cc3)cc2)cc1]

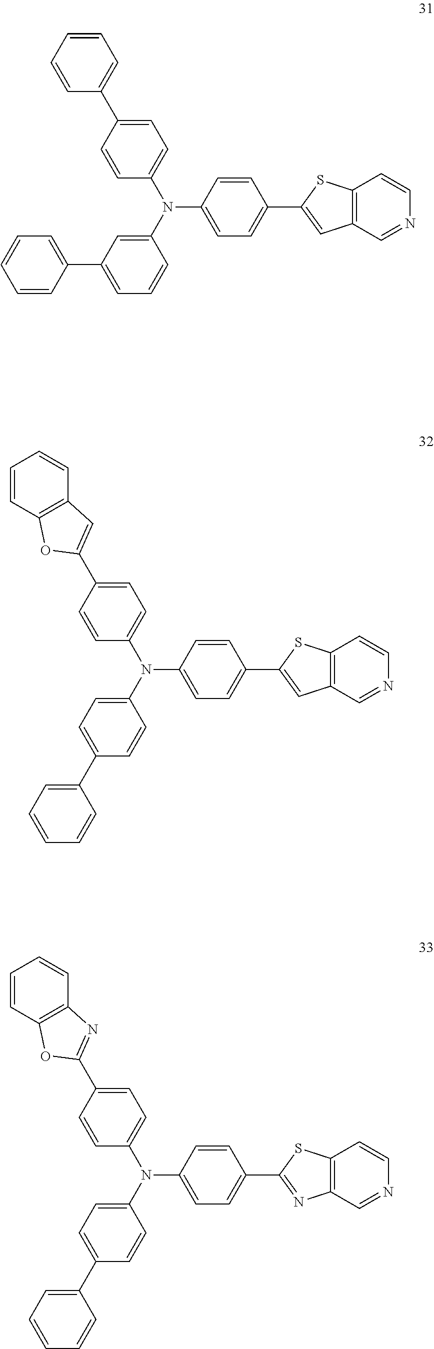 [SMILES: c1ccc(-c2ccc(N(c3ccc(-c4cc5cnccc5s4)cc3)c3cccc(-c4ccccc4)c3)cc2)cc1 ; c1ccc(-c2ccc(N(c3ccc(-c4cc5ccccc5o4)cc3)c3ccc(-c4cc5cnccc5s4)cc3)cc2)cc1 ; c1ccc(-c2ccc(N(c3ccc(-c4nc5ccccc5o4)cc3)c3ccc(-c4nc5cnccc5s4)cc3)cc2)cc1]

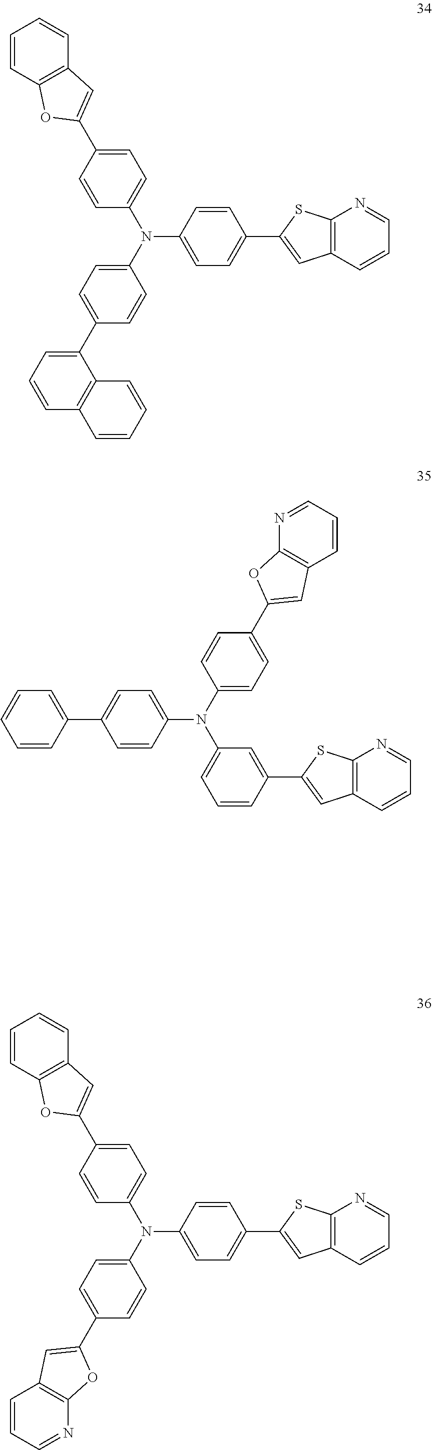 [SMILES: c1ccc2oc(-c3ccc(N(c4ccc(-c5cc6cccnc6s5)cc4)c4ccc(-c5cccc6ccccc56)cc4)cc3)cc2c1 ; c1ccc(-c2ccc(N(c3ccc(-c4cc5cccnc5o4)cc3)c3cccc(-c4cc5cccnc5s4)c3)cc2)cc1 ; c1ccc2oc(-c3ccc(N(c4ccc(-c5cc6cccnc6o5)cc4)c4ccc(-c5cc6cccnc6s5)cc4)cc3)cc2c1]

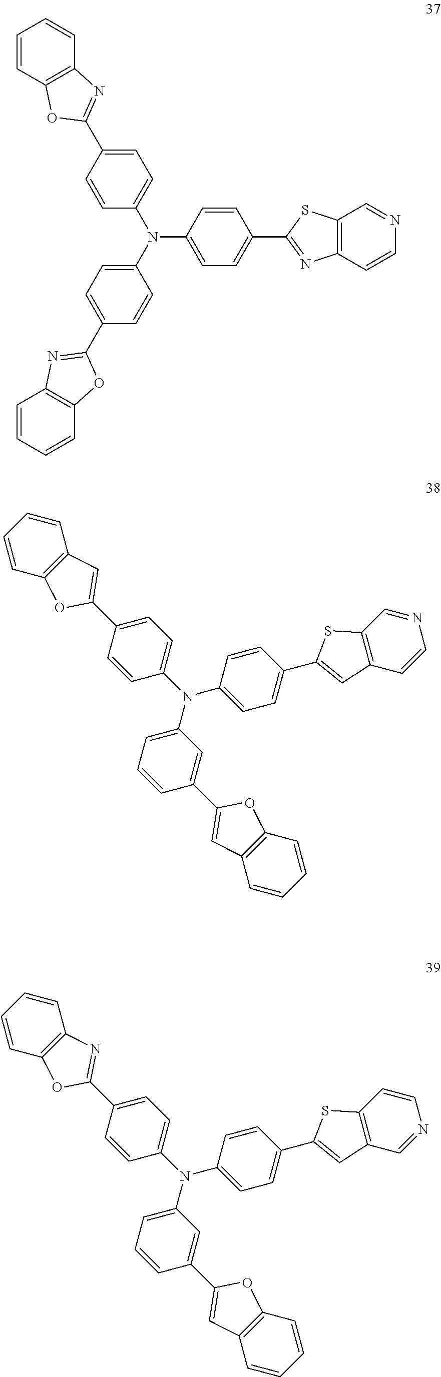 [SMILES: c1ccc2oc(-c3ccc(N(c4ccc(-c5nc6ccccc6o5)cc4)c4ccc(-c5nc6ccncc6s5)cc4)cc3)nc2c1 ; c1cc(-c2cc3ccccc3o2)cc(N(c2ccc(-c3cc4ccccc4o3)cc2)c2ccc(-c3cc4ccncc4s3)cc2)c1 ; c1cc(-c2cc3ccccc3o2)cc(N(c2ccc(-c3nc4ccccc4o3)cc2)c2ccc(-c3cc4cnccc4s3)cc2)c1]

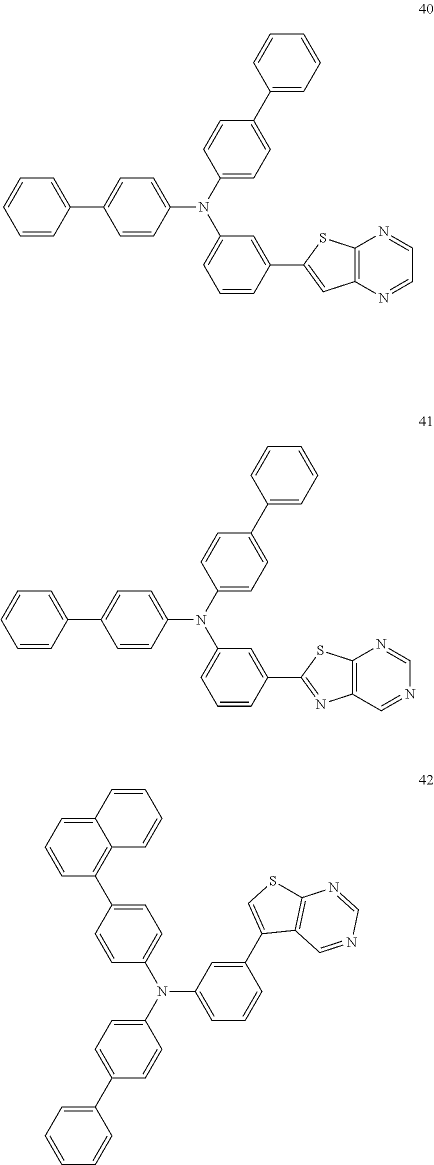 [SMILES: c1ccc(-c2ccc(N(c3ccc(-c4ccccc4)cc3)c3cccc(-c4cc5nccnc5s4)c3)cc2)cc1 ; c1ccc(-c2ccc(N(c3ccc(-c4ccccc4)cc3)c3cccc(-c4nc5cncnc5s4)c3)cc2)cc1 ; c1ccc(-c2ccc(N(c3ccc(-c4cccc5ccccc45)cc3)c3cccc(-c4csc5ncncc45)c3)cc2)cc1]

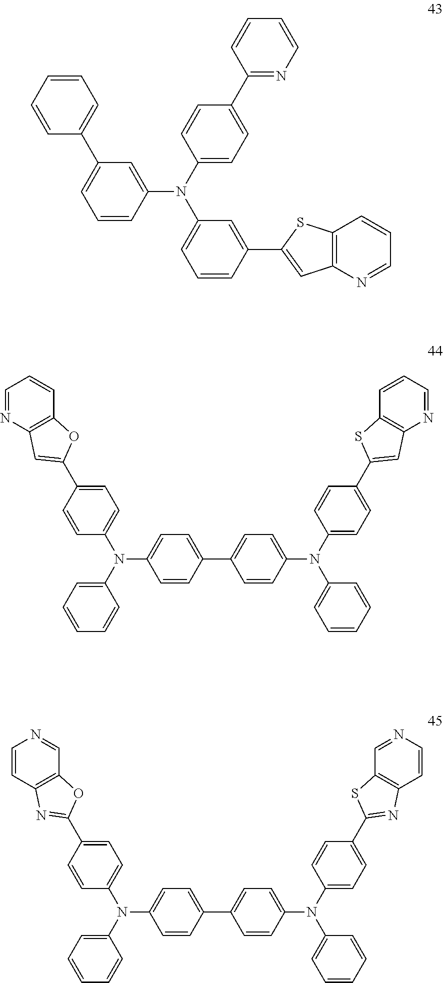 [SMILES: c1ccc(-c2cccc(N(c3ccc(-c4ccccn4)cc3)c3cccc(-c4cc5ncccc5s4)c3)c2)cc1 ; c1ccc(N(c2ccc(-c3ccc(N(c4ccccc4)c4ccc(-c5cc6ncccc6s5)cc4)cc3)cc2)c2ccc(-c3cc4ncccc4o3)cc2)cc1 ; c1ccc(N(c2ccc(-c3ccc(N(c4ccccc4)c4ccc(-c5nc6ccncc6s5)cc4)cc3)cc2)c2ccc(-c3nc4ccncc4o3)cc2)cc1]

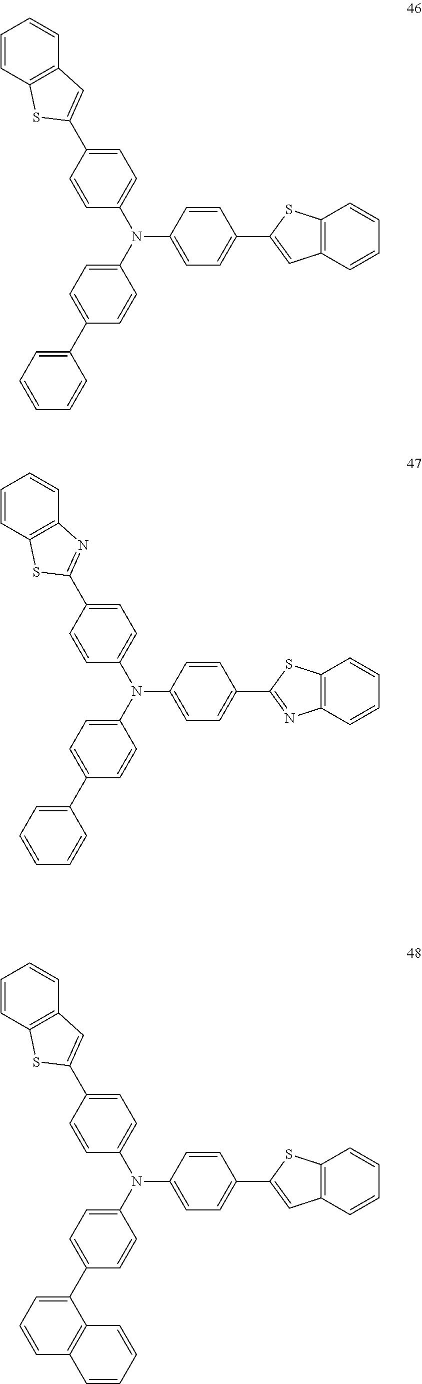 [SMILES: c1ccc(-c2ccc(N(c3ccc(-c4cc5ccccc5s4)cc3)c3ccc(-c4cc5ccccc5s4)cc3)cc2)cc1 ; c1ccc(-c2ccc(N(c3ccc(-c4nc5ccccc5s4)cc3)c3ccc(-c4nc5ccccc5s4)cc3)cc2)cc1 ; c1ccc2sc(-c3ccc(N(c4ccc(-c5cc6ccccc6s5)cc4)c4ccc(-c5cccc6ccccc56)cc4)cc3)cc2c1]

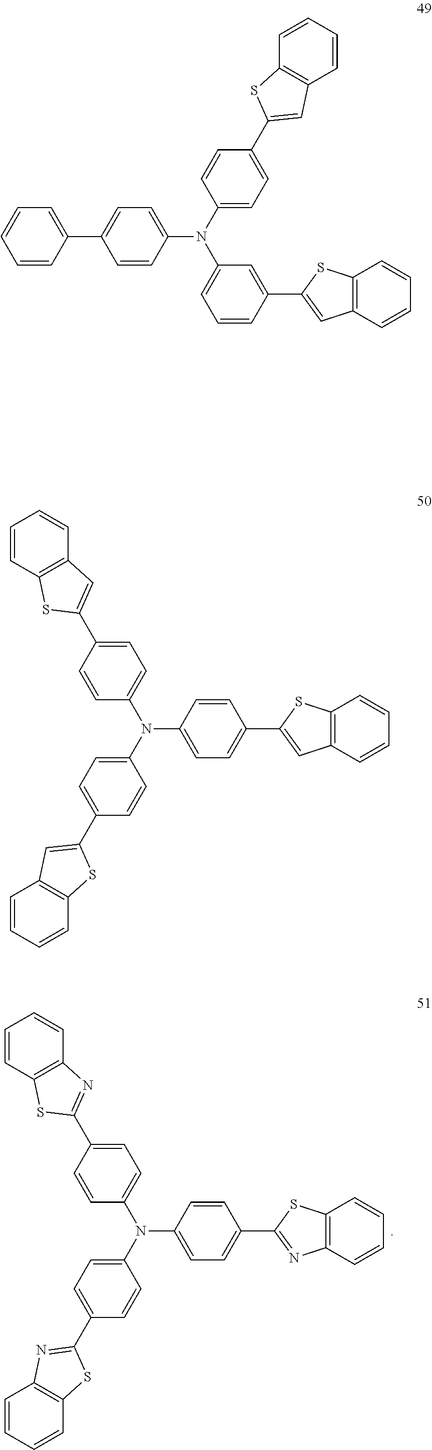 [SMILES: c1ccc(-c2ccc(N(c3ccc(-c4cc5ccccc5s4)cc3)c3cccc(-c4cc5ccccc5s4)c3)cc2)cc1 ; c1ccc2sc(-c3ccc(N(c4ccc(-c5cc6ccccc6s5)cc4)c4ccc(-c5cc6ccccc6s5)cc4)cc3)cc2c1 ; c1ccc2sc(-c3ccc(N(c4ccc(-c5nc6ccccc6s5)cc4)c4ccc(-c5nc6ccccc6s5)cc4)cc3)nc2c1]

5. The light emitting element of claim 1, wherein:
the first emission layer comprises a first light emitting host and a first light emitting dopant doped in the first light emitting host and comprising the first compound, and
the second emission layer comprises a second light emitting host and a second light emitting dopant doped in the second light emitting host and comprising the second compound.

6. The light emitting element of claim 1, wherein:
the first emission layer comprises a first red emission layer that emits red light, a first green emission layer that emits green light, and a first blue emission layer that emits blue light,
the second emission layer comprises a second red emission layer that emits red light, a second green emission layer that emits green light, and a second blue emission layer that emits blue light,
at least one among the first red emission layer, the first green emission layer and the first blue emission layer comprises the first compound, and
at least one among the second red emission layer, the second green emission layer and the second blue emission layer comprises the second compound.

7. The light emitting element of claim 6, wherein:
the first red emission layer, the first green emission layer and the first blue emission layer are separated from each other on a plane, and
the second red emission layer, the second green emission layer and the second blue emission layer are separated from each other on a plane.

8. The light emitting element of claim 6, wherein:
the first red emission layer comprises a first red light emitting host and a first red light emitting dopant doped in the first red light emitting host,
the second red emission layer comprises a second red light emitting host and a second red light emitting dopant doped in the second red light emitting host,
the first green emission layer comprises a first green light emitting host and a first green light emitting dopant doped in the first green light emitting host,
the second green emission layer comprises a second green light emitting host and a second green light emitting dopant doped in the second green light emitting host,
at least one among the first red light emitting dopant and the first green light emitting dopant comprises the first compound, and
at least one among the second red light emitting dopant and the second green light emitting dopant comprises the second compound.

9. The light emitting element of claim 8, wherein the first red light emitting dopant, the second red light emitting dopant, the first green light emitting dopant and the second green light emitting dopant are phosphorescence dopants.

10. The light emitting element of claim 8, wherein:
at least one among the first red light emitting dopant and the first green light emitting dopant is represented by the following Formula 3-1 or Formula 3-2, and
at least one among the second red light emitting dopant and the second green light emitting dopant is represented by the following Formula 3-1 or Formula 3-2: 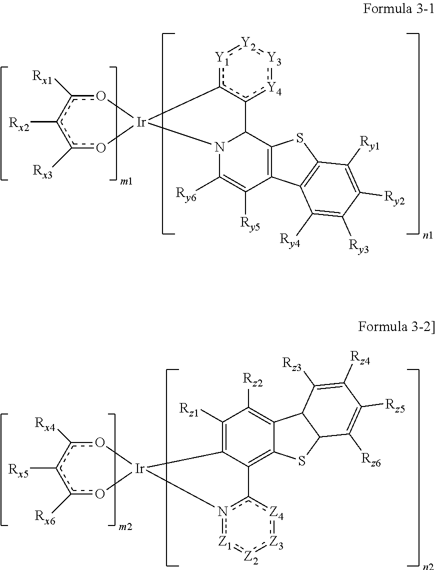
in Formula 3-1 and Formula 3-2,
Y₁ to Y₄, and Z₁ to Z₄ are each independently CR_{w} or N,
R_{w} and Rₓ₁ to Rₓ₆ are each independently a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined together with an adjacent group to form a ring,
R_{y1} to R_{y6}, and R_{z1} to R_{z6} are each independently a hydrogen atom, a deuterium atom, a halogen atom, a cyano group or a substituted or unsubstituted alkyl group of 1 to 20 carbon atoms,
m1 and m2 are each independently 0 or 1, and
n1 and n2 are each independently 2 or 3,
where, if m1 is 0, n1 is 3, if m1 is 1, n1 is 2, if m2 is 0, n2 is 3, and if m2 is 1, n2 is 2.

11. The light emitting element of claim 8, wherein:
at least one among the first red light emitting dopant and the first green light emitting dopant comprises at least one among the compounds in the following Compound Group R, and
at least one among the second red light emitting dopant and the second green light emitting dopant comprises at least one among the compounds in the following Compound Group R:

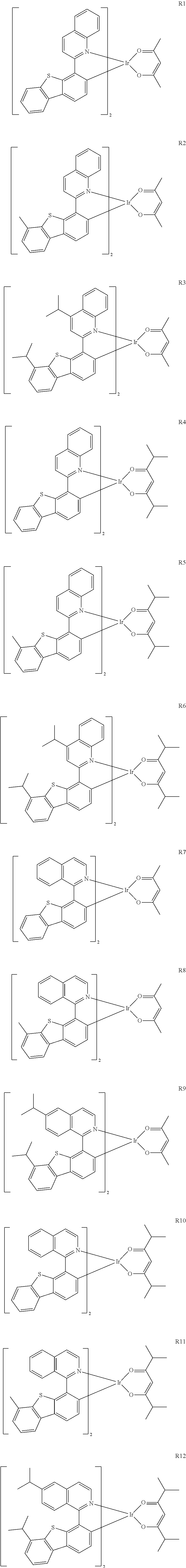

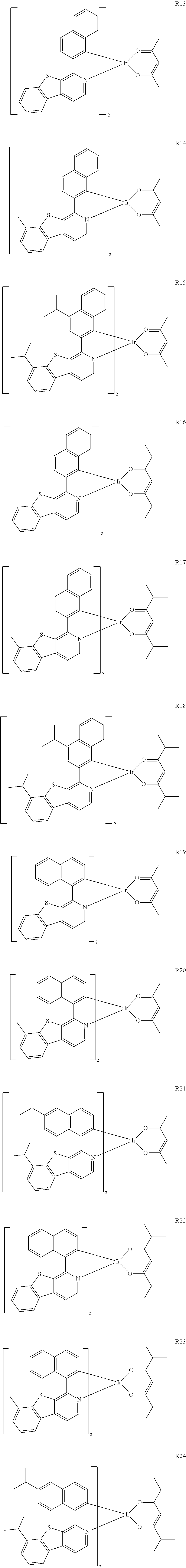

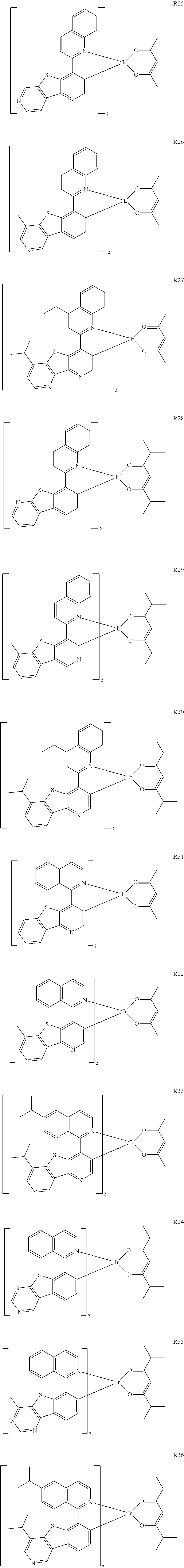

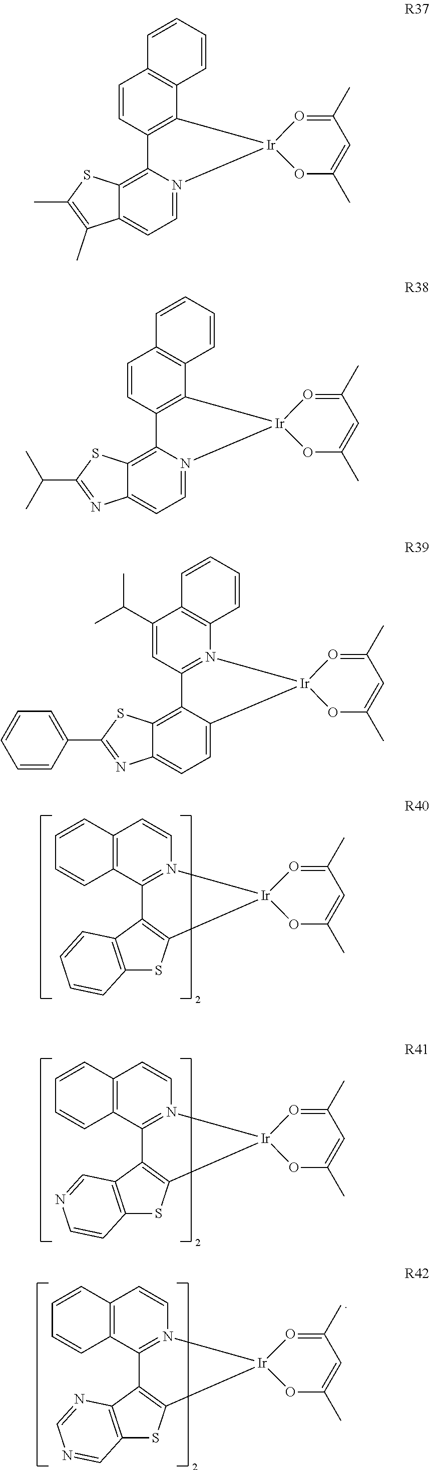

12. The light emitting element of claim 6, wherein:
the first blue emission layer comprises a first blue light emitting host and a first blue light emitting dopant doped in the first blue light emitting host,
the second blue emission layer comprises a second blue light emitting host and a second blue light emitting dopant doped in the second blue light emitting host, and
at least one among the first blue light emitting dopant and the second blue light emitting dopant comprises at least one among the compounds in the following Compound Group B:

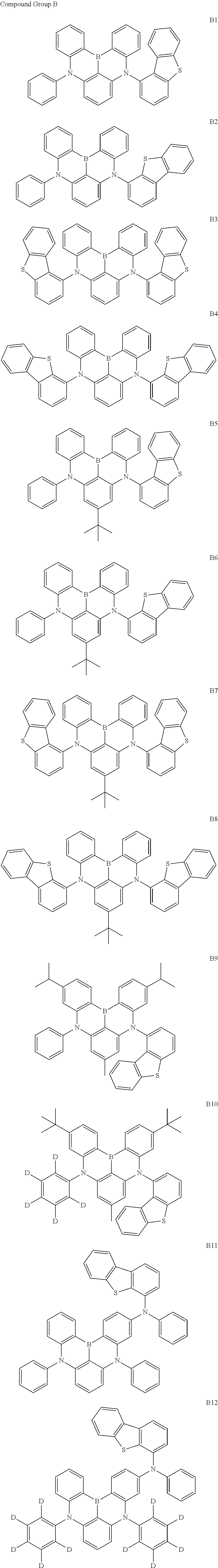

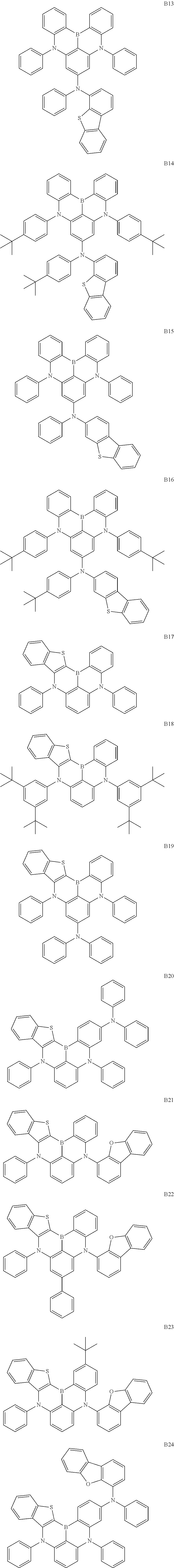

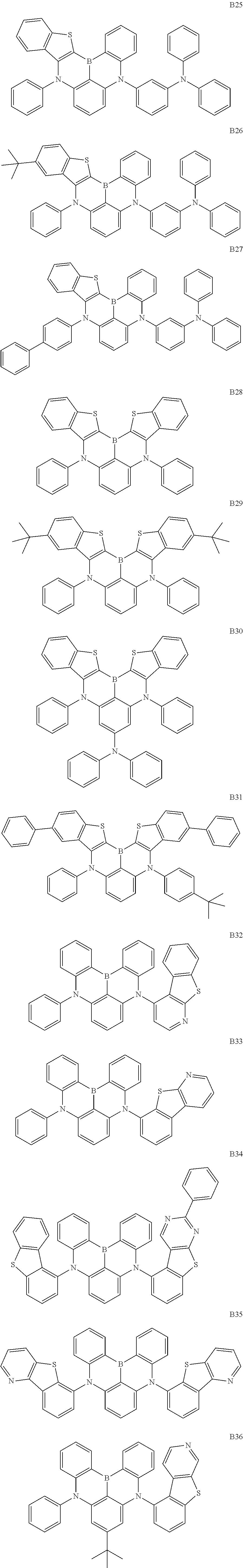

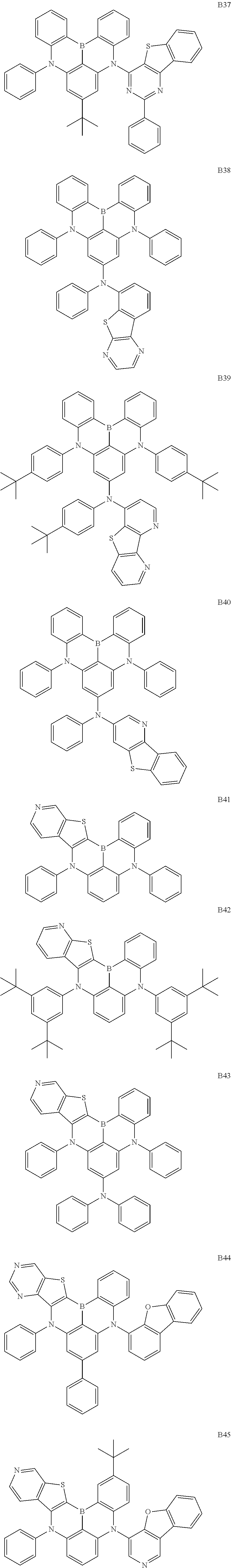

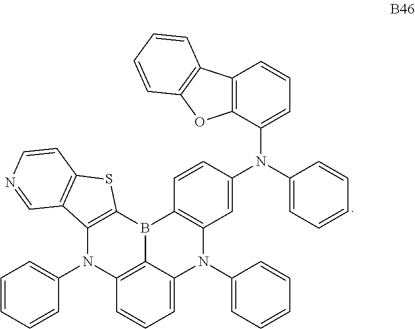 [SMILES: c1ccc(N2c3cc(N(c4ccccc4)c4cccc5c4oc4ccccc45)ccc3B3c4sc5ccncc5c4N(c4ccccc4)c4cccc2c43)cc1]

13. The light emitting element of claim 12, wherein the first blue light emitting dopant and the second blue light emitting dopant are fluorescence dopants.

14. The light emitting element of claim 1, wherein:
the first light emitting unit further comprises a first hole transport region between the first electrode and the first emission layer, and a first electron transport region between the first emission layer and the charge generation unit, and
the second light emitting unit further comprises a second hole transport region between the charge generation unit and the second emission layer, and a second electron transport region between the second emission layer and the second electrode.

15. The light emitting element of claim 14, wherein:
at least one among the first hole transport region, the first emission layer and the first electron transport region comprises the first compound, and
at least one among the second hole transport region, the second emission layer and the second electron transport region comprises the second compound.

16. The light emitting element of claim 14, wherein at least one among the first hole transport region and the second hole transport region comprises at least one among the compounds in the following Compound Group HT:

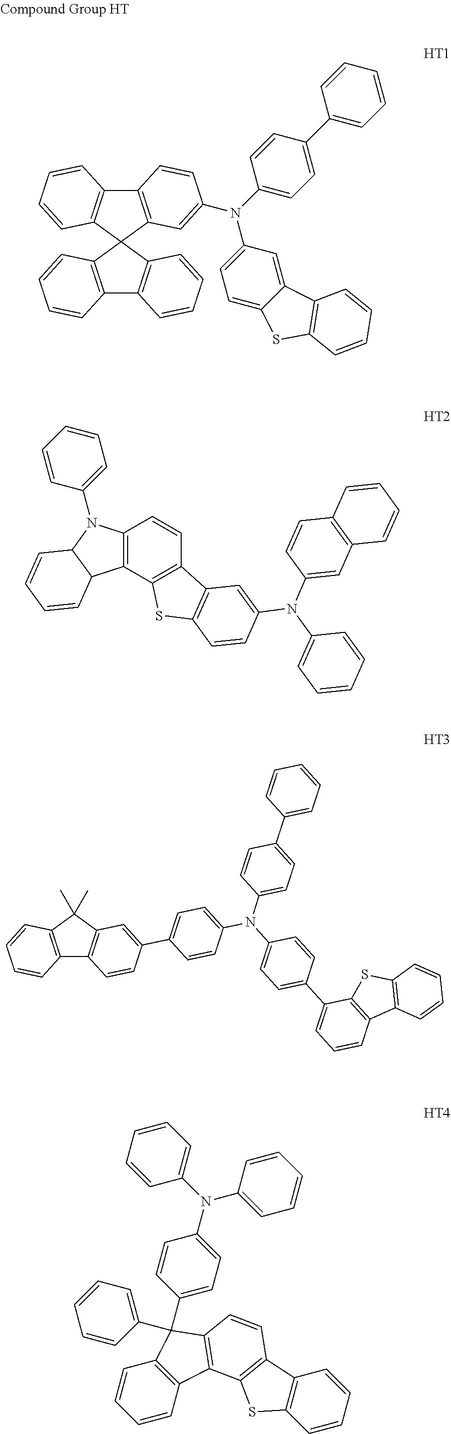 [SMILES: c1ccc(-c2ccc(N(c3ccc4c(c3)C3(c5ccccc5-c5ccccc53)c3ccccc3-4)c3ccc4sc5ccccc5c4c3)cc2)cc1 ; C1=CC2c3c(ccc4c3sc3ccc(N(c5ccccc5)c5ccc6ccccc6c5)cc34)N(c3ccccc3)C2C=C1 ; CC1(C)c2ccccc2-c2ccc(-c3ccc(N(c4ccc(-c5ccccc5)cc4)c4ccc(-c5cccc6c5sc5ccccc56)cc4)cc3)cc21 ; c1ccc(N(c2ccccc2)c2ccc(C3(c4ccccc4)c4ccccc4-c4c3ccc3c4sc4ccccc43)cc2)cc1]

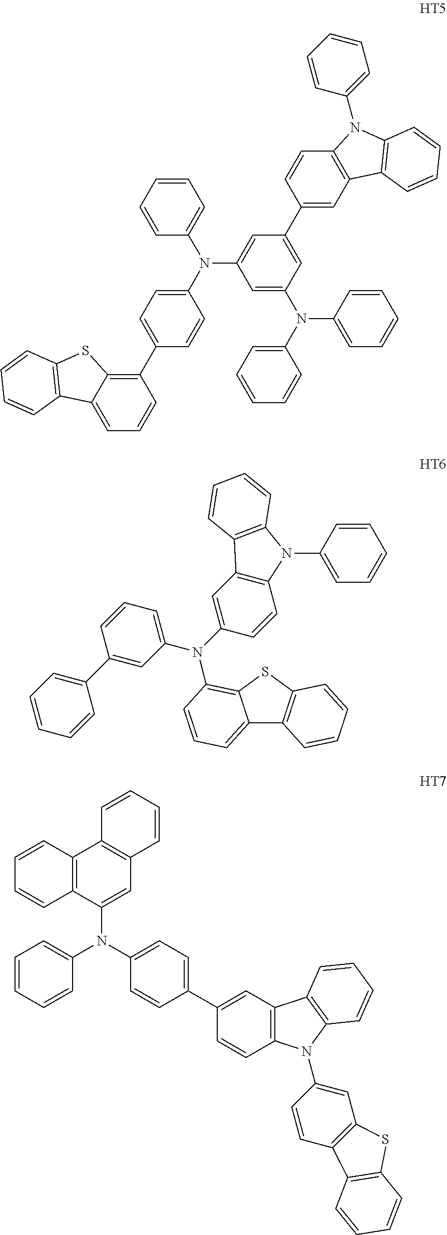 [SMILES: c1ccc(N(c2ccccc2)c2cc(-c3ccc4c(c3)c3ccccc3n4-c3ccccc3)cc(N(c3ccccc3)c3ccc(-c4cccc5c4sc4ccccc45)cc3)c2)cc1 ; c1ccc(-c2cccc(N(c3ccc4c(c3)c3ccccc3n4-c3ccccc3)c3cccc4c3sc3ccccc34)c2)cc1 ; c1ccc(N(c2ccc(-c3ccc4c(c3)c3ccccc3n4-c3ccc4c(c3)sc3ccccc34)cc2)c2cc3ccccc3c3ccccc23)cc1]

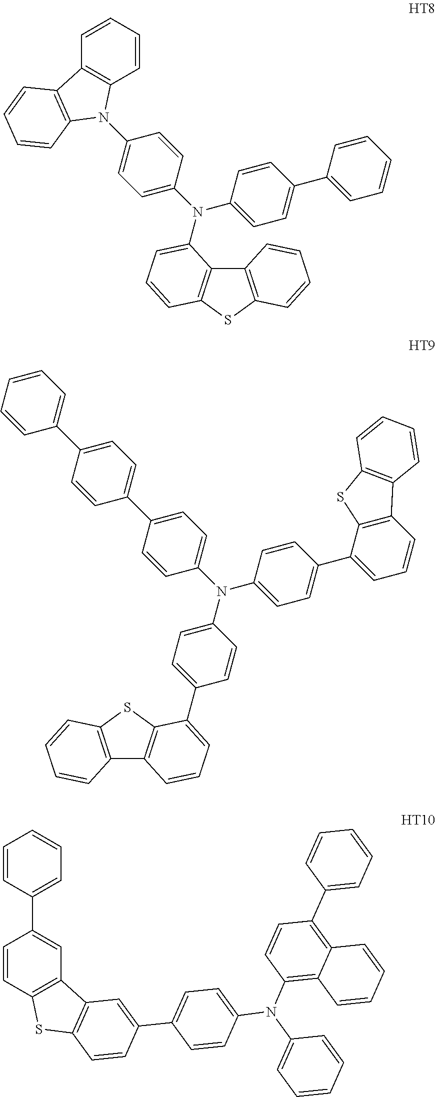 [SMILES: c1ccc(-c2ccc(N(c3ccc(-n4c5ccccc5c5ccccc54)cc3)c3cccc4sc5ccccc5c34)cc2)cc1 ; c1ccc(-c2ccc(-c3ccc(N(c4ccc(-c5cccc6c5sc5ccccc56)cc4)c4ccc(-c5cccc6c5sc5ccccc56)cc4)cc3)cc2)cc1 ; c1ccc(-c2ccc3sc4ccc(-c5ccc(N(c6ccccc6)c6ccc(-c7ccccc7)c7ccccc67)cc5)cc4c3c2)cc1]

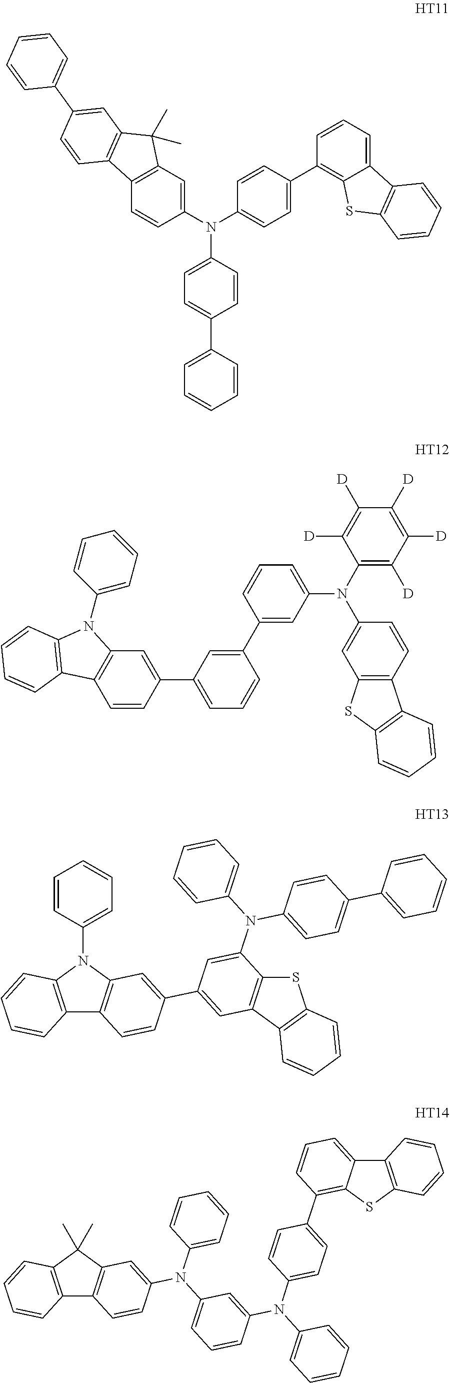 [SMILES: CC1(C)c2cc(-c3ccccc3)ccc2-c2ccc(N(c3ccc(-c4ccccc4)cc3)c3ccc(-c4cccc5c4sc4ccccc45)cc3)cc21 ; [2H]c1c([2H])c([2H])c(N(c2cccc(-c3cccc(-c4ccc5c6ccccc6n(-c6ccccc6)c5c4)c3)c2)c2ccc3c(c2)sc2ccccc23)c([2H])c1[2H] ; c1ccc(-c2ccc(N(c3ccccc3)c3cc(-c4ccc5c6ccccc6n(-c6ccccc6)c5c4)cc4c3sc3ccccc34)cc2)cc1 ; CC1(C)c2ccccc2-c2ccc(N(c3ccccc3)c3cccc(N(c4ccccc4)c4ccc(-c5cccc6c5sc5ccccc56)cc4)c3)cc21]

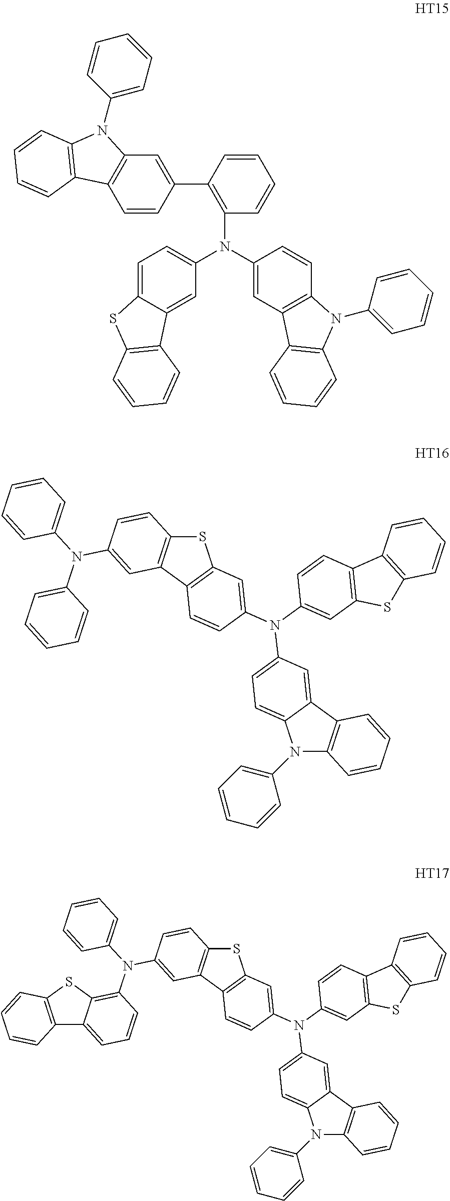 [SMILES: c1ccc(-n2c3ccccc3c3cc(N(c4ccc5sc6ccccc6c5c4)c4ccccc4-c4ccc5c6ccccc6n(-c6ccccc6)c5c4)ccc32)cc1 ; c1ccc(N(c2ccccc2)c2ccc3sc4cc(N(c5ccc6c(c5)sc5ccccc56)c5ccc6c(c5)c5ccccc5n6-c5ccccc5)ccc4c3c2)cc1 ; c1ccc(N(c2ccc3sc4cc(N(c5ccc6c(c5)sc5ccccc56)c5ccc6c(c5)c5ccccc5n6-c5ccccc5)ccc4c3c2)c2cccc3c2sc2ccccc23)cc1]

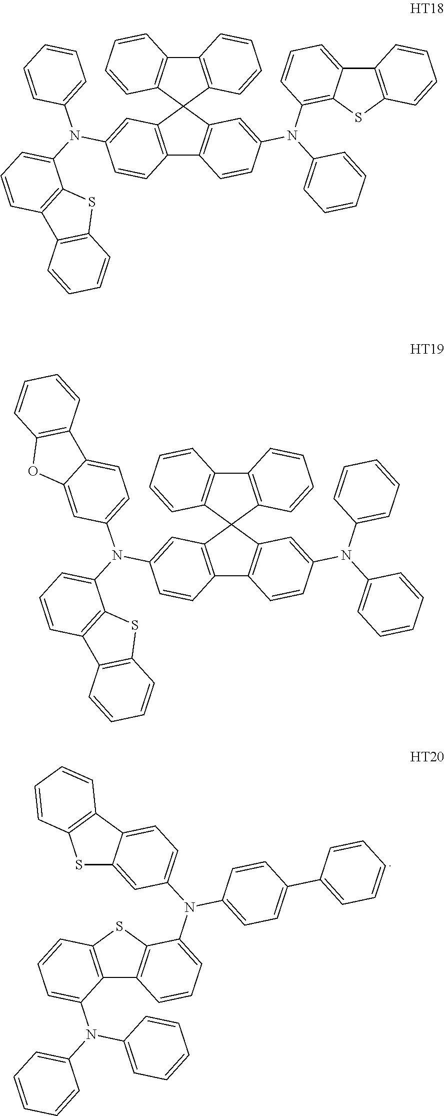 [SMILES: c1ccc(N(c2ccc3c(c2)C2(c4ccccc4-c4ccccc42)c2cc(N(c4ccccc4)c4cccc5c4sc4ccccc45)ccc2-3)c2cccc3c2sc2ccccc23)cc1 ; c1ccc(N(c2ccccc2)c2ccc3c(c2)C2(c4ccccc4-c4ccccc42)c2cc(N(c4ccc5c(c4)oc4ccccc45)c4cccc5c4sc4ccccc45)ccc2-3)cc1 ; c1ccc(-c2ccc(N(c3ccc4c(c3)sc3ccccc34)c3cccc4c3sc3cccc(N(c5ccccc5)c5ccccc5)c34)cc2)cc1]

17. The light emitting element of claim 14, wherein at least one among the first electron transport region and the second electron transport region comprises at least one among the compounds in the following Compound Group E:

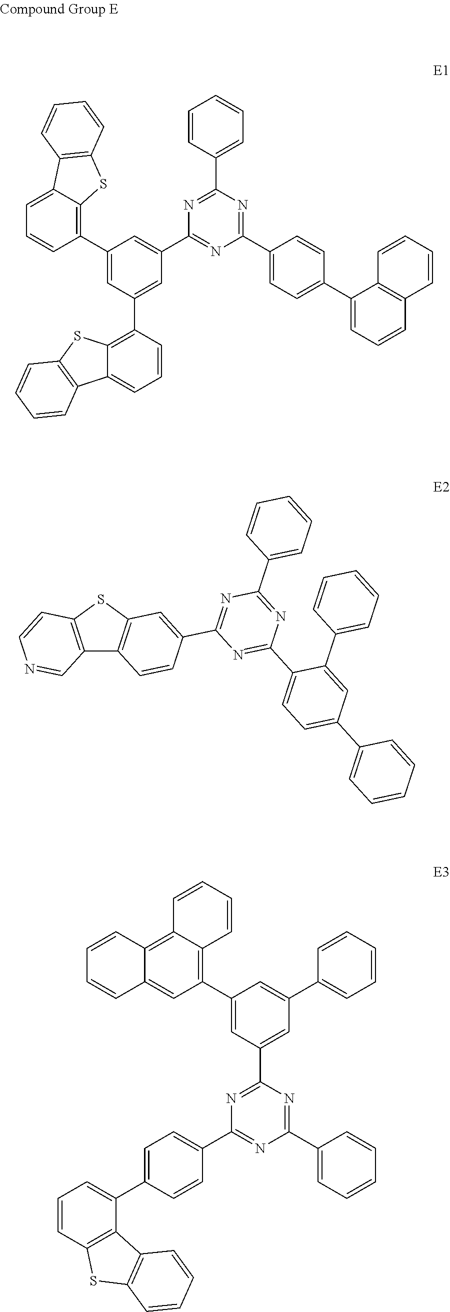 [SMILES: c1ccc(-c2nc(-c3ccc(-c4cccc5ccccc45)cc3)nc(-c3cc(-c4cccc5c4sc4ccccc45)cc(-c4cccc5c4sc4ccccc45)c3)n2)cc1 ; c1ccc(-c2ccc(-c3nc(-c4ccccc4)nc(-c4ccc5c(c4)sc4ccncc45)n3)c(-c3ccccc3)c2)cc1 ; c1ccc(-c2cc(-c3nc(-c4ccccc4)nc(-c4ccc(-c5cccc6sc7ccccc7c56)cc4)n3)cc(-c3cc4ccccc4c4ccccc34)c2)cc1]

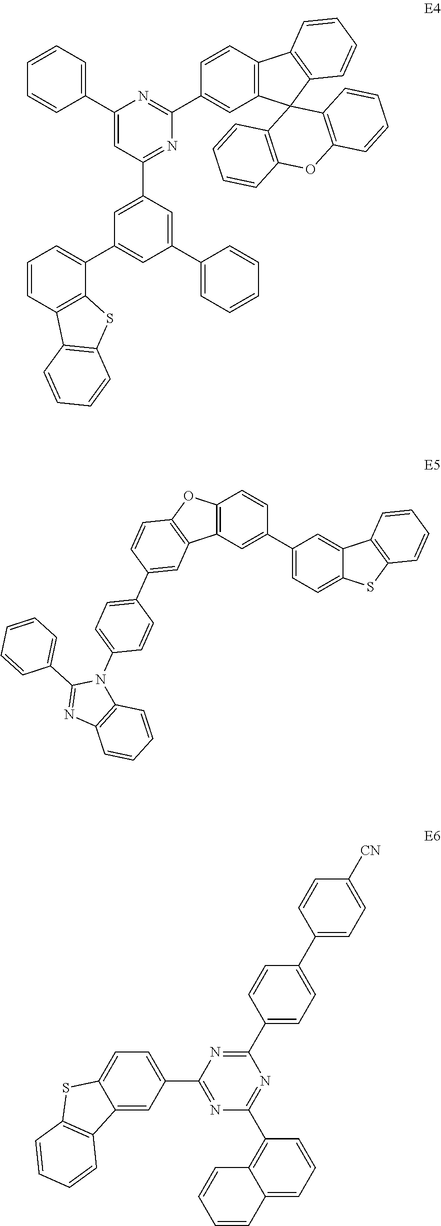 [SMILES: c1ccc(-c2cc(-c3cc(-c4ccccc4)nc(-c4ccc5c(c4)C4(c6ccccc6Oc6ccccc64)c4ccccc4-5)n3)cc(-c3cccc4c3sc3ccccc34)c2)cc1 ; c1ccc(-c2nc3ccccc3n2-c2ccc(-c3ccc4oc5ccc(-c6ccc7sc8ccccc8c7c6)cc5c4c3)cc2)cc1 ; N#Cc1ccc(-c2ccc(-c3nc(-c4ccc5sc6ccccc6c5c4)nc(-c4cccc5ccccc45)n3)cc2)cc1]

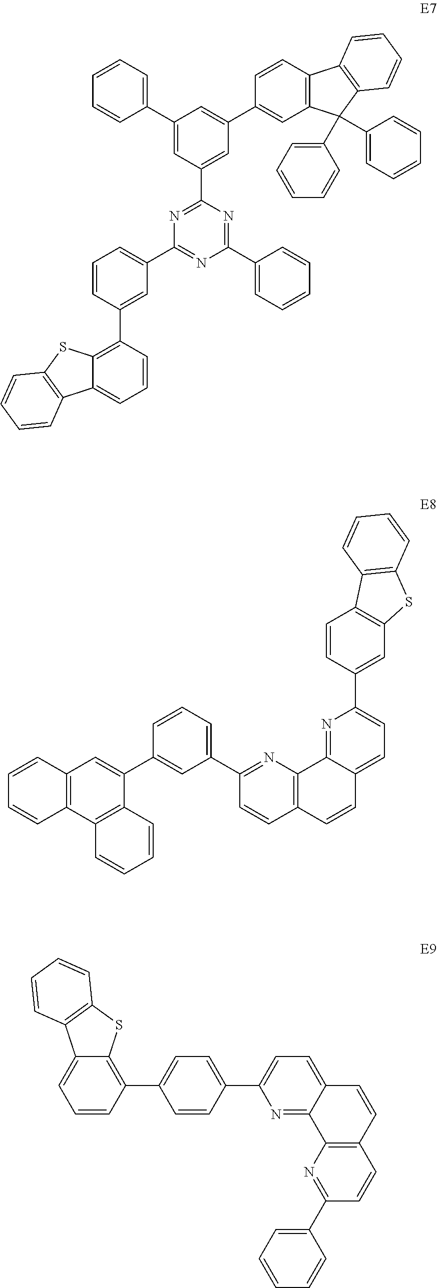 [SMILES: c1ccc(-c2cc(-c3ccc4c(c3)C(c3ccccc3)(c3ccccc3)c3ccccc3-4)cc(-c3nc(-c4ccccc4)nc(-c4cccc(-c5cccc6c5sc5ccccc56)c4)n3)c2)cc1 ; c1cc(-c2ccc3ccc4ccc(-c5ccc6c(c5)sc5ccccc56)nc4c3n2)cc(-c2cc3ccccc3c3ccccc23)c1 ; c1ccc(-c2ccc3ccc4ccc(-c5ccc(-c6cccc7c6sc6ccccc67)cc5)nc4c3n2)cc1]

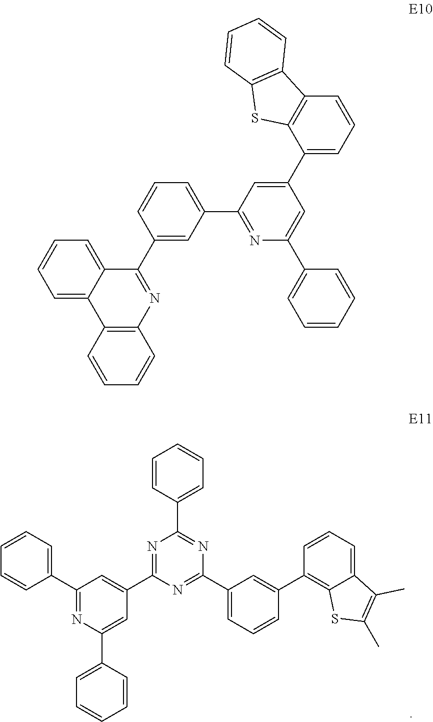 [SMILES: c1ccc(-c2cc(-c3cccc4c3sc3ccccc34)cc(-c3cccc(-c4nc5ccccc5c5ccccc45)c3)n2)cc1 ; Cc1sc2c(-c3cccc(-c4nc(-c5ccccc5)nc(-c5cc(-c6ccccc6)nc(-c6ccccc6)c5)n4)c3)cccc2c1C]

18. The light emitting element of claim 14, wherein:
each of the first hole transport region and the second hole transport region comprises a hole transport layer, a hole injection layer, and an emission auxiliary layer, stacked in order from the first electrode.

19. The light emitting element of claim 14, wherein:
the light emitting element comprises a first light emitting region that emits red light, a second light emitting region that emits green light, and a third light emitting region that emits blue light, and
the first electrode, the first hole transport region, the first electron transport region, the second hole transport region, the second electron transport region, and the second electrode are each provided as common layers in the first light emitting region, the second light emitting region and the third light emitting region.

20. A display device comprising:
a base layer;
a circuit layer on the base layer; and
a display device layer on the circuit layer and comprising a light emitting element,
wherein the light emitting element comprises:
a first electrode;
a first light emitting unit on the first electrode and comprising a first emission layer;
a charge generation unit on the first light emitting unit;
a second light emitting unit on the charge generation unit and comprising a second emission layer;
a second electrode on the second light emitting unit; and
a capping layer on the second electrode,
wherein:
the first light emitting unit comprises a first compound comprising a first moiety, the second light emitting unit comprises a second compound comprising a second moiety,
the capping layer comprises a third compound comprising a third moiety, and
the first moiety, the second moiety and the third moiety each independently comprises one among benzothiophene, thienopyridine, thienopyrimidine, thienopyridazine, thienopyrazine, thienotriazine, thienotetrazine, benzothiazole, thiazolopyridine, thiazolopyrimidine, thiazolopyridazine, thiazolopyrazine, thiazolotriazine, thiazoloetetrazine, benzothiadiazole, thiadiazolepyridine, thiadiazolepyrimidine, thiadiazolepyridazine, thiadiazolepyrazine, thiadiazoletriazine, and thiadiazoletetrazine.
